(19) United States
(12) Patent Application Publication
(10) Pub. No.: US 2015/0258769 A1
(43) Pub. Date: Sep. 17, 2015

(54) Rapid Thinning of GaN and SiC Substrates and Dry Epitaxial Lift-off

(71) Applicant: John Farah, Attleboro, MA (US)

(72) Inventor: John Farah, Attleboro, MA (US)

(73) Assignee: John Farah, Attleboro, MA (US)

(21) Appl. No.: 14/615,409

(22) Filed: Feb. 5, 2015

Related U.S. Application Data
(60) Provisional application No. 61/935,986, filed on Feb. 5, 2014.

(51) Int. Cl. B32B 43/00; C30B 29/42; C30B 29/40

(52) U.S. Cl. CPC B32B 43/006; C30B 29/40; C30B 29/42; B32B 2457/12

(57) ABSTRACT

An epitaxially grown layer III-V solar cell is separated from the growth substrate by propagating a crack close to the epi/wafer interface. The crack is driven by the elastic strain energy built up due to thermal stresses between GaAs and polyimide by cooling below room temperature. A GaAs wafer is bonded to a polyimide substrate on the epi-side and scribed on the opposite side. The crack is initiated from the scratch and guided along the interface using an epitaxially grown sacrificial layer with lower fracture toughness under the solar cell. No expensive ion implantation or lateral chemical etching of a sacrificial layer is needed. The active layer is transferred wafer-scale to inexpensive, flexible, organic substrate. The process allows re-using of the wafer to grow new cells, resulting in savings in raw materials and grinding and etching costs amounting to up to 30% of the cost of the cell. Several cells are integrated on a common blanket polyimide sheet and interconnected by copper plating. The blanket is covered with a transparent spray-on polyimide that replaces the cover glass. The solar cell is stress-balanced to remain flat on orbit.

Wide bandgap materials, such as Gallium Nitride (GaN) and Silicon Carbide (SiC) are very promising for light-emitting diodes (LEDs) and power electronics. These materials are extremely hard and difficult to machine and very expensive. The lack of good quality bulk GaN substrates with a smooth surface at a reasonable price is hampering the development of vertical devices.

A rapid thinning technique is presented by lifting-off a 20-70 μm thick layer from the surface within a fraction of a second, which leaves the surface shiny and smooth. The savings in lapping and polishing add up to 60%, when this technique is incorporated in the crystal manufacturing process. This technology also has application for backside thinning where the savings are even larger.

### BACKGROUND OF THE INVENTION

1. Field of the Invention

This invention applies to epitaxially grown solar cells and specifically to inverted solar cell structures. Inverted metamorphic III-V multi-junction solar cells achieve the highest efficiencies (>30% in space and >40% terrestrial under concentrator). These cells are grown epitaxially on Ge or GaAs wafers that are up to 700 μm thick. The solar photons are absorbed in the epitaxial layer, which is about 10 μm thick. The substrate is only for mechanical support and considered wasted from a materials point of view. Triple-junction solar cells for space cost>$250/W. This high cost is split among the cost of the substrate (40%), epitaxial growth (30%) and front side processing including metallization (30%). Epitaxial lift-off (ELO) is used to transfer the epi-layer to a flexible substrate and reuse the Ge or GaAs wafer to grow another epi-layer. There is a need to make high efficiency solar cells thin, lightweight and flexible to achieve high specific power (>200 W/Kg); and foldable so that they can be stowed in a small volume to increase payload space. It is desired to transfer the epi-layer to polyimide substrate and to reuse the Ge or GaAs wafer multiple times. A new cost-effective dry lift-off process which transfers the active cell layer wafer-scale to a less expensive flexible polyimide substrate without ion implantation or chemical etching is presented. This yields thin high efficiency solar cells which have the same performance on the host substrate as on the growth substrate and which are easily scalable to large size arrays. This process applies to all semiconductor substrates including Si, Ge, GaAs and InP and allows re-using of the base semiconductor wafer to grow new cells which results in savings in materials, grinding and etching expenses. This technology reduces the cost of the cell by 30% and allows very rapid growth of the terrestrial market for high efficiency III-V solar cells.

A dry epitaxial lift-off (DELO) process is presented by driving a crack at the epi/wafer interface and transferring wafer scale to a polyimide substrate which is used as the stressor layer and permanent carrier of the fragile solar cell, thus eliminating the need for detaching. The polyimide substrate has a thickness between 25 and 250 μm. Preferably, a thickness between 50 and 100 μm provides sufficient driving force and yields a specific power ratio>1000 W/Kg. The crack is driven purely by the thermal stresses due to the mismatch in CTE between GaAs and polyimide without the necessity for any external mechanical force or tool to aid crack propagation. This allows the use of automated roll-to-roll processes which reduce the cost even further. In order to reduce the cost of the cell a single junction GaAs solar cell with efficiency>20% at AM1.5 [1] can be used which simplifies the solar cell structure considerably and reduces the cost of epitaxial growth significantly compared to the triple junction. This process yields single atomic plane horizontal cleavage which reduces the need for post lift-off polishing, which allows multiple reuses of the substrate. This combined with cheaper metallization techniques such as aerosol jet printing, which is a maskless additive manufacturing technology, allows reducing the cost down to $50/W, which makes it attractive for terrestrial applications.

2. Discussion of Related Art

Inverted metamorphic (IMM) solar cells are grown epitaxially inverted (high bandgap junction first, low bandgap junction last) on Ge or GaAs wafers in multiple layers, as shown in FIG. 29. After transferring the layer to another substrate the solar cell is flipped upside down so that the high bandgap junction faces the sun. An InGaP etch stop layer or an AlGaAs sacrificial layer is grown under the epi-layer, which helps transfer the epi-layer stack to another substrate. Laboratories with special equipment are required to handle GaAs because it contains arsenic, which is toxic. The GaAs base wafer is usually ground away and etched. At $100 a piece this creates the most expensive toxic dust. It is desired to transfer the epi-layer without sacrificing the base Ge or GaAs wafer.

The (110) is the preferred cleavage plane in GaAs. However, solar cell manufacturers are reluctant to grow on (110) wafers because most of the industry is built on (100) wafers, albeit with large off-cut angles up to 15° toward the (111)A plane.

The ultimate goal of all lift-off techniques is to re-use the base wafer after lift-off.

### SUMMARY OF THE INVENTION

It is desired to cleave atomically flat surfaces at or very near the epi/wafer interface in order to minimize post lift-off polishing and avoid wasting substrate material. III-V materials have the advantage that devices are fabricated in epitaxially-grown layers. Thus, the epi-layer can be peeled off the substrate and transferred to a flexible carrier and the substrate can be reused to grow another epi-layer. If the quality of the surface is good and the substrate is recovered at original thickness then the substrate can be reused multiple, perhaps more than 10 times. The fragile crystalline solar cell must be supported at all times. A suitable flexible carrier is polyimide Kapton® sheet which is manufactured by DuPont and qualified for space applications. Kapton is available in sheets as thin as 25 μm which are easy to handle and come pre-coated with a uniform layer of acrylic adhesive. It operates continuously from cryogenic to >200° C. which is suitable for space and terrestrial applications. A Kapton sheet with adhesive layer is bonded to the epi-side of GaAs wafer using a hot roll laminator and then cured in an oven at 150-190° C. for about an hour. After lift-off the thin epi-layer is carried by the Kapton sheet which serves as permanent carrier of the solar cell. The entire thickness of the thin solar cell is less than 200 μm, which meets the specific power requirement.

FIG. 1 shows a thin IMM3J epi-layer carried by polyimide substrate which was obtained by etching away the GaAs wafer. It shows a smooth shiny surface of the InGaP etch stop layer. This can be obtained by lifting-off the epi-layer without sacrificing the growth wafer so that it can be re-used to grow another epi-layer. This solar cell was rolled mechanically to a radius<½″ and shocked thermally without fracturing.

### Dry Epitaxial Lift-Off (DELO)

A sheet of polyimide as thin as 50 μm bonded to a GaAs wafer of any size lifts a layer of GaAs about 10-20 μm thick off the substrate when immersed in liquid nitrogen within a minute. A crack nucleates with an audible sound at a temperature about −140° C. as the wafer is lowered in the Dewar even before it touches the liquid. The crack propagates beneath the surface at a depth which is prescribed by the thickness of the polyimide/GaAs wafer ratio. The crack propagates across the wafer in a split second. Two wafers ensue: the base wafer in one piece, and the epi-layer on the polyimide. There are no cracks in the epi-layer on the polyimide. The lift-off was captured on video and can be seen at the following link: http://www.youtube.com/watch?v=BR1LDdZabg. The video takes only 48 seconds. Lift-off happens at second 40. FIG. 36 from top to bottom left to right shows a sequence of snapshots taken at 0.1 sec intervals over a span of 0.5 second of a 4″ GaAs wafer at the moment of lift-off. It shows the wafer at rest in one piece in LN₂ at time zero. Then suddenly it splits 100 milli-sec later. It continues to split further until finally the two pieces land on top of each other.

Kapton® tape which is commercially available and comes pre-coated with a thin adhesive layer is perfect for this application and is even qualified for space. This is very convenient because it is not easy to apply an adhesive layer uniformly over an entire 4″ wafer. The adhesive layer must be uniform in order to carry a fragile epi-layer 1-10 μm thick without fracturing it. Kapton is available in layers as thin as 25 μm in 25 μm increments. Multiple layers can be laminated sequentially to obtain any desired thickness. Cooling in LN₂ is advantageous because GaAs becomes even more brittle at −196° C. which lowers the energy to propagate the crack. The organic adhesive material has sufficient shear strength and holds its grip at cryogenic temperature and is able to transmit the force necessary to rupture the semiconductor wafer, even Gallium Nitride (GaN) and Silicon Carbide (SiC) which have a fracture toughness and elastic modulus larger than GaAs. The entire lift-off happens within a couple of minutes. It was not known previously that a commercial off-the-shelf Kapton tape could be bonded to a semiconductor wafer and causes it to cleave a thin layer at a depth between 10 and 20 μm simply by dunking in LN₂.

The polyimide serves not only as the permanent carrier of the thin crystalline solar cell but also as stressor layer which creates the thermal stresses that lead to cleavage. The temperature is lowered by introducing the composite structure slowly in liquid nitrogen at −196° C. Within a minute, an audible crack initiates and the film snaps right off A polyimide thickness between 50 and 100 μm is able to lift-off a GaAs thickness between 10 and 20 μm and achieves a specific power ratio of 1000 W/Kg for space and terrestrial applications (see calculation of specific power in the Appendix). At this thickness the polyimide packs just enough elastic strain energy to initiate and propagate the crack through the wafer at the desired depth. In fact most of the strain energy is stored in the polyimide itself Kapton has a CTE about 16×10⁻⁶/° C. and GaAs 6×10⁻⁶/° C. The composite structure is subjected to a temperature drop of about 300° C. (between the curing temperature and LN₂). Thus, the driving thermal strain ΔαΔT=3×10⁻³. This thermal strain produces a tensile stress in the GaAs between 20 and 60 MPa which is sufficient to initiate the crack and overcome the resistance to its propagation. The stress intensity factor K_{I} which represents the stress concentration factor at the tip of the crack is related to the stress σ and the depth of the scratch a as K_{I}=σ\sqrt{πa} When the stress intensity factor exceeds the fracture toughness of the material K_{Ic} the crack starts to propagate. Thus, a scratch depth of about 20-40 μm is needed to initiate the crack, which can be readily achieved either by scratching manually with a diamond tip or with a nano-indenter. Crack nucleation is due solely to the build-up of thermal stresses without applying external mechanical force. The crack propagates across the wafer in about 0.1 milli-second. The wafer cleaves spontaneously at a plane parallel to the bond interface. For GaAs the lift-off temperature is about −140° C. whereas for Si the wafer must be cooled down to −196° C. The lift-off happens in a split-second and was captured on video. The front side of the solar cell can be processed on the Kapton after lift-off. The concept applies to all semiconductor materials, Si, Ge, GaAs, InP, GaN and SiC and to all epitaxially grown solar cells for space as well as terrestrial applications. The concept is illustrated in FIG. 2a and FIG. 2b.

The sequence of frames in FIG. 3 taken from http://www.youtube.com/watch?v=B1tj5ZUe9TI show the backside of a GaAs wafer piece bonded to Kapton 50 μm thick on the front side (underneath), on a plate as it is lowered slowly in a Dewar of liquid nitrogen. The successive pictures show the drop in temperature over the course of a few minutes until lift-off happened at a temperature of −140° C. As the lift-off temperature was reached the Kapton layer snapped off almost instantaneously. The curled peeled off epi-layer stuck to the Kapton sheet (brown) is shown in FIG. 3 (bottom right) sitting on top of the GaAs wafer piece.

The following video clips show the rolling and unrolling of GaAs epitaxial layers on Kapton as it is thermally cycled between a hot plate at +100° C. and −196° C. These movies take less than a minute each: http://www.youtube.com/watch?v=WED8cj2YfIw 1:33 min rolling and unrolling http://www.youtube.com/watch?v=U5rxiwkenmI 1:00 min rolling and unrolling

A lifted-off GaAs layer on Kapton can be held flat on a standard vacuum chuck. The following video shows the lifted-off layer spinning at 3000 RPM which allows fabrication of the front side of the solar cell. http://wvvw.youtube.com/watch?v=VC6v7_RAOok The video takes only 9 seconds.

The polyimide is very advantageous because it is able to induce lift-off for a temperature drop ΔT of only 300° C. compared to metal which requires raising to >800° C. Furthermore, it is completely inert and does not contaminate the semiconductor layer. This process is low temperature between +200° C. and −196° C. The combination of polyimide/adhesive is tough and can withstand these temperatures. The acrylic adhesive holds in liquid nitrogen and is able to transmit the force and break-off a layer of semiconductor wafer without losing its grip. The adhesive layer is applied uniformly to Kapton. It has a smooth surface and supports the epi-layer over the entire 4″ wafer.

### Cleavage by Crack Propagation Due to Thermal Stresses

The following is a summary of results obtained:
1) lifted-off a layer of GaAs 10-15 μm thick equivalent to IMM3J layer thickness,
2) cleaved 2″ (110) and 4″ (100) orientation wafers and saved the base wafer as one piece,
3) reused abase wafer and lifted-off another layer several times, there did not appear to be a limit to the number of reuses as long as the substrate remained thick enough,
4) obtained atomically smooth (mirror-like) surfaces (single atomic plane cleavage, roughness<1 nm) over large areas (several cm²) in (110) orientation wafer,
5) fabricated front side of solar cell on Kapton and demonstrated that the performance is not degraded compared to identical solar cell on GaAs wafer.

FIG. 4a and FIG. 5 show the lifted-off layer on Kapton to the right and the base wafer to the left for GaAs (110) and (100), respectively. FIG. 4b top shows the lifted-off layer on Kapton to the left and the base wafer of GaAs (110) broken to six pieces. FIG. 4b bottom shows the lifted-off layer on Kapton (top) and the base wafer of GaAs (110) saved in one piece. Uniform cleavage is obtained across 4″ wafer. The (110) orientation yields smoother cleaved surface as expected. FIG. 6 shows AFM average roughness of 0.059 nm, below instrument noise, indicating that the cleavage is a single atomic plane.

A Kapton film 50-100 μm thick carrying a GaAs layer 10-15 μm thick curls to a radius of about 15 mm in LN₂ as shown in FIG. 7, in agreement with simulations (see Examples in Appendix).

The residual stress causes curvature at room temperature which depends on the relative thickness of GaAs/polyimide, as shown in FIG. 8. The thickness of the polyimide is optimized to deliver the maximum bending stresses. The highest stresses are obtained in the bending mode. The thin epi-layer on Kapton rolls to 0.75-inch diameter in LN₂ without cracking, as shown in FIG. 9. As the temperature drops, the polyimide shrinks at a higher rate than the GaAs. This causes the composite structure to roll as a tube with the polyimide on the inside. The thin solar cell flattens when placed on a hot plate at 100° C.

The two parameters that influence crack propagation are the thickness of polyimide and the depth of the initial scratch. If the polyimide is too thin (<50 μm) then there is not enough elastic strain energy to overcome the resistance to crack propagation, i.e. the surface energy. If the polyimide is too thick (>300 μm) then several cracks start simultaneously. The wafer shatters in many pieces to increase the surface of the crack. The cracks will start even without scratching due to defects on the surface of the wafer. This leads to uncontrollable crack propagation. However, a scratch with the right depth is needed to obtain a controlled crack. If the scratch is too shallow then the crack will not propagate because the stress intensity factor is below the fracture toughness. If the scratch is too deep then the crack may continue along its vertical path until it hits the adhesive and may not turn sideways. Thus, controlling the crack is a delicate balance between scratching and the thickness of polyimide. A polyimide thickness between 50 and 100 μm lifts-off a layer 10-20 μm from a GaAs wafer 500-700 μm thick which are typically used to grow III-V IMM solar cells. The base wafer separates nicely in one piece and there are no cracks on the polyimide. Luckily this thickness range yields a rugged yet flexible solar sheet which meets the specific power requirement of 1000 W/Kg for space and terrestrial.

A rectangular strip of Si wafer was laminated with Kapton, but the Kapton was purposefully terminated before the edge of the strip, as shown in FIG. 10. The Kapton was recessed about ⅛″ from the edge of the strip. The strip was scratched near the middle on the backside opposite the Kapton. The goal was to discover whether the crack would start propagating from the scratch on the backside or from the edge of the Kapton on the front side, as it would with a Nickel stressor layer. After dunking in LN₂, half of the strip delaminated completely, while the other half was still hanging from the edge of the Kapton, as shown in FIG. 11. This proves beyond doubt that the crack started from the scratch in the middle and propagated toward the edge. This provides further proof that scratching competes with the spontaneous auto-cleavage mechanism due to a discontinuity in the structure and influences the path of the crack. FIG. 12 shows the recess in the Si around the edge of the Kapton. The Kapton/Si curls in LN₂ to a radius of 15 mm. At this thickness the Kapton/thin Si exhibits the strongest bow (see Appendix and FIG. 53 and FIG. 54). The thickness of the lifted-off layer on Kapton was measured with a digital micrometer which has ±1 μm accuracy. The pointed tips of the micrometer make dents about 10 μm deep in the polyimide and the thin GaAs, which reduce the thickness readings.

Substrates of different shapes were cleaved with polyimide. FIG. 13a and FIG. 13b show triangular pieces with dimensions varying between ¾″ to 1.5″ on the side having an area up to 7 cm², with uniform cleavage where the base wafer detached in one piece. The triangular substrate in FIG. 13a was not scratched. The cracks started from the three sides of the triangle. The three fracture fronts intersected along the bisectors of the triangle and converged on the center. The lines emanating from the three corners of the triangle are seen very clearly. Whereas the triangular piece in FIG. 13b was scratched about 1 cm along the common edge. As soon as it was lowered in LN₂, the back piece jumped out of the Dewar and fell in the sink about one foot below without shattering, and there are no cracks on the polyimide. The picture shows the crack front pattern radiating away from the scratched edge. A line emanating from the opposite corner of the triangle along the bisector is still visible, but the lines emanating from the other two corners were squished toward the outer edges of the triangle by the crack front. Thus, scribing makes a difference and influences the nucleation and propagation of the crack but does not prevent other cracks form happening. Horizontal cleavage definitely occurred because there is a uniform layer of Si remaining on the polyimide.

The GaAs wafer is subjected to tremendous stresses at lift-off which can cause the backside of the wafer to shatter rather than separate smoothly in one piece. When the polyimide is too thick (>300 μm) then several cracks start simultaneously even without scratching. This leads to uncontrollable crack propagation. The polyimide packs significant elastic strain energy and the wafer shatters in many small rectangular pieces to increase the surface of the crack. This happened mainly with GaAs (100) wafers that were scratched near and parallel to the flat edge. A crack may have originated from the scratch, but it was not the only one. The scratch did not prevent other spontaneous auto-initiated cracks from starting. The GaAs wafers started cracking even before they reached −196° C. when they were exposed to nitrogen gas. Cracks developed at right angles (parallel and perpendicular to the scratch) and the piece cleaved in many small rectangular pieces, as shown in FIG. 14.

The success of the epitaxial lift-off by crack propagation hinges on a delicate balance between the initial scratching and the loading by the polyimide which depends on the polyimide-to-GaAs thickness ratio and the crystallographic orientation of the wafer. GaAs (110) cleaves smoother and more uniformly than (100). The extent of the lateral crack propagation also depends on the thickness ratio. Thicker polyimide causes the crack to propagate farther but lifts-off a thicker layer and may break the wafer. It is desired to minimize the thickness of polyimide to increase the specific power ratio for space applications. The right combination of stresses is necessary to guide the crack near the interface. However, thermal stresses cause significant bow. It is desired to minimize the effect of stresses on the performance of the solar cell.

Precise control over crack propagation is necessary to lift-off layers with uniform thickness and smooth surface. Atomically smooth cleaved surfaces were obtained by controlling the crack propagation. The polyimide applies pure bending moment on the GaAs wafer which is the optimal mode of opening a crack in tension (Mode I). Shearing stresses (Mode II) cause deviation in the path and uncontrollable crack propagation [16]. If these requirements are not met then the crack can bifurcate and branch out and cause secondary cracks to propagate at different angles along different paths. To maximize yield in production a fundamental understanding of fracture mechanics at the nano-scale is essential. For industrial applications this process must be controlled. The focus of the research is to better understand the stress mechanisms that lead to rupture and how to control the path of the crack. The challenges are controlling the crack propagation depth near the epi/wafer interface and preventing the substrate from shattering.

### BRIEF DESCRIPTION OF THE DRAWINGS

The accompanying drawings are not intended to be drawn to scale. In the drawings:

FIG. 1 Thin IMM3J solar cell on polyimide substrate 50 μm thick;

FIG. 2a Schematic of wafer with epi-layer bonded to Kapton® polymeric permanent carrier;

FIG. 2b Schematic of wafer separated and solar cell carried by Kapton® after lift-off;

FIG. 3 Epitaxial layer lifted-off GaAs wafer piece at −140° C. on Kapton sheet (brown) 50 μm thick;

FIG. 4a GaAs (110) wafer lifted on Kapton (right), base wafer (left);

FIG. 4b top GaAs (110) wafer lifted on Kapton (left), base wafer (left) broken to six pieces, bottom base wafer saved in one piece;

FIG. 5 GaAs (100) wafer lifted on Kapton (right), base wafer (left);

FIG. 6 AFM roughness measurements of cleaved GaAs (110) wafer;

FIG. 7 Kapton film 50-100 μm thick carrying a GaAs layer 10-15 μm thick curled to a radius of about 15 mm in LN₂;

FIG. 8 Kapton film 50-100 μm thick carrying a GaAs layer 10-15 μm thick curled at room temperature;

FIG. 9 GaAs layer 10-15 μm thick on Kapton film 50 μm thick rolled to 0.75-inch diameter in LN₂;

FIG. 10 Kapton smaller than Si strip;

FIG. 11 Crack in Si wafer strip started at the scratch in the middle of the strip and propagated toward the edge. A piece of the wafer remains stuck to the Kapton;

FIG. 12 Recess in Si 20 μm deep equal to thickness of lifted-off layer;

FIG. 13a Triangular wafer piece unscratched;

FIG. 13b Triangular wafer piece scratched along common edge;

FIG. 14 GaAs (100) wafer shattered to small rectangular pieces;

FIG. 15 optical microscope picture of cleaved single atomic plane (blank area) with ridges on the side;

FIG. 16 Bird's eye view of single atomic plane cleaved surface taken with Zygo optical profilometer;

FIG. 17 Mirror-like cleaved surface of GaAs (110) wafer;

FIG. 18 Vertical crack starts from scratch on upper surface of GaAs wafer under tensile stress;

FIG. 19 Path of the crack;

FIG. 20 GaAs (110) wafer scratched near edge, crack propagated both ways. Atomic plane cleavage area 2.5 cm×1 cm near broken common edge;

FIG. 21 Horizontal crack in GaAs (110) on Kapton 50 μm;

FIG. 22 Stitched images of microscope pictures of area of single atomic plane cleavage 3 cm×1.5 cm;

FIG. 23 Cleavage in GaAs (100) wafer;

FIG. 24 Embedded layer of lower fracture toughness, such as GaAs (110), in GaAs (100) wafer;

FIG. 25 GaAs (110) layer embedded in GaAs (100) wafer;

FIG. 26a Unit cell of GaAs;

FIG. 26b Unit cell of GaAs;

FIG. 27 Atomic arrangements in three planes (100), (110) and (111) for Si and GaAs;

FIG. 28 GaAs (110) plane cross-section (black rectangle) superimposed on (100) plane cross-section (blue square) and shifted by ¼ lattice constant;

FIG. 29 Inverted metamorphic triple junction (IMM3J) solar cell structure grown on GaAs wafer;

FIG. 30 Semiconductor wafer bonded to high-CTE and low-CTE polyimide substrates;

FIG. 31 Polished 4″ diameter high-CTE polyimide wafer 250-500 μm thick;

FIG. 32 Si (111) wafer auto-cleaved along two parallel lines without scratching the surface prior to cooling;

FIG. 33 Cracks starting under the Kapton;

FIG. 34a Vertical crack stops at compressive InGaAs layer;

FIG. 34b Crack guided around complex shape;

FIG. 35a Solar cell for space 6.6 cm×4 cm bonded to 4″ polyimide wafer (half circle) on one side and Kapton on the other side;

FIG. 35b Base GaAs wafer on the polyimide wafer and the epi-layer on the Kapton after lift-off;

FIG. 36 Sequence of snapshots showing 4″ GaAs wafer at the moment of lift-off;

FIG. 37 4″ GaAs wafer diced yields two cells for space applications. Several cells are integrated on common blanket polyimide sheet. Photo courtesy of Sharp Corporation;

FIG. 38 Schematic of packaged and encapsulated 8-layer solar cell;

FIG. 39 Two cells integrated on copper-cladded polyimide sheet with ECA (white);

FIG. 40a Contacting both sides of IMM cell from the top of the wafer;

FIG. 40b Interconnecting of several IMM cells in series;

FIG. 41a Deformations of 8-layer solar cell structure at −200° C. for Spray-on Polyimide Thickness of 25 μm, at different CTE's, flat at CTE=16.5 ppm/° C.;

FIG. 41b Deformations of 8-layer solar cell structure at −200° C. for Spray-on Polyimide Thickness of 50 μm, at different CTE's, flat at CTE=20 ppm/° C.;

FIG. 42 Top view of the interconnect region between two adjacent cells;

FIG. 43 Process for electroplating series and parallel connections;

FIG. 44a GaAs/polyimide composite structure at the temperature of zero stress;

FIG. 44b Thermal strain in GaAs and polyimide;

FIG. 44c Bending of GaAs/polyimide composite structure due to thermal stress;

FIG. 45 Strain and stress fields near edge, A₁A₂ becomes C₁C₂ after deformation;

FIG. 46 Forces and moments acting on the GaAs and the polyimide;

FIG. 47a 1/R and bending stresses vs h for GaAs 370 μm thick and ΔT=300° C. before lift-off;

FIG. 47b 1/R and bending stresses vs h for Si 200 μm thick and ΔT=300° C. before lift-off;

FIG. 48a 1/R and bending stresses vs h′ for GaAs 20 μm thick and ΔT=300° C. after lift-off;

FIG. 48b GaAs 20 μm thick on Kapton 50 μm in liquid nitrogen having a radius of about 4 cm;

FIG. 49 Maximum bending+axial stresses;

FIG. 50 Vectors in the surface of the wafer for the three principal orientations. All three surfaces contain a <110> vector;

FIG. 51 Axis of curvature not parallel to flat;

FIG. 52 Actual stresses due to cooling show tensile bending stresses at upper surface of GaAs and axial stretching of the polyimide;

FIG. 53 Locus of K_{I} and K_{II} for crack growth;

FIG. 54 Change in the direction of propagation of the crack depending on the ratio of K_{II}/K_{I} [9];

FIG. 55 Dependence of the energy release rate on the direction of crack propagation [9];

FIG. 56 Horizontal crack of length a;

FIG. 57a Elastic strain energy of GaAs/polyimide before crack propagation;

FIG. 57b Elastic strain energy of GaAs/polyimide after crack propagation;

FIG. 58a U/Lb vs thickness for GaAs, polyimide h₂=150 μm, showing range of residual energy in lifted-off layer corresponding to surface energy;

FIG. 58b U/Lb vs thickness for Si, polyimide h₂=150 μm, showing range of residual energy in lifted-off layer corresponding to surface energy;

FIG. 59 Thin IMM Solar Cell (9-layer) Structure;

FIG. 60 AFM image of typical epi-ready 4H—SiC showing average roughness=0.755 nm;

FIG. 61 AFM image of cleaved 4H—SiC showing average roughness=0.654 nm. Note the absence of grinding marks;

FIG. 62a SiC/Kapton laminate bent in LN₂;

FIG. 62b GaN/Kapton laminate bent in LN₂;

FIG. 63 SiC substrates separated from Kapton;

FIG. 64 SiC substrates separated from Kapton;

FIG. 65 DekTak height profile measurements of cleaved surface and backside of a cleaved wafer piece

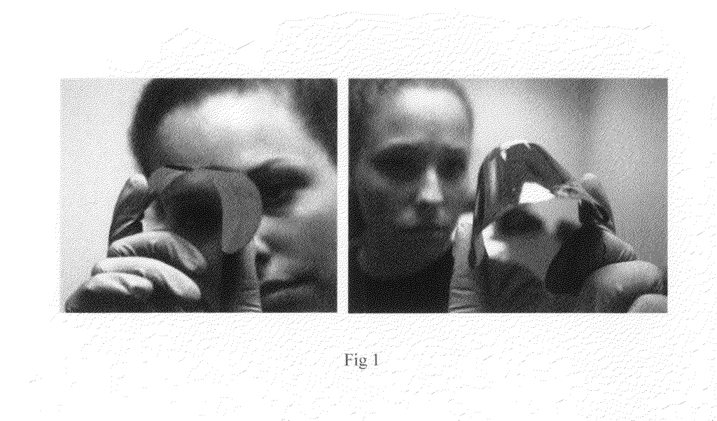

### DETAILED DESCRIPTION OF THE INVENTION

This invention is not limited in its application to the details of construction and the arrangement of components set forth in the following description or illustrated in the drawings. The invention is capable of other embodiments and of being practiced or of being carried out in various ways. Also, the phraseology and terminology used herein is for the purpose of description and should not be regarded as limiting. The use of “including”, “comprising”, or “having”, “containing”, “involving”, “triple-junction” or “multi-junction” and variations thereof herein, is meant to encompass the items listed thereafter and equivalents thereof as well as additional items.

### Single Atomic Plane Cleavage in GaAs (110) Wafer

It is desired to cleave a single atomic plane to reduce the amount of polishing and thickness variation after each lift-off. A touch polish would only be necessary followed by cleaning of the surface. The (110) is the preferred cleavage plane in GaAs because it has the lowest fracture toughness. GaAs presents anisotropy with K_{I} varying between 0.31 and 0.46 MPam^{1/2} along different <110> directions. The origin of the anisotropy lies in the difference between dislocation mobilities along the different directions [10,11]. The mobility of <110> dislocations on As-terminated planes is much higher than on Ga-terminated {111} planes (Warren et al. 1984). A (100) surface contains 2 <110> vectors perpendicular to each other. Thus, the effective value of K_{Ic} depends on whether the scratch is parallel or perpendicular to the flat.

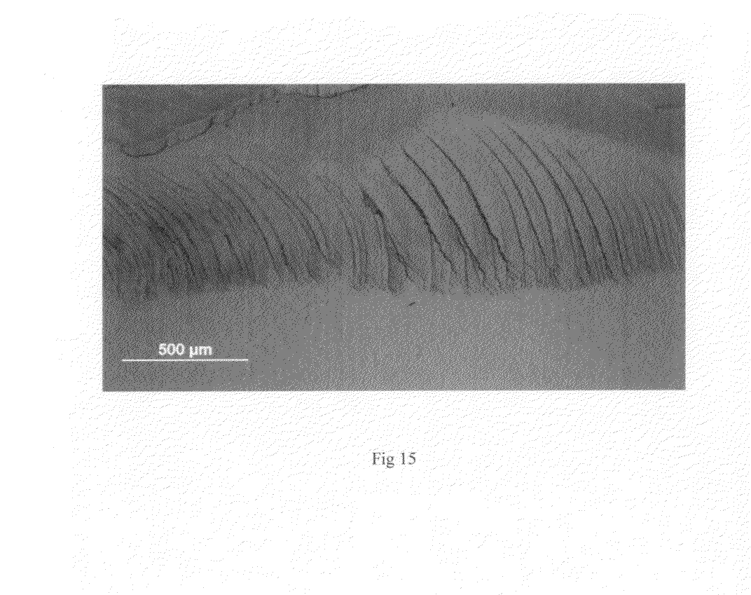

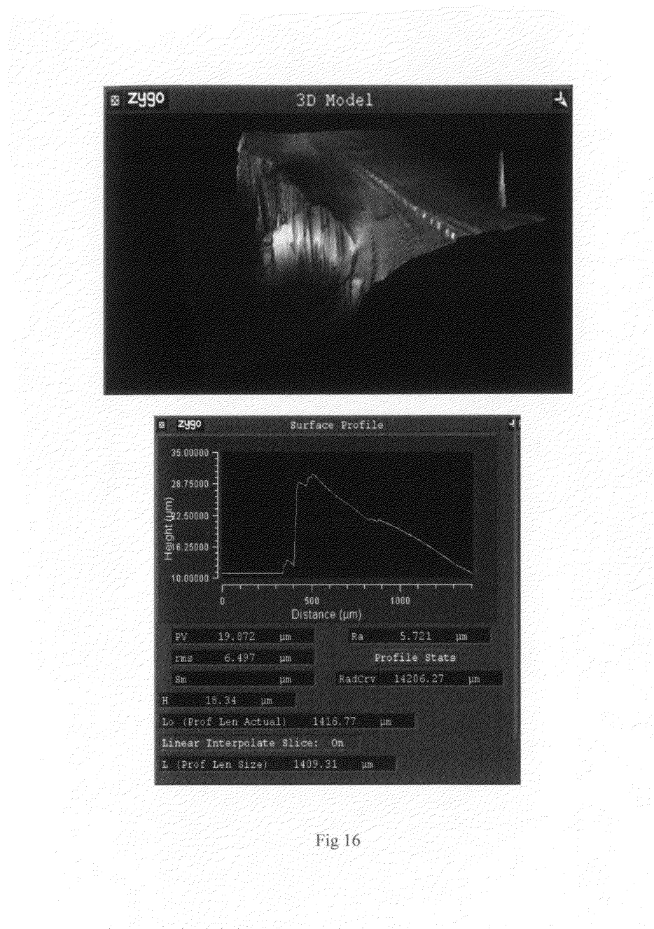

Smoother cleaved surfaces were obtained on (110) than (100) planes. FIG. 15 shows a picture taken with the optical microscope of cleaved single atomic plane area (blank) with ridges on the side. These are known as river lines in fractography. The entire area is >1 cm². Actually, it is like a lake surrounded by mountains. FIG. 16 shows a scan of the same area taken with Zygo profilometer, which proves that the surface is a single atomic plane (flat blue area). It is shiny and smooth like a polished surface, but it is a cleaved surface because it lies about 15-20 μm below the original wafer surface. The lifted-off layer of the same thickness is on the Kapton. The horizontal scale on the picture is 1.4 mm, and the height of the step is about 17.5 μm.

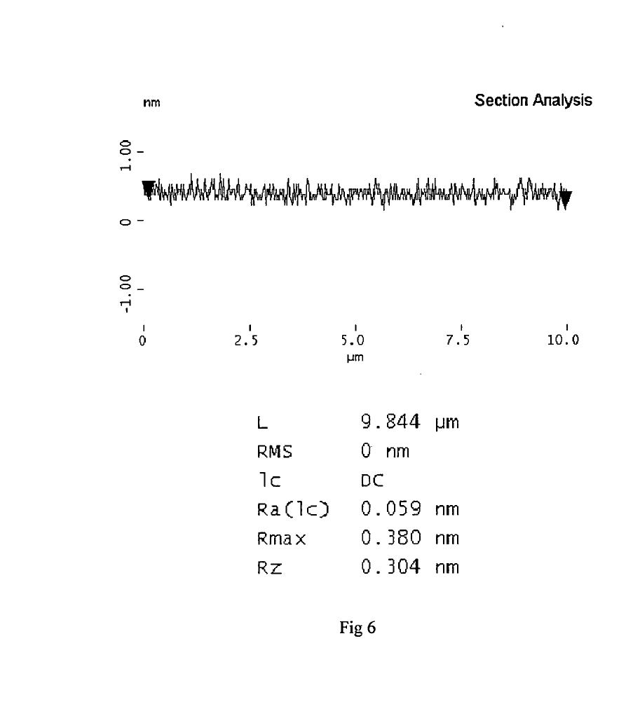

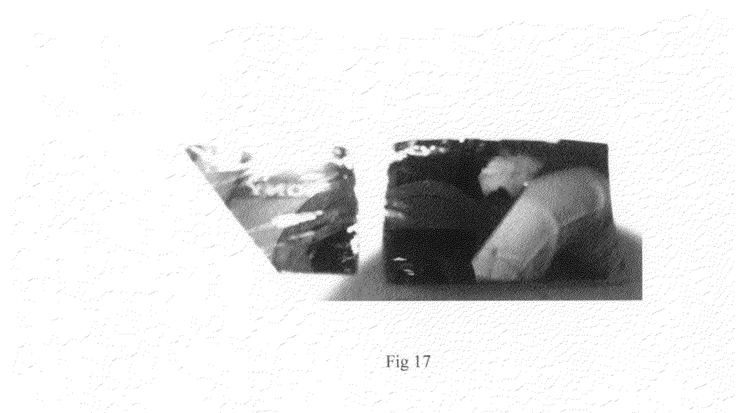

FIG. 6 above shows AFM measurements of the cleaved surface showing average roughness well below 1 nm (Ra=0.059 nm) indicating that it is a single atomic plane. This figure is below instrument noise. By comparison, (100) cleaved surfaces exhibit an average surface roughness Rₐ˜1 μm. FIG. 17 shows that the cleaved surface is practically mirror-smooth. The image of the camera and the fingers taking the picture can be seen in the reflection.

### Horizontal Crack Propagation

Horizontal crack propagation in non-crystalline materials has been investigated theoretically and experimentally since the late 80's [2,3,4]. However, horizontal cleavage or spalling of crystalline semiconductor substrates, especially those carrying solar cells, has only been investigated in the last few years [5,6,7]. When a composite structure is subjected to thermal stresses upon cooling, a vertical crack opens under tensile stresses in pure mode I because there is no mechanism to open a horizontal crack. However, as the crack propagates downward it encounters significant shear stresses which cause deviation of its path. Horizontal crack propagation is due to mixed-mode I (opening) and II (shear) stress at the crack tip. The theoretical investigations attempt to calculate the stress intensity factors (K_{I} and K_{II}) at the crack tip due to an over-layer with residual tensile stress, and suggest that the horizontal crack propagates at a depth where K_{II}=0. K_{I} is related to the stress a and the depth of the scratch a, as mentioned above. The theory of fracture mechanics assumes that a crack already exists, but does not pay particular attention to where it nucleated or how it started. When a crack reaches a certain length under a certain stress, such that K_{I}=K_{Ic} which is a material property called the fracture toughness, the crack starts to propagate on its own. According to Thouless [2] no matter where the crack starts, it ends up propagating at the same depth. For this reason it is called “steady-state” propagation. The calculation of K_{I} and K_{II} is not straightforward. Alternatively, the depth of cleavage can be predicted from the principle of conservation of energy. According to Griffith's criterion, once the crack starts to propagate the energy release rate G, i.e. the change in the elastic strain energy of the system per unit crack advance is constant, pinned at the surface energy 2γₛ, which is a material property.

### Why the Crack Turns 90°

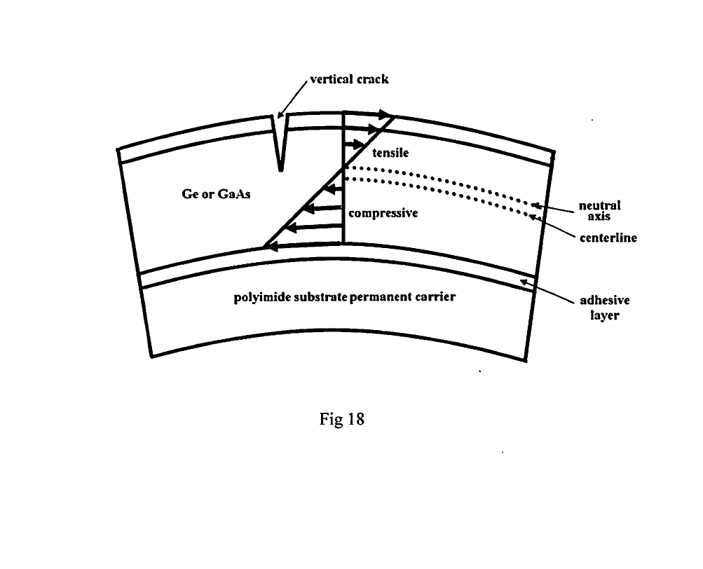

The crack opens vertically in pure mode I at the upper surface where the stress and K_{I} are maximal, as shown in FIG. 18. As it approaches the neutral axis, K_{I} drops to zero as the stress switches from tensile to compressive. The crack will stop as it enters a zone of compressive stress and turns horizontal. At that point K_{II} becomes larger than K_{I}. A crack will propagate as long as (K_{I}²+K_{II}²)>K_{Ic}². However, the direction of propagation of the crack changes depending on the ratio of K_{II}/K_{I} [9]. The crack turns by 90° and steers away from a compressive zone as K_{I} drops to zero (K_{II}/K_{I}→∞) (See the Appendix). However, K_{Iv} and K_{IIv} for the vertical crack are different from those for the horizontal crack, K_{Ih} and K_{IIh}. Nevertheless, they are related by the same energy release rate G=(K_{Iv}²+K_{IIv}²)/E_{eff}=(K_{Ih}²+K_{IIh}²)/E_{eff}, where E_{eff} is the effective modulus of elasticity for plane strain. Thus, as K_{Iv} approaches zero, the crack swerves by 90° and keeps going. As mentioned above, a horizontal crack propagates at a depth where K_{IIh}=0. But there is experimental evidence that the vertical crack stops at a depth where K_{Iv}=0. Thus, it would be most advantageous to coincide the two locations where K_{Iv}=0 with K_{IIh}=0 at the desired cleavage depth.

### Path of the Crack

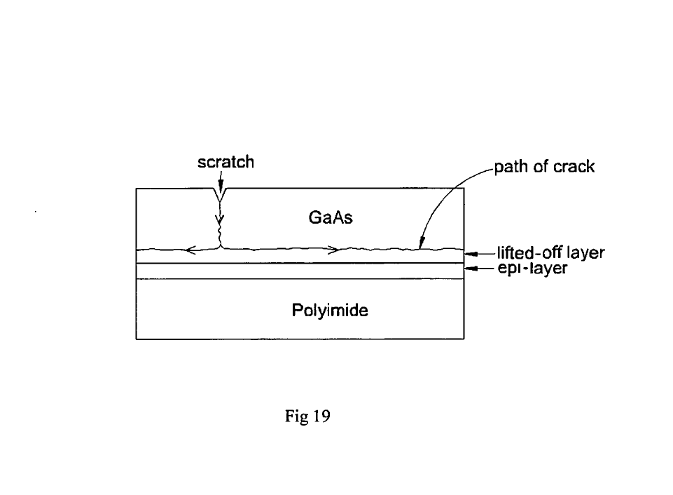

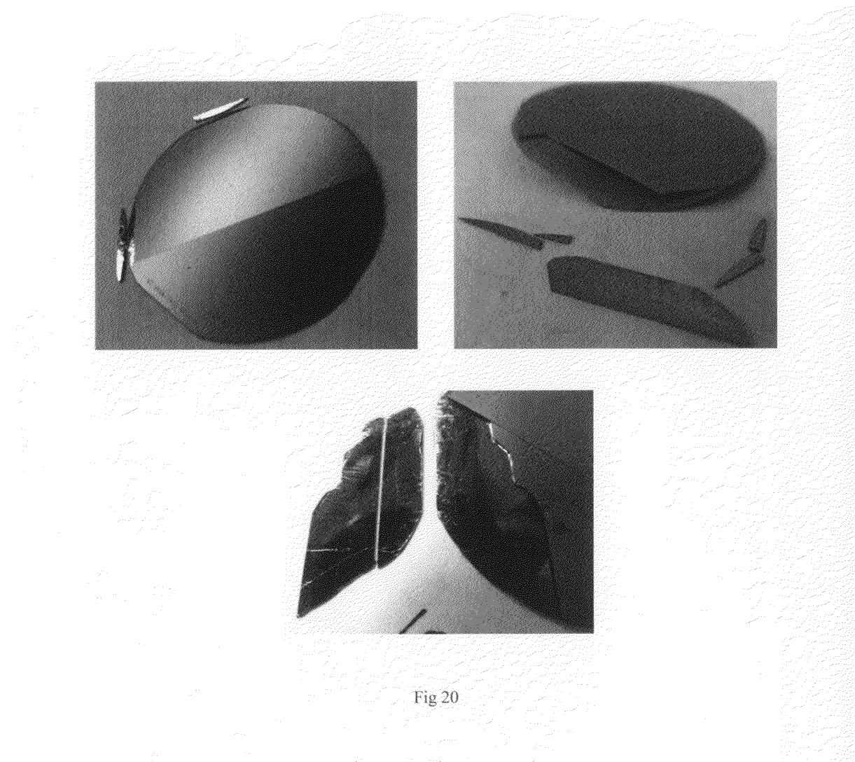

FIG. 19 illustrates the path of the crack schematically. The crack starts vertically from the scratch, stops at a certain distance away from the epi/wafer interface and turns 90°. It propagates horizontally in both directions. The wafer is scratched near the edge in order to minimize the area of the wafer that is lost. FIG. 20 shows a GaAs wafer that was scratched on the ground backside about 1 mm away from the edge and cleaved a narrow strip. A layer of GaAs about 10-15 μm thick remains stuck to the Kapton. The crack also went in the other direction but did not propagate all the way across the wafer. It required scratching several times. When the thickness of polyimide was increased, the crack propagated readily from one edge of the wafer to the other, and the base wafer detached in one piece. There are no visible cracks in the thin GaAs on the Kapton.

FIG. 21 shows the same wafer standing on edge under an optical microscope. This provides irrefutable evidence that the crack originated from the scratch on the backside (away from the polyimide) and turned by (almost) 90°. The crack stops in a compressive zone near the polyimide. The hypothesis that a crack starts vertically and turns horizontally has been proven. We were able to compete with the spontaneous auto-cleavage mechanisms due to defects in the wafer and influence the path of the crack. The only driving force behind the crack is the elastic strain due to the thermal mismatch between GaAs and polyimide. For a polyimide thickness of 50 μm the crack propagated in jolts. This allowed a rare peak at crack propagation. In FIG. 21 the crack propagated a distance about 350 μm under the GaAs before it stopped. When the thickness of polyimide was increased to 100 μm, the crack zipped through the wafer in a fraction of a second and no such picture could be taken. FIG. 20 shows an area about 2.5 cm×1 cm near the edge of GaAs (110) wafer where single atomic plane cleavage occurred.

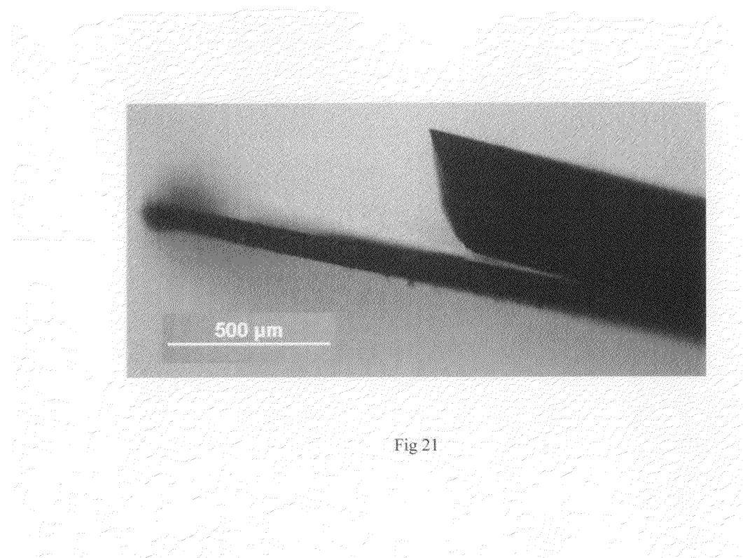

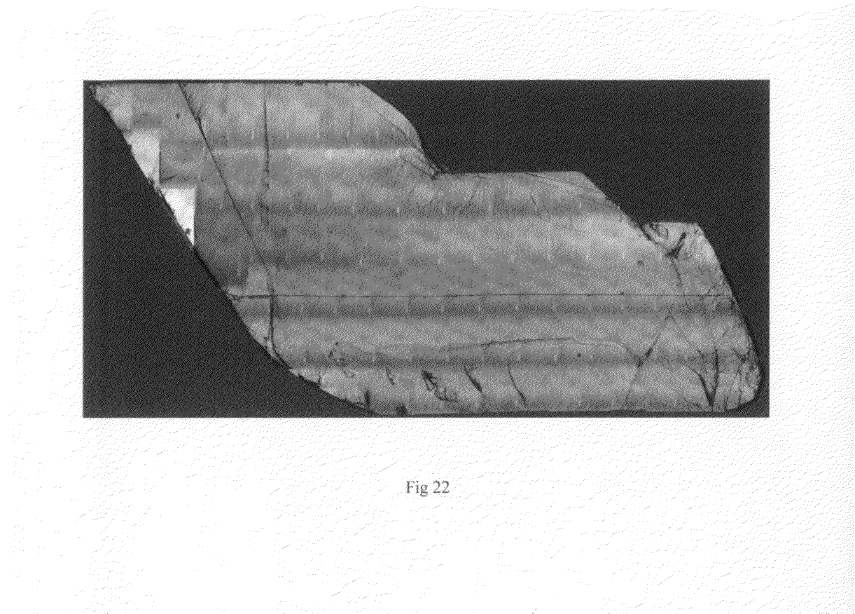

FIG. 15 above shows a picture taken with the optical microscope with 5× Magnification of one spot along the broken common edge in FIG. 20. FIG. 22 shows a map of the entire area of single atomic plane cleavage, about 3 cm×1.5 cm, obtained by stitching of more than 100 such pictures by scanning the wafer in the x-y plane. The single atomic plane cleavage extends over an area of a few cm² as confirmed by Zygo profilometer and AFM roughness measurements<1 nm, as shown in FIG. 6 and FIG. 16 above.

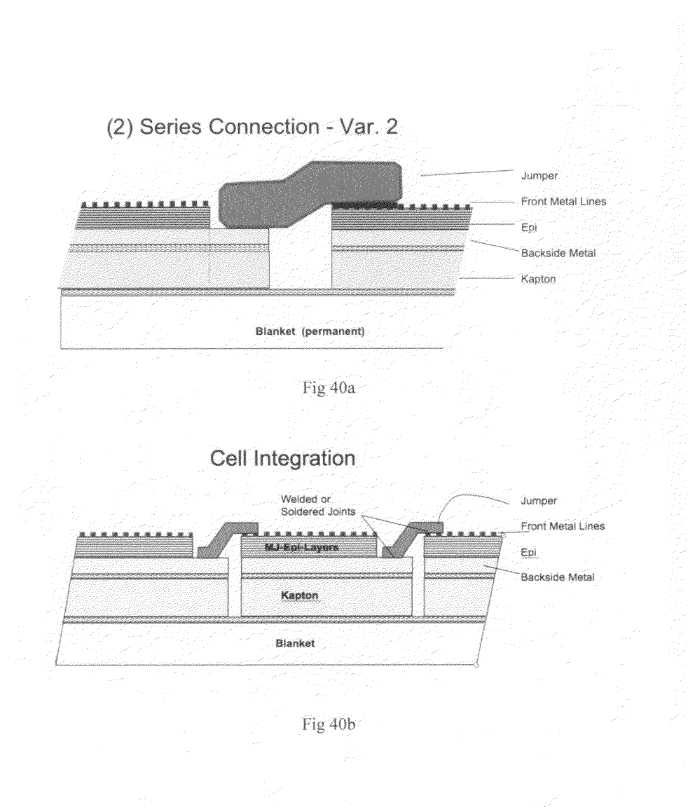

Kapton polyimide tape is used as the stressor layer and permanent carrier. The fragile solar cell is supported at all times. The use of Kapton is more advantageous than metallic substrates. The front side of the solar cell is processed on the Kapton after lift-off at temperatures that do not exceed 200° C. The process can be automated on a roll-to-roll basis because the driving force behind the crack is due solely to the thermal stresses without the help of any external force that must be applied manually to each individual wafer. Several, up to hundreds of GaAs 4″ wafers can be placed face down on a roll of Kapton up to tens of meters long and processed simultaneously. Scribing on the backside can also be automated because it does not involve scratching the edge of the wafer or using special tools. A scribing machine can be programmed with the exact load to yield precisely the desired scratch depth (20-40 μm) required to propagate the crack. The Kapton sheet holding the wafers can be folded at the seams and heated in an oven at 150-190° C. to cure the adhesive and then bathed in LN₂. The base wafers just pop-off the Kapton collectively and are recovered while the epi-layers remain on the Kapton sheet. The assembly is subsequently electroplated with copper and adjacent cells are connected in series or parallel. Both sides of the epi-layer solar cell can be contacted electrically from the top side of the wafer without going through the Kapton, as shown in FIG. 40a and FIG. 40b [13]. This automation process in conjunction with wafer reuse will reduce the cost significantly close to $50/W.

A single crack has been launched successfully competing with spontaneous crack nucleation. Uniform bonding and cleavage across 4″ wafer was demonstrated showing that a polyimide film can carry a thin epitaxial layer free of cracks; and the base wafer was saved in one piece and can be reused to grow another epi-layer. The depth of cleavage can be changed by varying the thickness of the polyimide. FIG. 23 shows the cleavage results for GaAs wafer (100) orientation. The substrate was reused multiple times and cleaved several layers from the same wafer. The following is the design process flow sequence: For a certain GaAs wafer thickness choose the thickness of polyimide based on the thickness of the epi-layer and the desired specific power ratio. This determines the level of stress in the substrate. Based on that, the scratch depth necessary to propagate the crack is calculated from the fracture toughness. A scribing machine is calibrated from the load vs displacement curve and programmed to yield this scratch depth and the process is automated. The process is easily scalable to large size arrays.

The technology is very simple. It only involves laminating using a desk laminator, scratching the backside, curing in an oven and cooling in liquid nitrogen and voila! The wafer separates in two pieces and the epi-layer is lifted-off onto the polyimide substrate.

The use of Kapton as the stressor layer is novel. It is very convenient to induce lift-off with a substrate that also serves as the final carrier of the solar cell because there is no need to dissolve or detach the substrate. By controlling the depth of cleavage precisely in conjunction with single atomic plane cleavage it is possible to lift-off exactly the thickness of GaAs that was grown epitaxially, so that the substrate remains at its original thickness after every lift-off. This allows up to 10 or more reuses of the substrate.

It is remarkable that single atomic plane cleavage was obtained from a hand scratch. This was not obtained with any of the other dry ELO techniques. It is desired to widen the area of single atomic plane cleavage and improve the quality of the cleaved surface and to minimize thickness variation. This requires more control over the crack path to determine exactly where it turns and how it transitions from a vertical crack to a horizontal crack. This can be accomplished either by scratching more precisely with a nano-indenter or by embedding a layer of lower fracture toughness at the desired depth to help guide the crack. This is necessary to facilitate processing the cleaved epitaxial layers into functional solar cells. The goal is to minimize the necessity to repolish the substrate and increase the number of substrate reuses.

Scratching with Nano-Indenter

The goal of scratching is to create a single dominant crack, which nucleates at higher temperature (−140° C.) and preempts the other cracks due to auto-nucleation (at −196° C.) from happening. The scratch must be deeper and sharper than any defect in the material. The critical stress intensity level is reached at the scratch first. A single crack was launched successfully without controlling the temperature very precisely by lowering the wafer slowly in the LN₂ Dewar. However, it is expected that controlling the crack parameters, such as scratch depth and temperature will yield more control over the crack path.

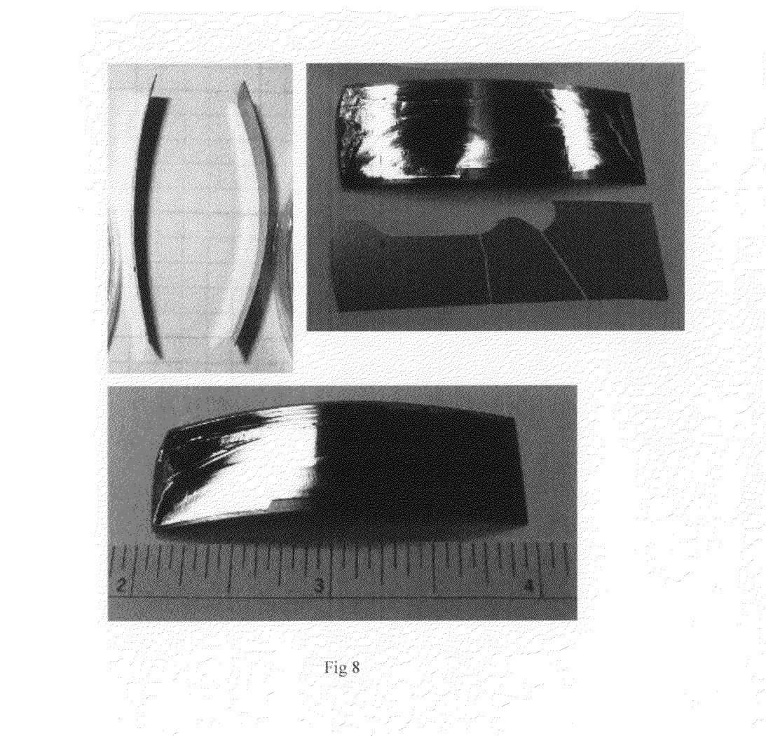

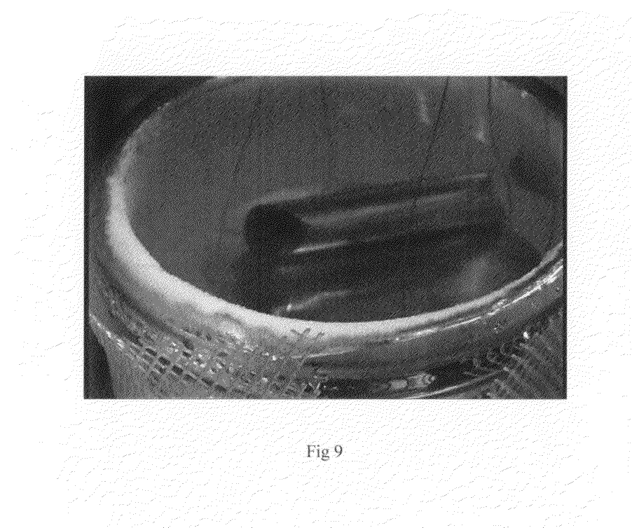

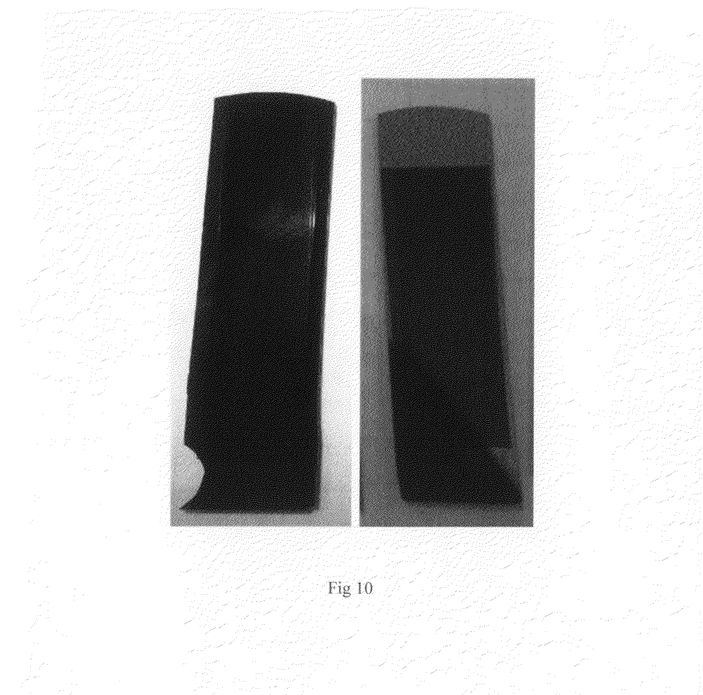

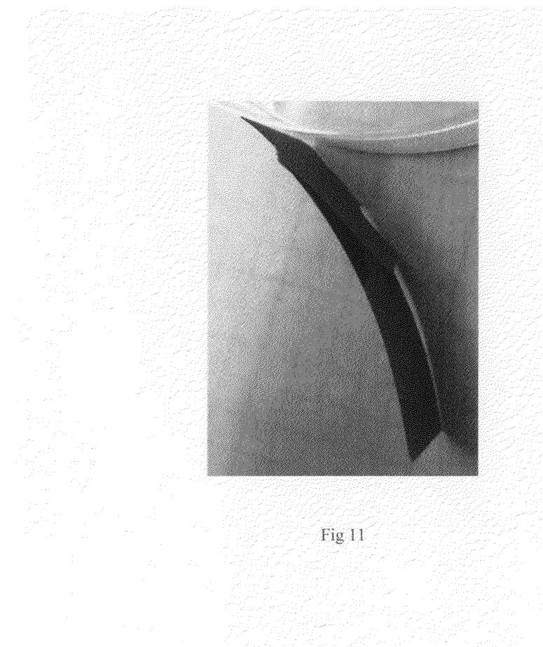

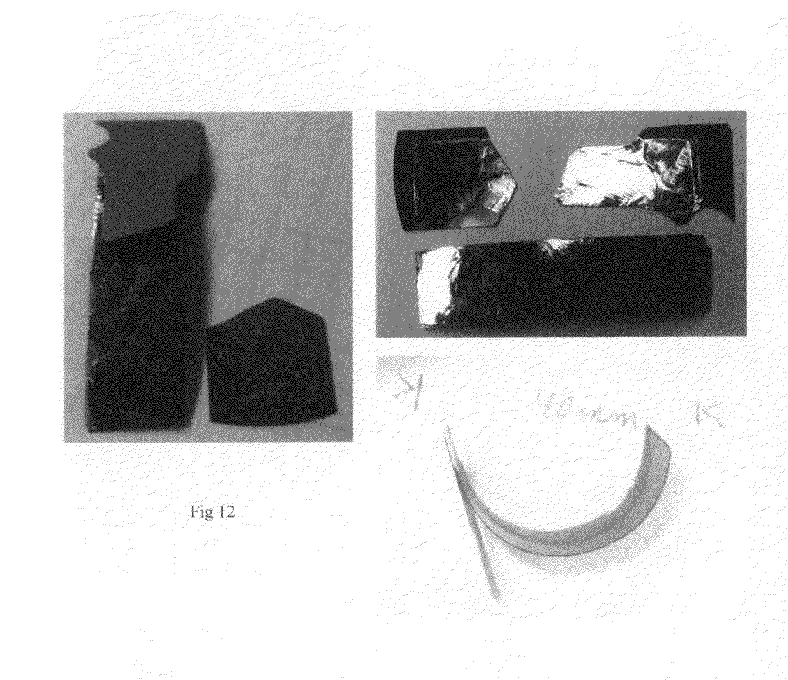

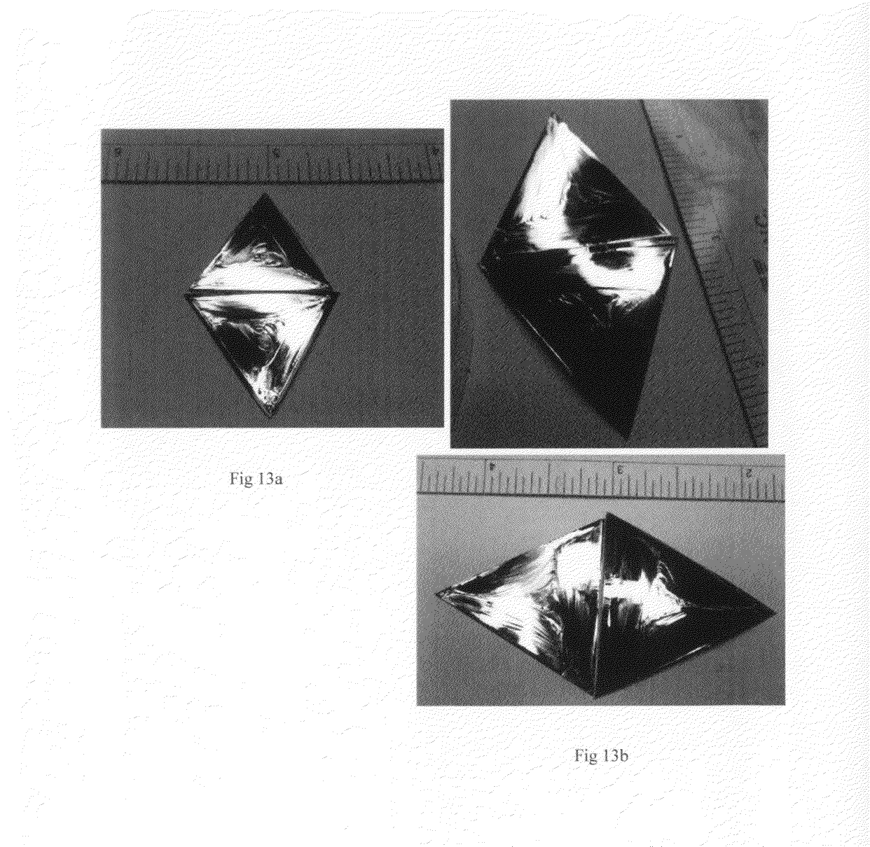

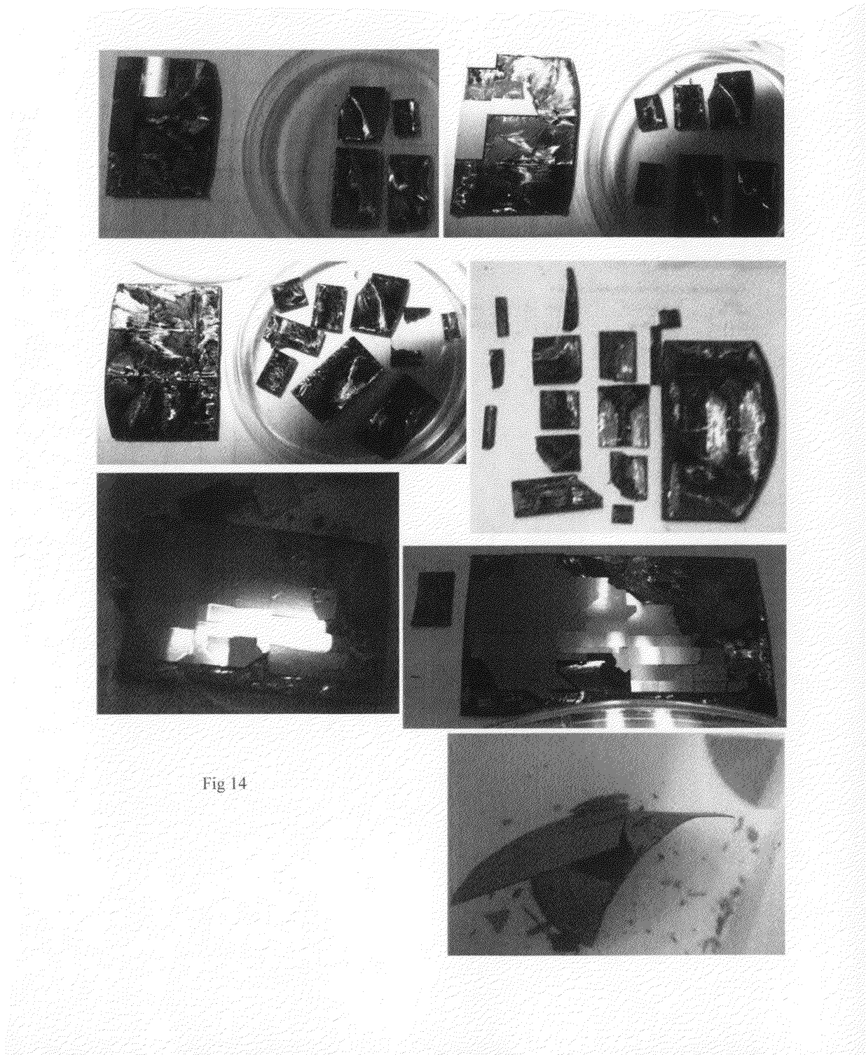

Single atomic plane cleavage was obtained over a limited area (>1 cm²) in spite of scratching by hand. A more precise scratch is obtained with a nano-indenter. In fact the nano-indenter can produce atomically smooth vertical surfaces [15,16,17] if the scratch is oriented along the <110> direction. Scratching with a nano-indenter produces a sub-surface damage known as a median crack under the plastic deformation which is seen on the surface, with a depth that varies as the load to the power^{2/3} [16]. A median crack size between 20 and 40 μm is desired. This requires a scratching load on GaAs between 70 and 200 mN using a diamond tip [16 see FIG. 8 on page 119]. A typical nano-indenter utilizes a Berkowich tip with a radius of 2.7 μm.

A median crack with a precisely controlled depth is required to obtain vertical single atomic plane cleavage. If the median crack is too small, catastrophic failure and uncontrolled crack propagation ensues. When the median crack reaches a critical depth, the fracture is controlled and the quality of the cleaved surface is greatly improved. This cannot be obtained by scratching with hand. The scratching load must be controlled very precisely within a narrow range in order to yield a median crack with the desired depth and avoid chipping [16]. If the load is below this range then only plastic deformation ensues. If it exceeds this range then chipping of the substrate occurs. The tip radius is also very important as it determines the shear stresses that cause dislocations and influences the depth of the median crack. The nano-indenter provides just enough energy to create the precursor median crack. The polyimide will initiate and propagate the precursor crack due to strain energy. The initiation is very difficult to control as the energy input to the system must be precisely controlled knowing with great accuracy the precursor crack. A thick polyimide initiated several cracks simultaneously from many nucleation sites and the cleavage was not controllable. This could circumvent the median crack. Therefore, it is important to know how the polyimide applies the load on the GaAs, in order to avoid the effort spent controlling the vertical scratch very precisely being wasted by the polyimide starting cracks at different locations. We were able to influence the cleavage and reduce the number of cracks by choosing the right thickness of polyimide. The thinner the polyimide, the thinner is the lifted-off thickness. The thickness of polyimide (50-100 μm) yields a depth of cleavage which coincides with the thickness of the epi-layer and satisfies the specific power ratio requirement.

There is no doubt that the crack started from the scratch and propagated vertically downward, stopped and turned horizontally, as can be seen from FIGS. 18-21. The goal is to control exactly where it stops and turns. One degree of control is the creation of the median crack but the horizontal crack does not proceed from the tip of the median crack. A median crack created very precisely using a nano-indenter will yield vertical single atomic plane cleavage, which leads to a horizontal single atomic plane cleavage.

The velocity of crack propagation also influences the quality of the cleaved surface. Cracks in brittle materials typically propagate at speeds ˜1-2 Km/sec which are up to 35% of the Rayleigh wave speed. In order to obtain single atomic plane cleavage it is necessary to slow down the speed of the crack. Any scribing machine can be used as long as it provides the desired load range on GaAs between 50 and 200 mN, where the load can be monitored accurately during scratching within a couple of milli-Newtons, and the tip radius and geometry can be precisely characterized. This allows the use of automated scribing machines that are used routinely in semiconductor wafer dicing, which lowers the cost of the scratching operation significantly.

### Crack Initiation on Front Side of Wafer

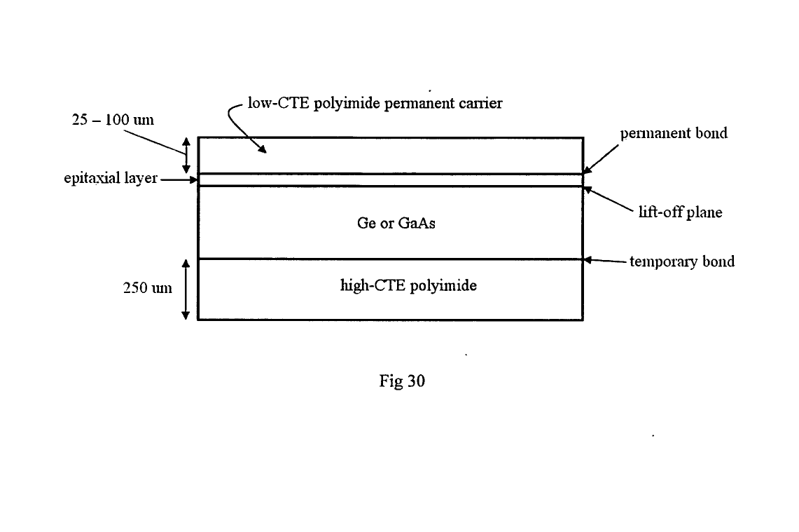

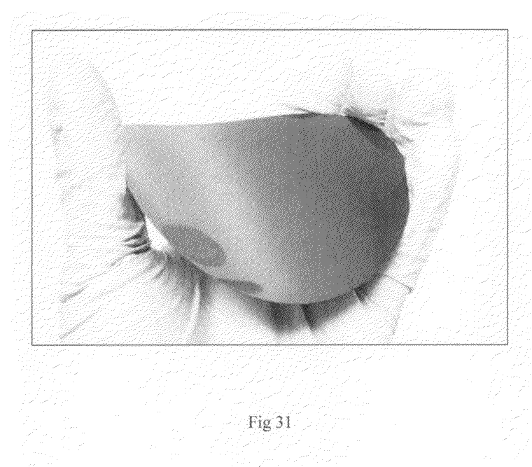

The crack starts propagating from the scratch on the backside of the wafer, as illustrated schematically in FIG. 19, vertically downward through most of the thickness of the wafer before it turns horizontally near the epi/wafer interface, as shown in FIG. 21. It is desired to avoid vertical crack propagation through the wafer and to confine the horizontal propagation near the surface where the crack started. This can be accomplished by using two polyimide substrates, one with high CTE and one with lower CTE, as illustrated in FIG. 30. The high-CTE polyimide substrate is referred to interchangeably as the polyimide wafer shown in FIG. 31.

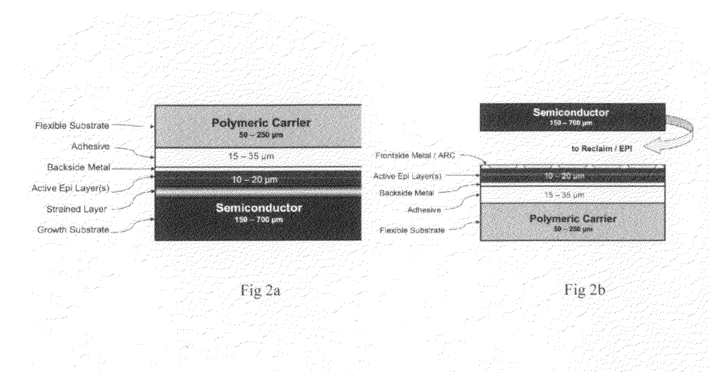

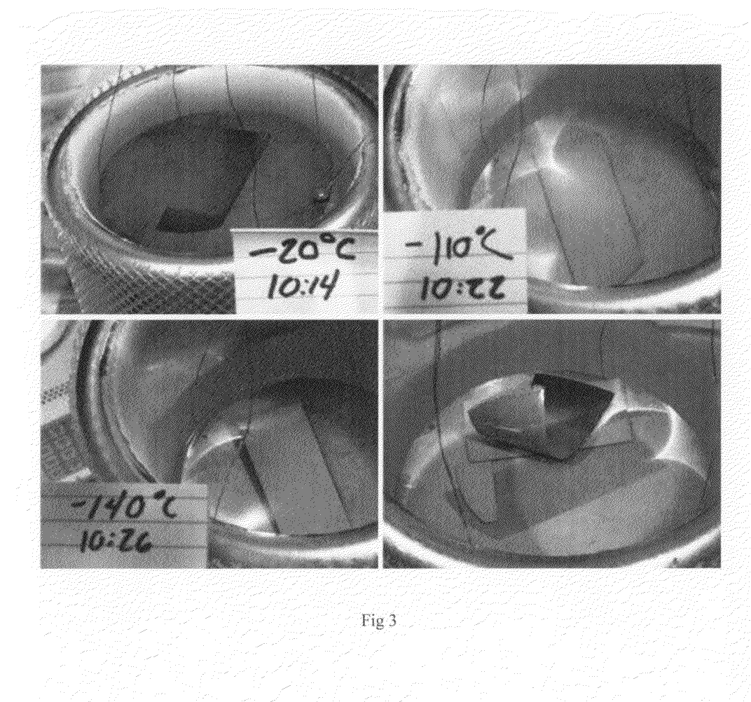

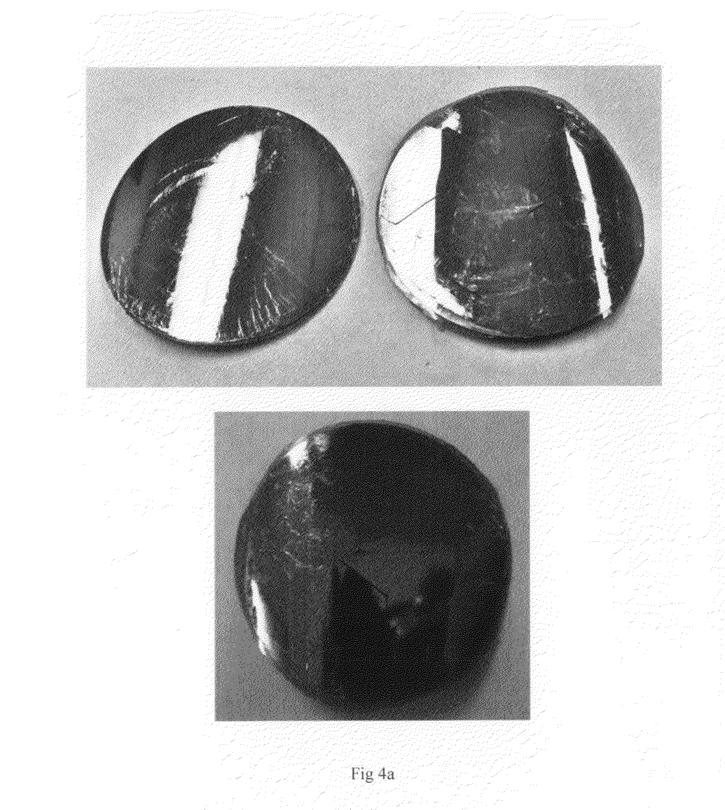

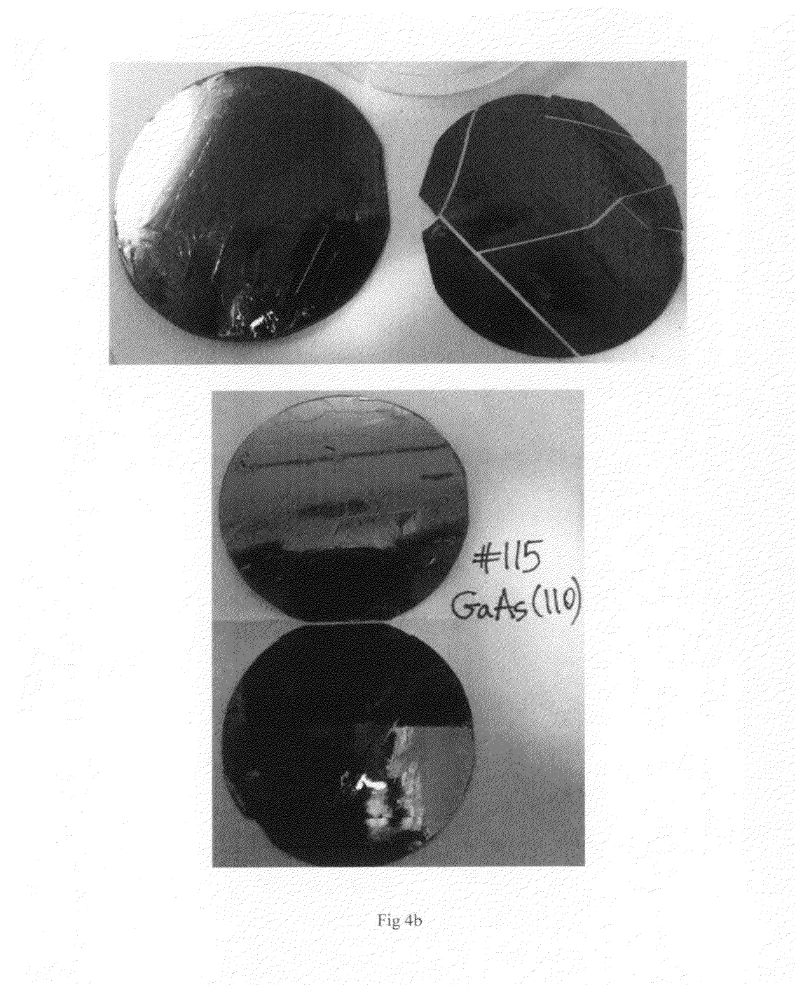

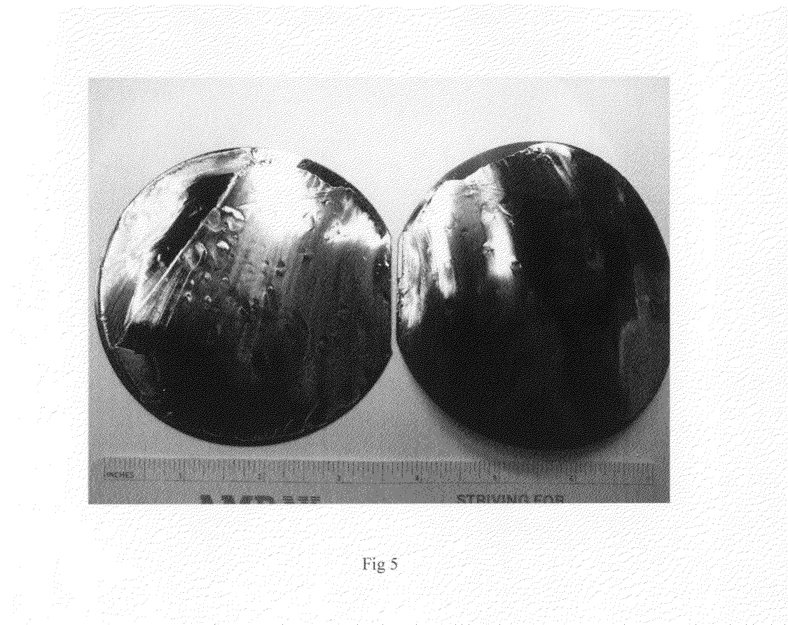

The lower-CTE substrate is made of Kapton which is bonded to the epi-side and serves as the permanent carrier of the thin epi-layer after lift-off. The wafer is bonded to a high-CTE polyimide substrate on the opposite side away from the epi. The polyimide wafer has a CTE of 54 ppm/° C. and thickness of about 250 μm, which is optimized to deliver the maximum bending stresses for a typical semiconductor wafer about 175-200 μm used for PV applications. The thickness of the polyimide substrate can be adjusted arbitrarily and continuously to deliver the maximum punch if thicker semiconductor wafers are used because the polyimide substrate is sliced from ingot. The high-CTE polyimide induces the lift-off. The wafers are bonded using adhesive layers. The bond to Kapton is permanent, whereas the bond to the high-CTE polyimide substrate is temporary and is dissolved after each lift-off so that the high-CTE polyimide substrate can be reused to lift-off another epi-layer. It is intended that the wafers separate at the epi/wafer interface so that the epi-layer remains permanently attached to the Kapton, as shown schematically in FIG. 2. The high-CTE polyimide substrate is detached from the base wafer by dissolving the temporary adhesive. Both the semiconductor wafer and the high-CTE polyimide substrate can be reused to grow another epi-layer for another lift-off.

The process of lift-off starts by laminating the Ge or GaAs wafer to Kapton and polyimide wafer and then heating to a temperature between 150 and 190° C. for about an hour to activate and cure the adhesives. The lamination using a hot roller takes only 30 seconds and can be repeated a few times to strengthen the bond. After bonding, the wafers are ready for lift-off. The temperature is lowered by introducing the bonded wafers in a Dewar of liquid nitrogen at −196° C. Lift-off happens naturally as the wafers reach a certain temperature without applying any external force or pressure. The wafer cleaves spontaneously at a plane parallel to the bond interface when the temperature is reached. An audible crack is heard and the film snaps right off in a fraction of a second. The entire process takes only a couple of minutes. This process is called dry epitaxial lift-off or DELO to differentiate it from other techniques that require ion implantation, high-temperature annealing or wet etching. DELO also applies to non-epitaxially grown solar cells and to any circuit layer in general. The polyimide substrate can cleave a layer of a certain thickness from a semiconductor wafer regardless of whether it contains an epi-layer or an active electronic circuit or not. Kapton can cleave a layer on its own; however, the crack may propagate through the majority of the thickness of the semiconductor wafer. When a polyimide wafer with a higher CTE is bonded temporarily on the backside opposite the Kapton, the crack is confined near the Kapton, thus limiting the depth which the crack traverses through the wafer.

The polyimide wafer has a high CTE of 54 ppm/° C. which lowers the temperature drop necessary for lift-off. The polyimide is tough and can withstand temperatures from 300° C. down to −196° C. The adhesive is applied uniformly. The surface of the polyimide wafer does not have to be polished. It can be ground or lapped and still supports the epi-layer over the entire 4″ diameter. The front side of the solar cell can be processed on the Kapton after lift-off. The high-CTE polyimide substrate is described in U.S. Pat. Nos. 6,563,998; 6,807,328; 7,512,297; and 8,107,777. A polished 4″ diameter polyimide wafer 250-500 μm thick is shown in FIG. 31.

FIG. 32 shows a Si (111) wafer which auto-cleaved along two parallel lines without scratching the surface prior to cooling. The lines make an angle of about 30° relative to the flat of the wafer. The wafer was bonded to polyimide substrate and lowered in LN₂. Two spontaneous vertical cracks developed within a couple of minutes after immersion. The vertical cracks stopped at a distance of about 30-40 μm from the polyimide surface and proceeded horizontally toward the edge of the wafer. Two pieces of silicon remain hanging from the edge of the wafer. Underneath these pieces the surface is very smooth across the wafer. This provides conclusive proof that the horizontal crack does not initiate from the edge of the wafer toward the center, rather starts from a vertical crack and travels toward the edges of the wafer.

FIG. 18 shows schematically the bending stresses that the high-CTE polyimide substrate applies on the semiconductor wafer. As the temperature drops, the polyimide shrinks at a higher rate than the semiconductor. The polyimide applies pure bending moment and compressive axial stresses (no shear) on the semiconductor wafer. The stresses are tensile in the upper half of the wafer above the neutral axis and compressive in the lower half near the polyimide wafer. A crack starts in the epi-layer under the Kapton and propagates vertically down toward the polyimide wafer, in the absence of shear stresses. However, as the crack approaches the neutral axis and enters the region of compressive stress it stops and turns horizontally. The mode I stresses drop to zero as the mode II (shear) stresses rise which cause deviation of the path of the crack by 90°. If the wafer is not scratched, i.e. in the absence of a dominant crack, then several spontaneous cracks initiate at defects on the side of the wafer under tensile stress and stop at about the same depth because the polyimide wafer applies a uniform state of stress across the wafer, i.e. the bending moment remains constant along the wafer. Isobaric planes of constant stress run parallel to the surface of the wafer. All the vertical cracks terminating at roughly the same height connect horizontally. This gives rise to the horizontal cleavage.

FIG. 33 shows very clearly that the cracks start under the Kapton. The piece to the right is the base semiconductor wafer on polyimide wafer.

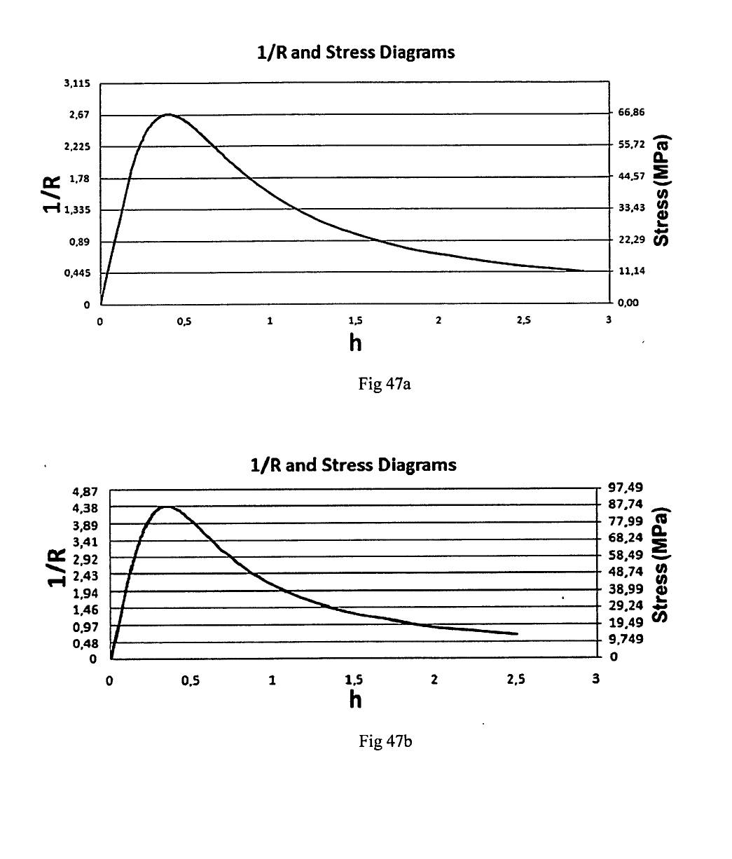

From biaxial stress and beam theory the maximum bending stress that a polyimide substrate applies on the GaAs wafer at the onset of crack initiation is about 66-86 MPa depending on the thicknesses of GaAs and polyimide substrate, as can be seen in FIG. 47a in the Appendix below. Given that GaAs has a Young's modulus of 86 GPa, this corresponds to a strain of 0.1%. The fracture strength of GaAs is 2.7 GPa, which corresponds to a strain of 3%. Thus, the stress concentration factor at the tip of the crack is about 30.

Under the right initial conditions a region with compressive stress can stop a crack and even guide it. In GaAs the preferred cleavage plane is <110>. So if a crack encounters a barrier along the <110> direction because it cannot penetrate a compressive zone then it will simply turn 90° and continue its path along the interface. According to Griffith's criterion which forms the basis for fracture mechanics, the initial elastic strain energy is equal to the energies of the two surfaces created after the crack has propagated plus the residual strain energy. This is used to predict the depth of the cleavage plane as shown in the Appendix.

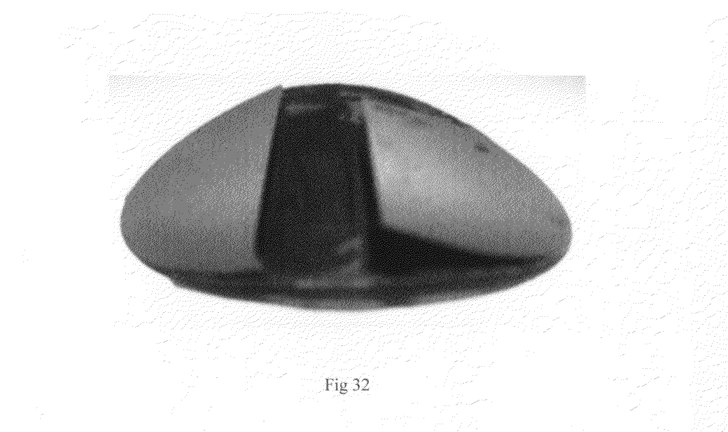

It is well known that one can induce a vertical crack to propagate through the thickness of the wafer by scratching the surface and cleaving manually. This is routinely used to cleave mirror-like facets of laser diodes. If a silicon wafer unscratched is bonded to a polyimide wafer on the back side and introduced gently in a container of liquid nitrogen and left alone to reach thermal equilibrium at −196° C. then it will curl and start cracking audibly within a couple of minutes. A GaAs or Ge wafer would start cracking at −140° C. because it is more fragile than Si. If the polyimide is too thick, i.e. if the strain energy is too high, then the base wafer will shatter into many small pieces and a contiguous layer of semiconductor will remain stuck to the polyimide. If liquid nitrogen is poured on it then it will shatter instantaneously due to the non-uniform thermal gradients. This is auto-initiation. However, if the thickness of the polyimide is just right and the backside of the wafer is scratched with the right depth and tip radius then the base wafer will separate in one piece. We compete with auto-initiation by scratching the wafer at a prescribed location so that the crack starts propagating under the scratch at a higher temperature before all the other auto-initiated cracks have the chance to start, thus, preempting all the other cracks. The polyimide substrate opens the crack due to tensile stress by bending, which is the preferred mode of opening. It is preferable to avoid crack propagation through the thickness of the wafer and to confine the crack near the surface where it started. Thus, the polyimide wafer must be used only to initiate the crack on the opposite side and a second mechanism should be used to stop it before it travels through the wafer. A compressively strained pseudomorphic layer, such as InGaAs, grown under the epi-layer can be used effectively to stop the crack within a few microns from where it started, as shown in FIG. 34a. However, care must be taken not to scratch through the strained layer. For this reason it would be advantageous to use front-side referenced scribing such as the stylus of an AFM which is independent of wafer thickness variation.

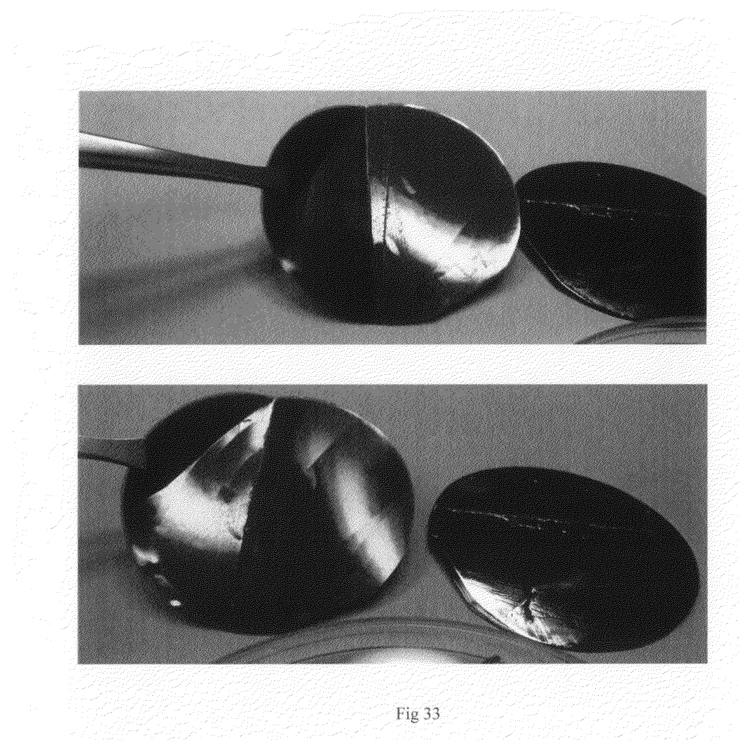

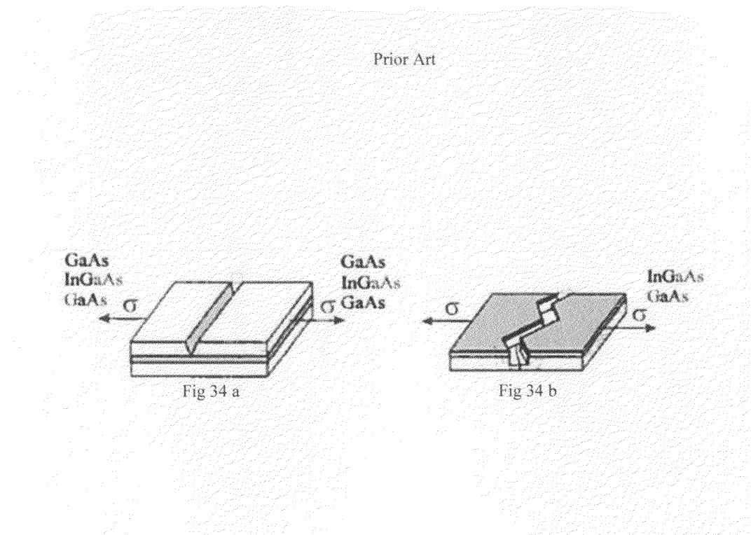

Ideally the wafer is scratched near the edge parallel to the flat to minimize wafer area loss, as shown in FIG. 20. However, since a solar cell for space does not occupy the whole wafer, as shown in FIG. 35a, it can be scribed along the edge of the cell. FIG. 35a shows a solar cell for space which measures 6.6 cm×4 cm bonded to a 4″ diameter polyimide wafer (half circle) on one side and Kapton on the other side. FIG. 35b shows the base GaAs wafer on the polyimide wafer and the epi-layer on the Kapton after lift-off.

After transfer, the anti-reflective coating (ARC) and wire grid electrode are deposited on the front side of the solar cell on the Kapton. The base semiconductor wafer is recycled by polishing the surface to remove any remains of the release layer, and is ready for the next epitaxial growth thereby completing the manufacturing cycle.

The two main design parameters of DELO are the thicknesses of the polyimide and semiconductor wafer. The stresses depend on the elastic modulus of the semiconductor material and on the ratios of the elastic moduli and thicknesses of the wafers, as can be seen from equations (6-9) in the Appendix. The radius of curvature depends on the thickness of the polyimide substrate and on the ratios of the elastic moduli and thicknesses of the wafers, as can be seen from equation (5).

### Crystallographic Orientation

GaAs (110) wafers yield smoother, thinner and more uniform cleavage with less surface variation than (100) wafers. However, solar cell manufacturers are reluctant to grow on (110) wafers because most of the III-V industry is built on (100) wafers, albeit with some deviation up to a few degrees.

{100} planes and {110} planes are orthogonal to each other. Thus a {110} plane is obtained by rotating a {100} plane by 90° about a <110> axis. Therefore, tilting the (100) plane by 15° toward the (111)A plane brings it closer to the {110} plane, which makes it easier to cleave than a perfectly aligned (100) wafer.

Embedded Layer with Lower Fracture Toughness

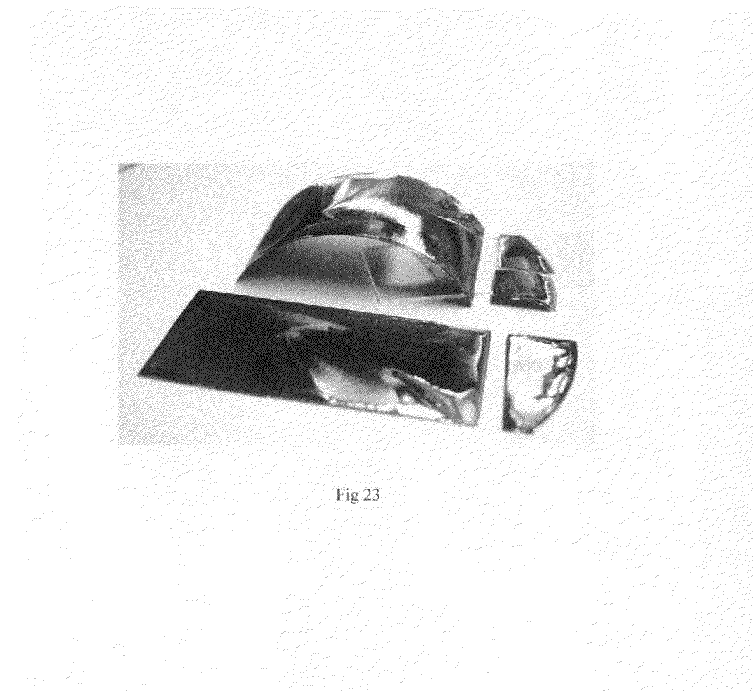

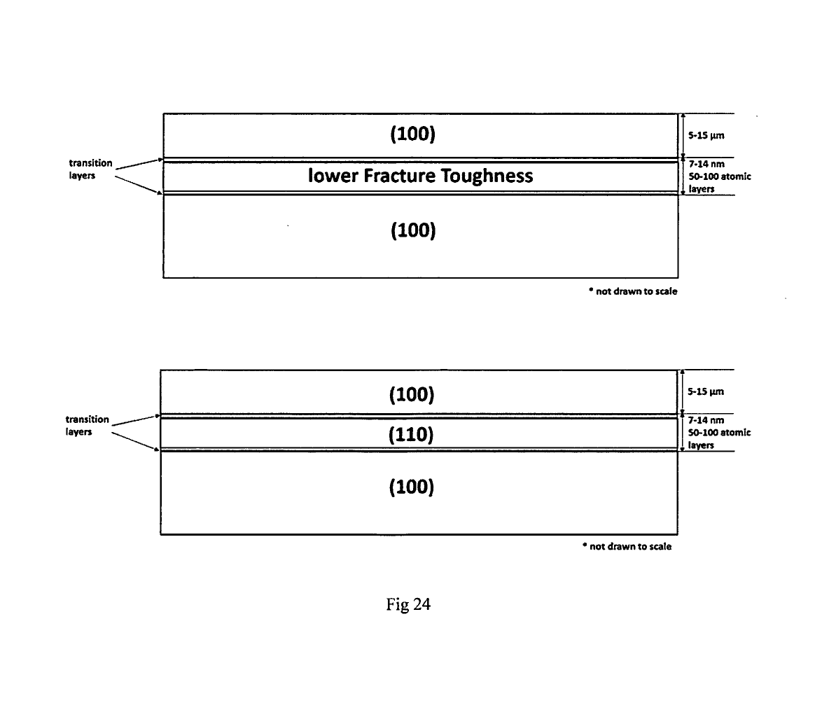

As it was observed that a (110) wafer cleaved much smoother and thinner than a (100) wafer, because it has lower fracture toughness, this leads to the concept of embedding a nano-layer of lower fracture toughness, such as GaAs (110), at the desired depth in a (100) wafer. It is known that the (110) orientation in GaAs is the preferred cleavage plane because it has lower fracture toughness. The concept is illustrated in FIG. 24. The requirements on such a layer are that it must be epitaxially grown, preferably lattice-matched to the substrate in order to grow a thick single, dual or triple junction on top of it. The epi solar cell must not feel the presence of the embedded layer underneath it, as if it were grown directly on the (100) wafer. The nano-layer can be as thin as 50-100 atomic layers, which is below the critical thickness. The purpose of the nano-layer is to guide the crack. The nano-layer can be made of tertiary compounds of In, Ga, P and As and may be strained because it has a different lattice constant than GaAs. InGaAs, for example, which is commonly grown on GaAs with strain up to 3% is not suitable because its fracture toughness is higher than GaAs.

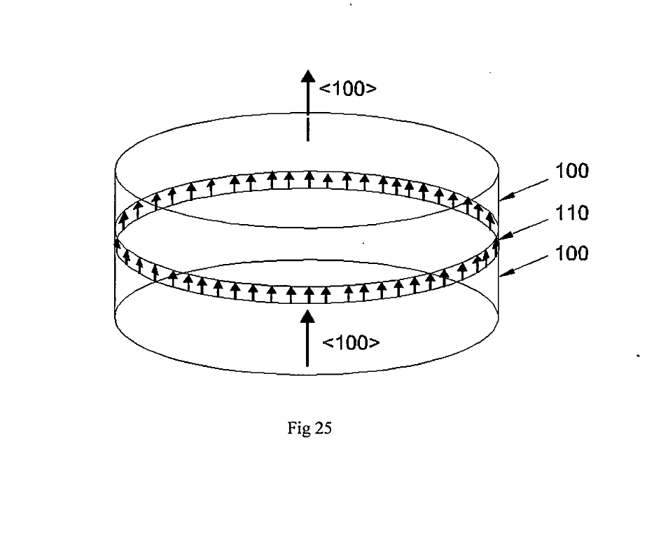

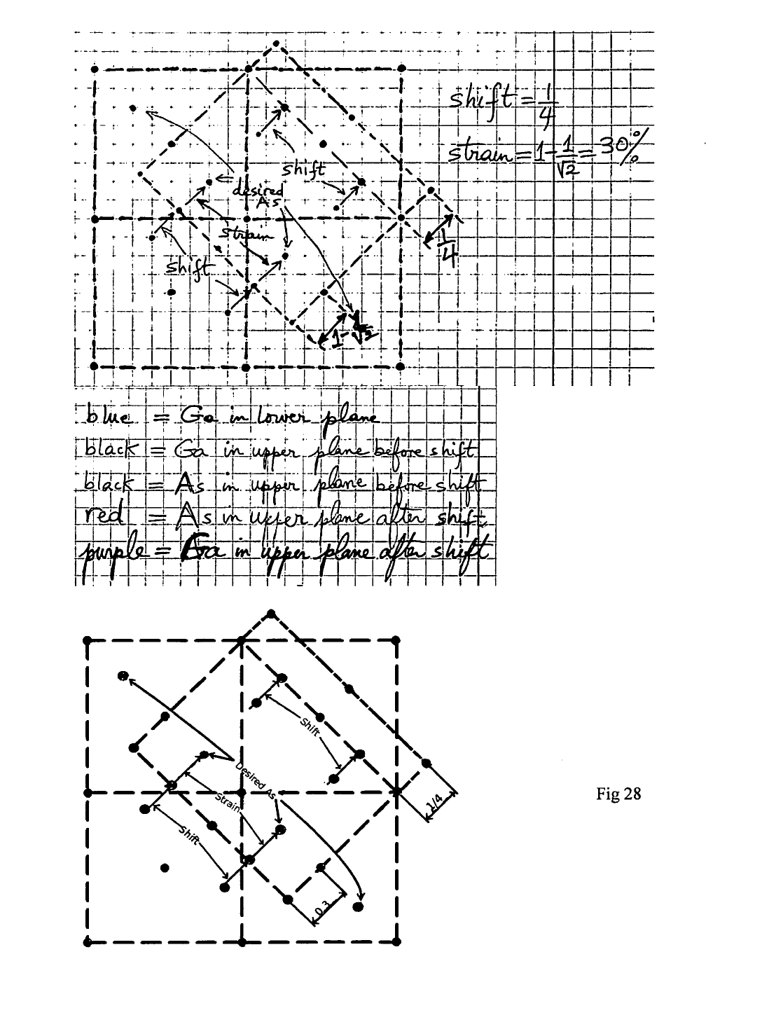

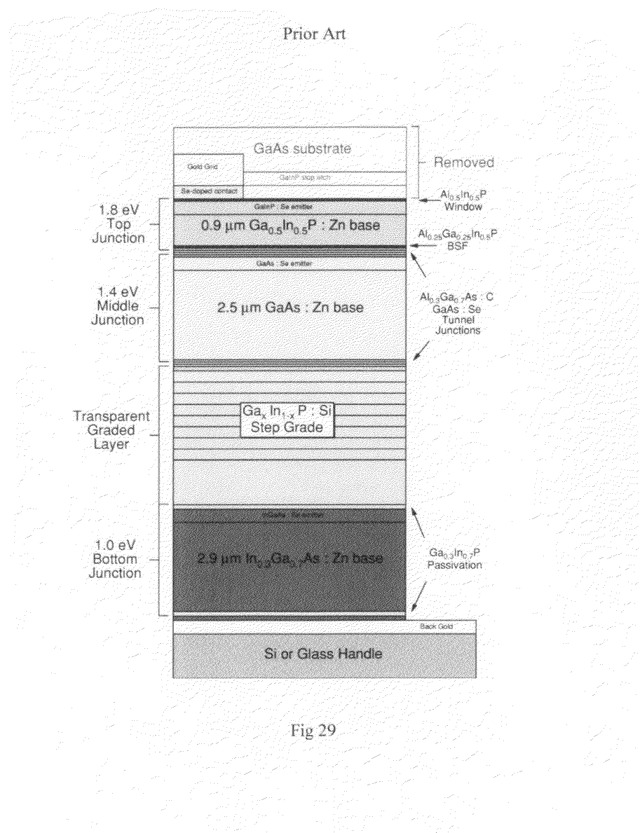

FIG. 25 shows schematically a GaAs (110) nano-layer embedded in a GaAs (100) wafer. The large <100> vectors of the bottom substrate and upper solar cell layer are vertical perpendicular to the surface. The <110> vector of the embedded layer is also vertical inside the (100) wafer. Such a layer would be strained because the film and substrate have different orientations even though they are both made of the same GaAs crystal and have the same unit cell because the distance between successive (110) planes is smaller than that between (100) planes by a factor of \sqrt{2}. This can be eased with the use of transition layers, as shown in FIG. 28, which absorb the strain and transition the “lattice constant” from (100) to (110) and back to (100), so that the sacrificial embedded layer of lower fracture toughness is not strained. The strain in the transition layers can reach up to 30%.

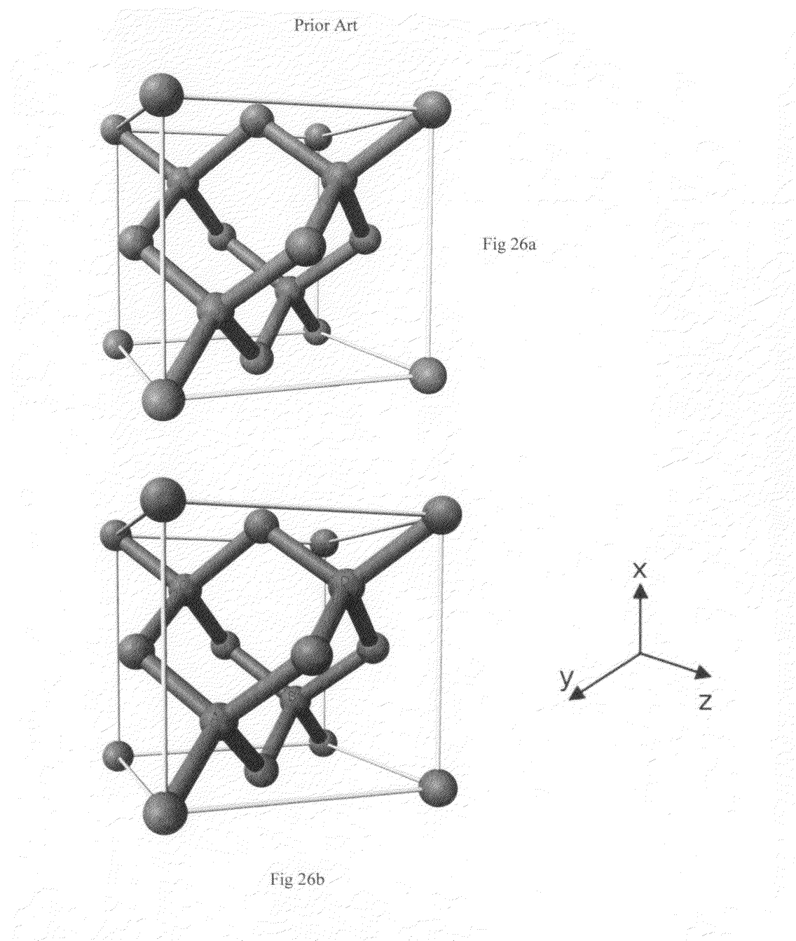

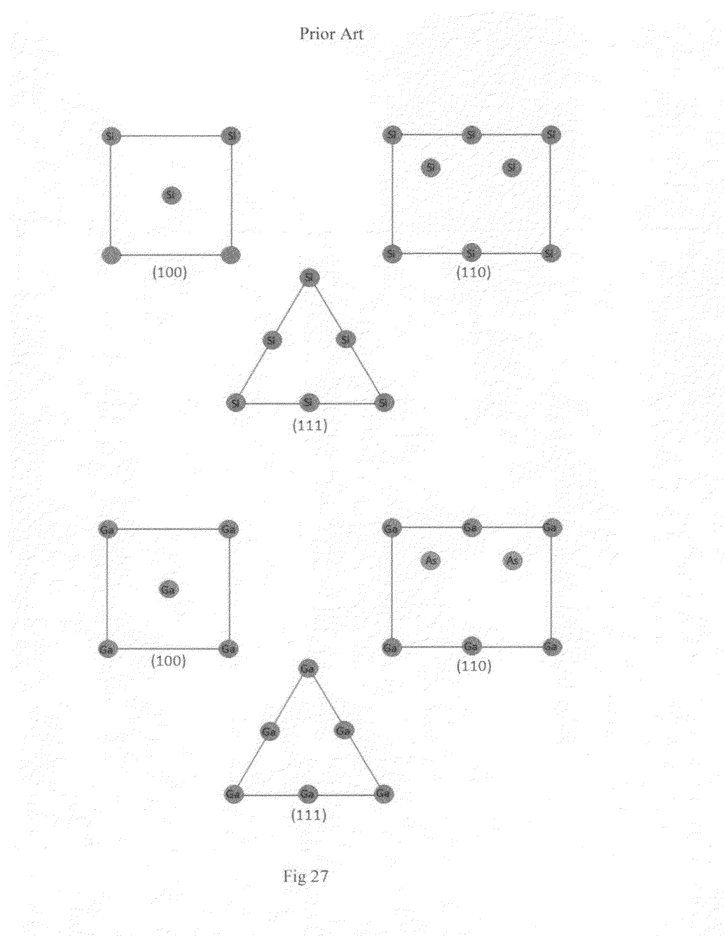

FIG. 26a and FIG. 26b show the unit cell of GaAs which is based on the face-centered cubic diamond structure. The brown spheres represent Ga atoms, the purple spheres As atoms and the links in between represent covalent bonds. The unit cell can alternatively and equivalently be represented by shifting the unit cell by one-quarter of the distance between Ga atoms along each of the x-y-z axes, i.e. along the <111> direction. Then the Ga atoms replace the As atoms and vice versa. FIG. 27 shows the atomic arrangements in the three plane cross-sections (100), (110) and (111) for Si and GaAs, respectively. Similarly, in this figure the locations of the Ga and As atoms can be switched and yields equivalent representation. The unit cell has a 1×1 square cross-section in the (100) plane, whereas the (110) cross-section is a \sqrt{2}×1 rectangle. Thus, if a (110) oriented film is to be grown on a (100) wafer then the rectangle must be superimposed on the square while trying to coincide the As atoms in the (110) plane with the locations where the Ga atoms in the (100) plane expect them to be. FIG. 28 shows the (110) plane cross-section (black rectangle) rotated by 45° and superimposed on the (100) plane cross-section (blue square). The two black dots represent the As atoms. The purple rectangle is the same (110) plane cross-section shifted in the plane by one-quarter of a unit cell along a <110> vector so that the As atoms (two red dots) occupy the locations where the Ga atoms in the lower plane expect them to be. This out-of plane rotation by 45° followed by in-plane translation of ¼ of a unit cell is equivalent to pivoting around the axis passing through the A and B Arsenic atoms in FIG. 26b by 90°. Consider the vertical (01-1) plane parallel to the x-axis and passing through points A and B in FIG. 26b. The corresponding [01-1] vector is in the y-z plane. A rotation about the A-B axis by 90° would point this vector vertically parallel to the x-axis. This accomplishes the goal of making the <110> vector vertical. Similarly, a rotation of 90° about the C-D axis would turn the (011) plane passing through points C and D so that its associated [011] vector points vertically upward parallel to the x-axis. While rotations of 90° about axes A-C or B-D would point <110> vectors parallel to the y-axis; and rotations of 90° about axes B-C or A-D would point <110> vectors parallel to the z-axis. This is called coincident epitaxy, when some but not all lattice points of the film coincide with lattice points of the substrate [20 page 5].

A subset of {100} planes and {110} planes make an angle of 45° with respect to each other. For example, the (101) plane passing through Arsenic atoms A and C in FIG. 26b is inclined by 45° relative to the horizontal (100) y-z plane. However, it is not possible to rotate this plane by 45° to align it with the (100) plane. A {110} plane must be rotated by 90° as mentioned above in order to create a (110) embedded nano-layer inside a (100) wafer. Alternatively, this can be accomplished by bonding a (100) wafer to a (110) wafer and thinning. However, it is not possible to thin a (110) wafer down to a nano-layer. It is desired to accomplish the embedded structure through epitaxial growth.

Besides shifting the plane by one quarter of a unit cell the atoms must be dragged by an additional amount of {1−1/\sqrt{2}}≈0.3 to coincide the lattices, as shown in FIG. 28, i.e. the transition layer must be strained by 30%. This is a rather large strain. It is desired that the strain be absorbed within the first 5-10 atomic layers on each side so that the inner 80-90 atomic layers of the (110) film are unstrained.

A (100) GaAs surface is naturally biased to grow a (100) epi-layer. However, if the As atoms are placed at locations A and B in FIG. 26b, where the Ga atoms expect them to be, then the (100) surface cannot tell whether the film grown on top of it is (100) or (110). However, even if the As atoms are perfectly aligned with their host Ga atoms for one unit cell, they will not be for the adjacent cells because the distance between adjacent planes for (100) and (110) orientations differ by a ratio off and the (100) and (110) lattices are rotated 45° with respect to each other. The Ga and As atoms will coincide naturally (without strain) every integer multiple of \sqrt{2}. But the problem is that \sqrt{2}=1.414213562373 is not a rational number, i.e. it is not the ratio of two integer numbers. Thus, depending on the degree of approximation the unit cells of (100) and (110) will align every 14 or 141 or 1414 or 14142 unit cells, etc. Thus, in order to coincide lattice points of the film with lattice points of the substrate naturally it is necessary to skip 13 or 140 unit cells etc, hence coincident epitaxy. Thus, not all the Ga atoms are covalently bonded to As atoms, which will facilitate lift-off.

However, the problem is that the location of the As atoms cannot be controlled precisely during epitaxial growth. It is very difficult to grow such a layer using current MBE or MOCVD equipment. Even techniques such as Atomic Layer Epitaxy where one atomic layer is grown at a time, for example only Ga atoms first then As atoms next, cannot afford the level of control required to write single or groups of atoms on an epitaxial surface. Epitaxial growth is very sensitive to the group V/group III ratio. A certain ratio must be maintained to obtain optimal growth conditions. GaAs surfaces are generally described as either Ga-rich or As-rich. As-rich surfaces are easier to grow on because the sticking coefficient of As atoms on As-rich surfaces is always nearly 100%. However, the delicate balance comes in when the surface is Ga-rich.

It is worth noting that this concept is different from the porous silicon “weak” layer approach spear headed by IMEC and others because there is no vertical force to separate the epi-layer. The embedded layer is weaker than the (100) GaAs substrate in the sense that it has a slightly lower fracture toughness but it is still a solid epitaxially grown layer which forms the basis for the thick solar cell grown on top of it.

### Metallization of the Front Side

The cost of fabricating the front side of space solar cells accounts for 30% of the cost of the cell. Thus, the cost of metallization must be reduced in order to meet the target cost requirement of $50/W. Alternative cheaper techniques can be used to write the metal lines and bus bar because a solar cell for terrestrial applications does not have to last as long as 15 years as in space. Ag is the main metal used for III-V solar cells. A very thin Cr layer is used to enhance the adhesion of Ag to GaAs and the Ag is encapsulated on both sides with a thin layer of Au which acts as barrier and prevents diffusion of the Ag into the GaAs. The metals are patterned using a lift-off process. The wafer is covered with a patterned photoresist and the metal is deposited usually by evaporation. Subsequently, the residual photoresist is developed leaving the metal lines on the surface. No transparent conductive oxide is needed because Ag has good lateral conductivity. The metal grid lines are typically 11 μm wide and 5 μm high. Screen printing is an inexpensive technology which is used for interconnecting silicon solar cells but does not have the required resolution either vertically or laterally.

Aerosol jet printing, produced by Optomec in Albuquerque N. Mex., is a cost-effective maskless non-contact direct-write metallization technique which has been used for high efficiency solar cells [18]. It uses additive technology and inks containing metallic nano-particles to build up metal lines with widths below 10 μm layer by layer. It is applied at low temperature and is particularly suited for non-planar surfaces and flexible substrates which present challenges regarding stretching and potential cracking of the metal lines. The flexible substrate is held flat on a vacuum chuck while writing. It is an emerging alternative to traditional photolithography and has much higher resolution than inkjet. A pulsed flash lamp is used to fuse the metallic nanoparticles and cure the inks similar to rapid thermal annealing. A Novacentrix flash curing unit is used in conjunction with aerosol jet printing for roll-to-roll processing.

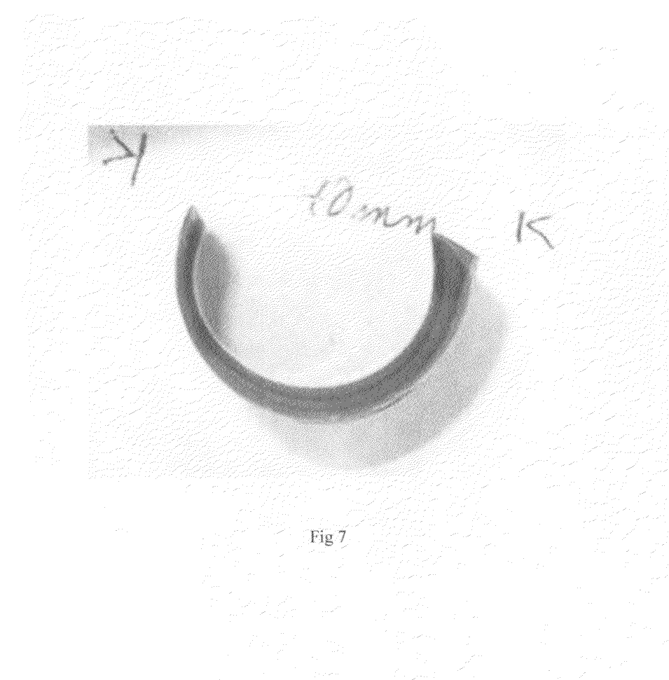

The front side of the solar cell is processed at a temperature that does not exceed 200° C. Good efficiency and fill factor were obtained from solar cells processed on flexible substrates without loss in performance compared to the original substrates [see FIG. 7 in 19].

Electron imaging tools such as SEM, TEM, X-ray diffractometry and cathodo-luminescence (CL) and dissecting tools such as focused ion-beam milling (FIB) can be used to study the composition of layers. SEM can be used to examine the FIB cross-sections of median cracks. TEM can be used to reveal microscopic defects in the layers.

The GaAs wafer can be scratched with a nano-indenter, such as the one made by CSM in Peseux, Switzerland, or by Hysitron in Minneapolis, Minn., or by Nanovea in Irvine, Calif. The applied load can be correlated to the median crack size while avoiding the creation of radial and lateral cracks, which are responsible for chipping. A knoop type indenter, such as Vickers, rather than a conical tip can be used as it yields better control over the crack in brittle materials. Different tip radii can be used. The tip radius can be measured and the size of the defect can be calibrated vs radius. Scratches can be made along different crystallographic directions. The goal is to calibrate the depth of the median crack vs load and to observe the effect of the crystallographic orientation. FIB can be used to dissect parallel and perpendicular to the scratches.

A more precise control over the temperature may result in better control over the propagation of the crack. The wafer is instrumented with a thermocouple which measures the temperature as it is lowered in the LN₂ jar.

When an unmetallized GaAs wafer is bonded to Kapton, the adhesive holds its grip in LN₂ and the crack propagates in the GaAs wafer. However, actual solar cells are capped with a blanket metal layer on top of the epi-layer, which forms the backside contact after lift-off. The adhesive layer is in contact with the metal layer. The adhesion to metal is improved to prevent delamination at the metal/epi interface.

A process for achieving single atomic plane cleavage wafer scale and a cost-effective metallization scheme for processing the front side of a solar cell is presented. The effects of thermal stresses and crack propagation on the performance of the solar cell are minimized. Roll-to-roll processing, i.e. simultaneous cleavage of several cells mounted on one large sheet of Kapton, and reclaim of the substrates. Several cells are interconnected using copper plating to produce flexible panels with output power that exceeds 20 W. This lift-off technology has applications for space and terrestrial solar cells and is qualified for space.

### Integration and Packaging of III-V Solar Cells

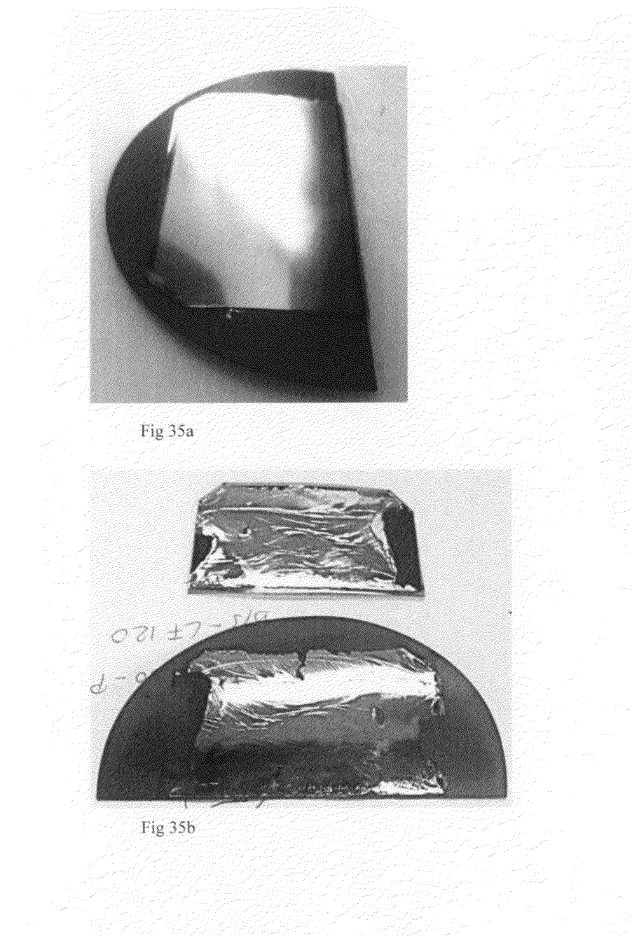

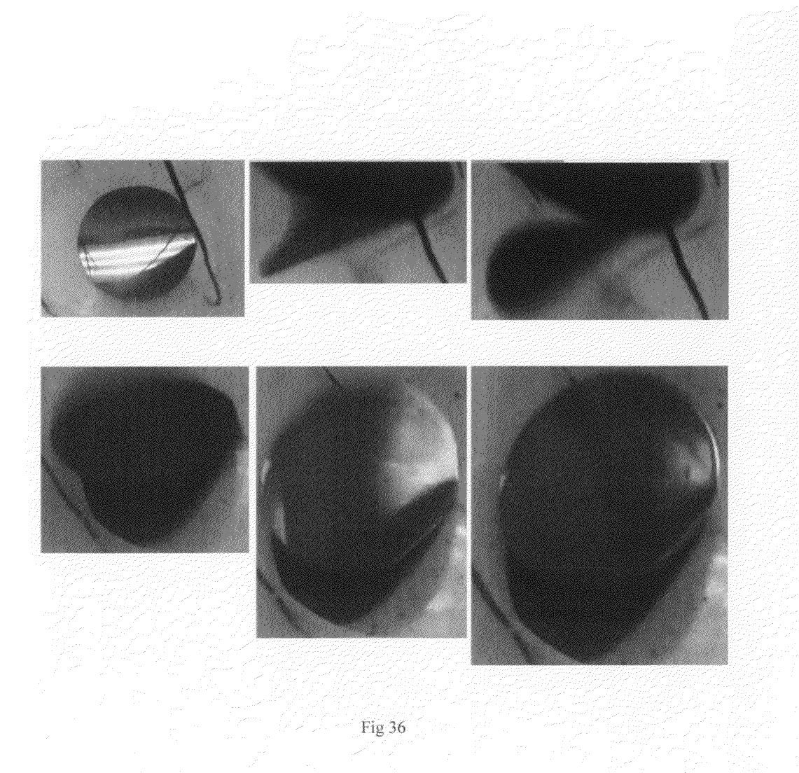

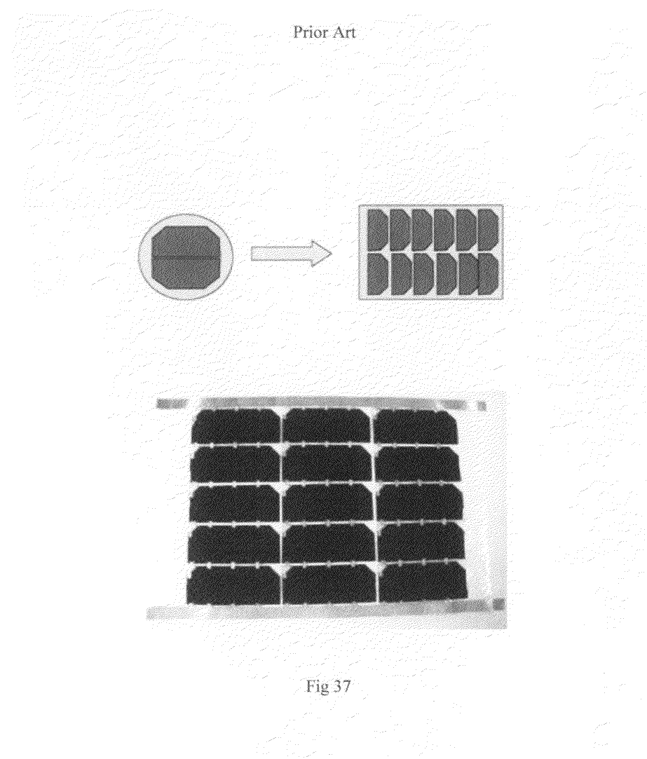

A GaAs wafer with IMM3J epi-layer capped with a metal layer is bonded face down to Kapton substrate and trimmed. After lift-off a typical 4″ wafer is diced to yield two trapezoidal solar cells for space applications having dimensions of approximately 4 cm×6.6 cm (area 26.6 cm²). Several cells are integrated on a common blanket polyimide sheet and interconnected, as shown schematically in FIG. 37.

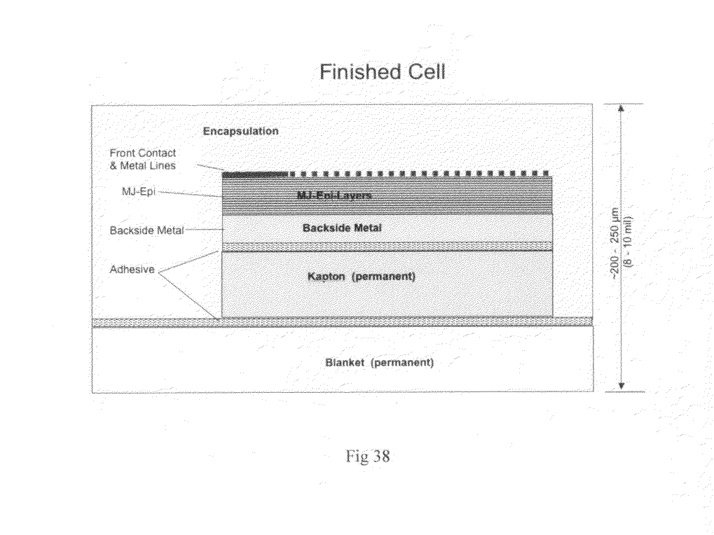

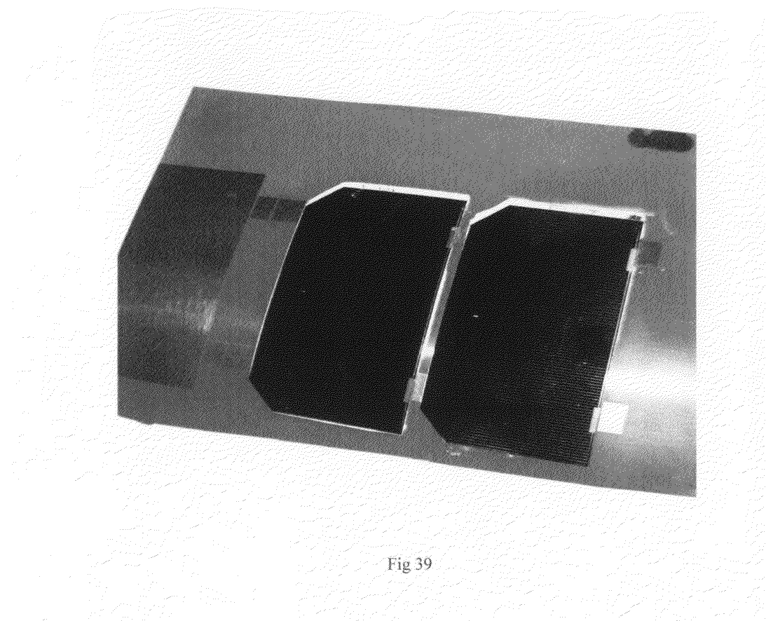

The thin encapsulated solar cell structure is shown schematically in FIG. 38 and has a total thickness of 200-250 μm. Adhesive layers are used on either side of the Kapton® layer to attach the IMM cell to the blanket polyimide sheet. This avoids the use of copper cladded substrates and reduces the weight of the blanket considerably.

Both sides of the epi-layer can be contacted from the top of the wafer, as shown schematically in FIG. 40a and FIG. 40b with a copper ribbon. The backside metal layer can be accessed from the top at the GaAs/metal interface by etching a few mm² of the GaAs epi-layer to expose the top of the metal layer during processing of the front side, as shown in FIG. 40a. Subsequently, contact is made between the backside of one solar cell and the front side of the next cell by copper plating. This will mitigate the risk of breaking the thin epi-layer while contacting. The final assembly of the solar cell is shown in FIG. 40b. Both sides of the epi-layer are contacted from the top side of the wafer. This eliminates the need for copper cladded substrates. Simple non-cladded polymeric blanket sheet can be used with organic adhesive layers (grey cross-hatched layer).

A solar cell was encapsulated with Imiclear (previously Corin® XLS) layer available from Hybrid Plastics, Inc in Hattiesburg, Miss. ImiClear is a spray-on fluorinated polyimide nano-composite, which was developed to replace the cover glass for space applications. It has the combination of transparency and UV resistance and ruggedness that make it suitable for space applications. It can be sprayed-on at room temperature to a thickness between 25 and 50 μm and does not perturb the balance of the structure. It is applied at room temperature and therefore does not exert any thermal stress on the thin solar cell. This provides a process for fabricating a thin flexible solar cell, interconnecting the front and backsides, integrating several cells on a common blanket polyimide sheet, and encapsulating, which applies to both inverted and non-inverted cells.

### Numerical Simulation

It is necessary to flatten the structure of a multi-layer solar cell over a wide temperature range to encompass temperature swings that are encountered on orbit. ANSYS simulation was used to balance the 8-layer solar cell structure of FIG. 38 over a temperature range of 300° C. from +100° C. to −200° C. by varying the CTE of the blanket polyimide sheet. FIG. 41a and FIG. 41b show the deformations of the 8-layer structure at −200° C. for spray-on polyimide thickness of 25 μm and 50 μm, respectively. For spray-on polyimide thickness of 25 μm, a CTE of 16.5 ppm/° C. flattens the structure, whereas for spay-on polyimide thickness of 50 μm, a CTE of 20 ppm/° C. flattens the structure. Below this CTE the structure bends upward, whereas above this CTE the structure bends downward. For the value of CTE that balances the structure, the solar cell remains flat over the entire temperature range from +100° C. to −200° C. Thus, the solar cell structure can be balanced over the entire temperature range.

Controlling the thickness of the spray-on polyimide cover layer within a fraction of a mil is crucial as it affects the transparency and degree of protection of the cell. A change in thickness of only half of a mil (12.5 μm) causes a shift in the UV cut-off wavelength of 15 nm, which can be critical for the performance of the cell. The thickness of spray-on polyimide is controlled precisely by concentration and duration of the spray. Furthermore, the value of the CTE of the blanket polyimide layer required to stress-balance the structure depends on the thickness of the ImiClear cover layer. The 8-layer solar cell structure can be balanced using Novastrat® variable-CTE polyimide, which is available commercially from Nexolve, Inc which is a division of Mantech SRS in Huntsville, Ala.

A typical triple junction solar cell for space applications produces about 2.2 V and generates a current of 0.45 A at the Maximum Power Point (MPPT), which corresponds to a power output of about 1 W. Thus, a blanket made of one hundred thousand cells having an area of 300 m² produces a total power of 100 KW. At least 100 cells are connected in series to produce a voltage >200 V, i.e. 1000 cells are connected in parallel.

### Process for Integrating and Packaging Lifted-Off Solar Cells

The lifted-off solar cells are integrated on a common blanket polyimide sheet and interconnected in series and parallel using copper electroplating. The process starts by bonding the epi-wafer to Kapton® polyimide substrate in a clean room and then lifting-off the epi-layer, as described above. After lift-off the thin IMM structures are processed into fully functional solar cells and a new IMM structure is grown on the original GaAs wafer. Anti-reflection coating (ARC) is deposited and metal lines are patterned on the front side of the IMM cell on Kapton to create metal landing pads. A small volume (10 μm×10 μm×10 μm) is etched at the point of interconnect on the edge of the epi-layer as shown schematically in FIG. 40b, to enable access to the backside metal layer. The processing is done wafer scale. Then the wafer is diced to yield two trapezoidal shaped cells. The front side of the solar cell must be protected while mounting on the back side blanket sheet. The solar cells are aligned and mounted on UV tape, such as dicing tape, about 160 μm thick and laid down on the blanket polyimide sheet. The Mylar sheet protective backing is peeled off the backside of the Kapton to expose the adhesive before mounting on the blanket polyimide sheet. Kapton also comes coated with a uniform film of acrylic adhesive 25 μm thick on both sides, similar to double-sided tape, can be used to facilitate attachment of the Kapton to the epi with metal layer and the blanket sheet. This is a product made by DuPont called Pyralux®. The assembly is then heated at 150-200° C. for about an hour under the weight of a few pounds to activate and cure the adhesive layer. The front side tape is then removed by UV exposure. At this point the cells are ready for interconnect by electroplating. The final step in the process is encapsulation by spraying of ImiClear polyimide to the desired thickness.

The initial bonding of the epi-layer to Kapton by lamination and the electroplating after assembly are done in a clean room. A standard sheet of polyimide (8½″×11″) accommodates 2 rows of 6 cells (6.6 cm×4 cm each), i.e. 6 series and 2 parallel connections. Automated equipment can be used to process in a roll to roll format using 1,000 foot×12″ rolls of polyimide.

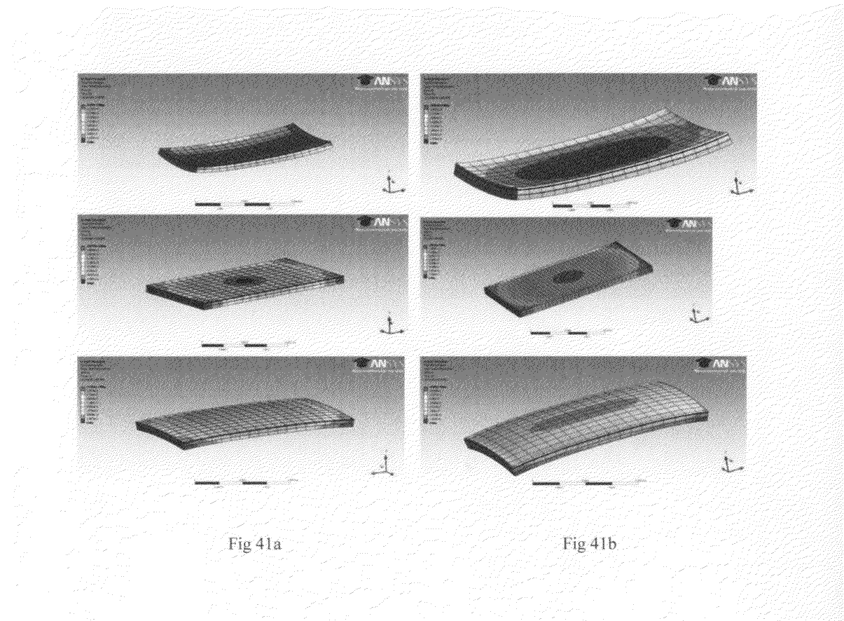

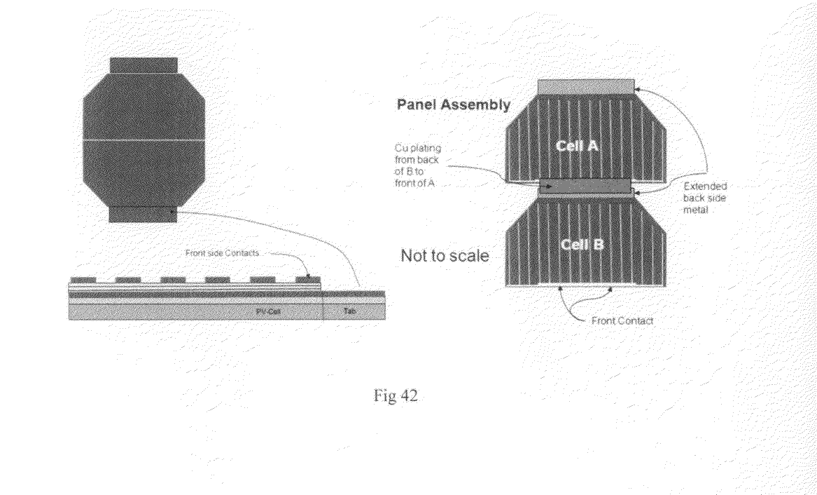

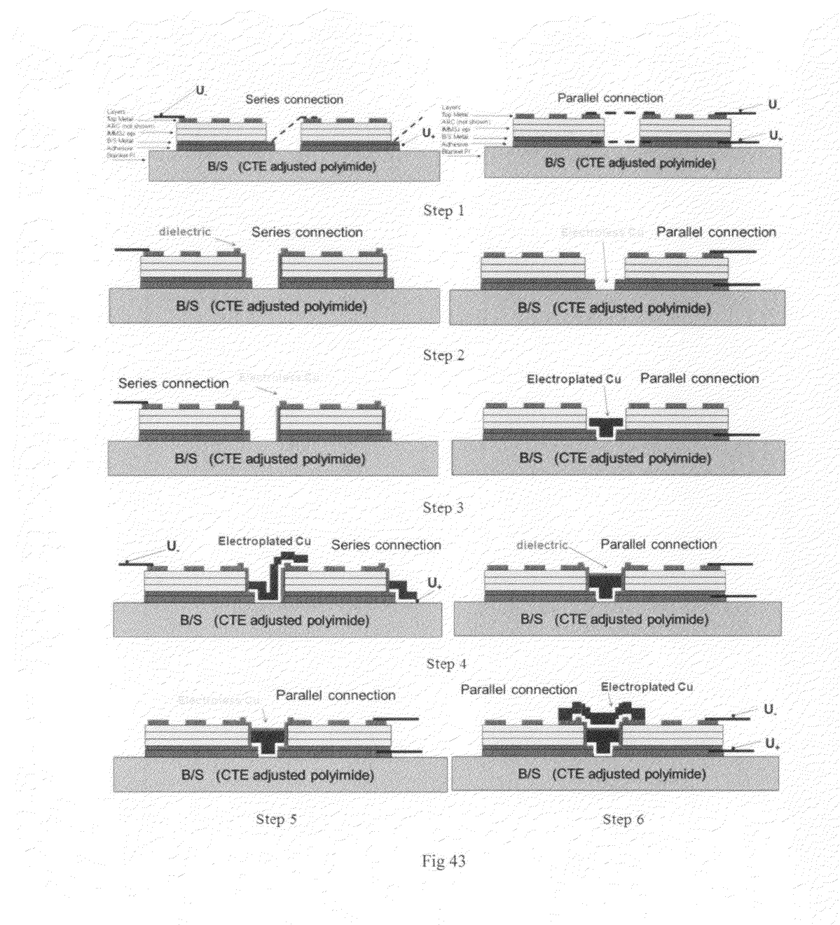

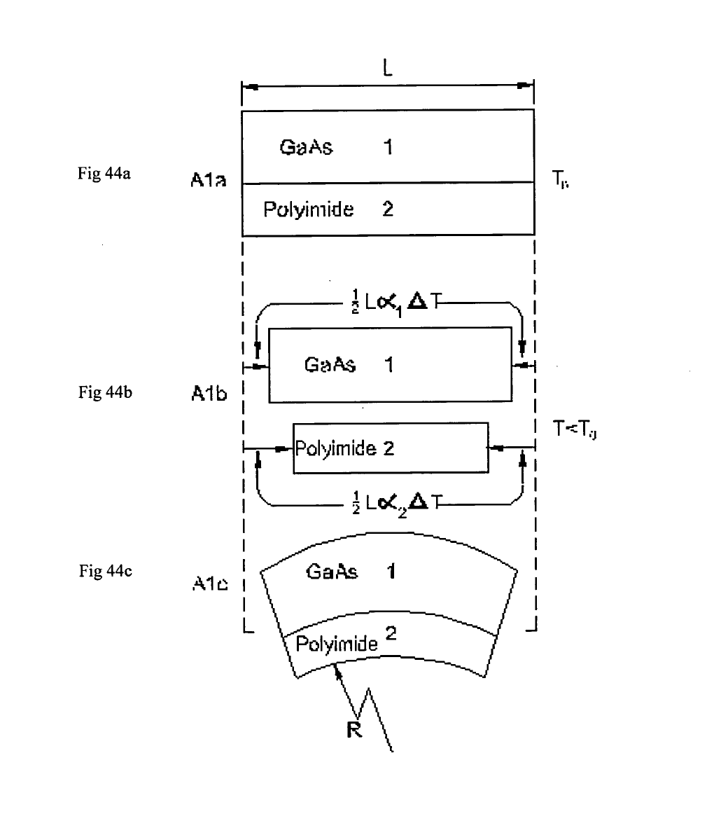

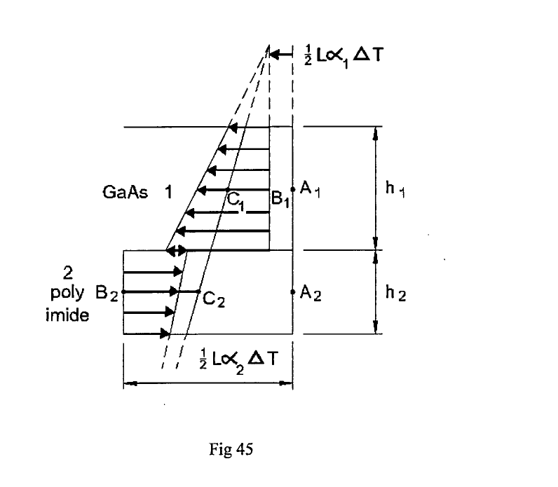

FIG. 42 shows the extension of the backside metal layer beyond the epi-layer and a top view of the interconnect region between two adjacent cells. The cells are interconnected using standard procedures that are well established in the semiconductor industry. FIG. 43 illustrates the process for series connection (steps 1-4, left column) and for parallel connection (steps 1-6, right column). Step 1 illustrates the connections conceptually.

### Process for Electroplating Series Connection

The process starts by coating all surfaces with photoresist, exposing through a mask, and developing leaving all surfaces covered except those that will be coated with dielectric. The samples are then coated with a thin layer of dielectric using Atomic Layer Deposition (ALD), which is particularly effective at coating side walls and sharp edges. All the surfaces are coated with dielectric, including the photoresist. After the photoresist is dissolved the remaining dielectric is shown in Step 2. Subsequently, a second coat of photoresist is applied and patterned, leaving only some areas exposed for electroless Cu plating. Submerging the samples in electroless Cu coats the entire assembly with a thin layer of Cu. Dissolving the second photoresist and the overlying Cu, a thin Cu layer remains over the dielectric in the areas shown in Step 3. This step creates a continuous electrical path from one cell to the next.

The assembly is then coated with a third layer of photoresist, exposed through a mask and developed; leaving exposed the surfaces that will be electroplated. The samples are submerged in an electroplating bath and Cu is plated to the desired thickness in the areas shown in Step 4. The remaining photoresist is finally removed. Electroplating allows much tighter spacing in the placement of the cells compared to other interconnect methods and a much smaller area of the epi-layer needs to be etched away. The IMM cell would not survive immersion in a plating bath unless it is protected by photoresist.

### Process for Electroplating Parallel Connection

Step 1 (right column) illustrates the concept of connecting two neighboring cells in parallel, which is slightly different from the series connection. There is no need for dielectric coating at the beginning because the two connected metals are at the same level. Electroless Cu is deposited directly after patterning to connect the back side metals, as shown in Step 2, which is followed by electroplating copper by applying a potential to the interconnected back side metal layers in step 3. This is followed by patterning the areas to be covered by a dielectric layer and dielectric deposition using ALD in step 4. The parallel connection requires a second electroless Cu deposition, as shown in Step 5. Finally, the cells are patterned and electroplated one more time, as shown in Step 6. These steps require photoresist deposition, patterning and removal three times as in the series connection. The completed and interconnected cells will be encapsulated using spray-on polyimide.

### Rapid Thinning of Wide Bandgap Materials

Wide band gap materials, such as GaN and SiC, are advantageous for high power electronics because they can operate at high switching speeds, voltages and temperatures [25]. GaN devices fabricated on native substrates achieve better performance due to lower defect densities. Vertical GaN LEDs fabricated on GaN substrates achieve higher brightness and can handle higher current densities and yield chips with smaller footprint compared to conventional GaN LEDs fabricated on other substrates because the chip can be contacted from both sides. Another advantage of growing on GaN substrate is the flexible choice of crystallographic plane, which yields improved LED performance [26]. The lack of good quality bulk GaN substrates at a reasonable price is hampering the development of vertical devices. The largest diameter GaN substrate is 2″ and a premium GaN wafer costs over $3,000. The largest commercially available m-plane GaN substrate is only 10 mm×5 mm. A premium 4″ 4H—SiC wafer currently costs about $1000, while a premium 6″ 4H—SiC wafer sells for over $2,500. Devices are made in epitaxial layers. To grow an epi-layer, a smooth epi-ready surface free of subsurface damage is required. However, these materials are extremely hard and difficult to machine (Mohs hardness of 9). Conventional lapping and polishing of a GaN substrate takes between 15 and 20 hours using fine grit diamond particles [27], depending on the amount of material removed, and leaves the surface with scratches that are visible under the microscope and bowed. The typical average surface roughness is on the order of 1 nm and the grinding marks are about 5-10 nm deep. This is about 10 times rougher than softer materials, like sapphire and GaAs. For this reason, chemical-mechanical polishing (CMP) is needed to smooth the surface further for epitaxial growth. However, CMP is not very effective on these materials because the Ga-face is chemically very stable [28]. It can take up to 150 hours of CMP time [29] to get rid of all the grinding marks and remove all the subsurface damage. Lapping/polishing/CMP of a 2″ wafer currently costs $500 or equivalently about 20% of the cost of the wafer. Thus, it is necessary to reduce the cost of surface preparation of epi-ready GaN and SiC substrates.

The wafers are often thinned from the backside after device fabrication by either lapping or grinding from an original thickness of 400 or 500 μm down to 100 μm to separate the laser bars [28] or to improve heat dissipation for power applications [30]. However, a wafer breaking rate of about 30% has been reported [28]. Thus, 80% to 90% of the material is wasted. These crystals are too expensive to be ground away to dust. Furthermore, thinning produces a strong bow and warpage [31]. Reduction of wafer bow is necessary to improve the yield and facilitate facet cleavage. Wafers with pre-fabricated devices are covered with UV curable tape on the front side prior to grinding to protect the devices and prevent contamination with grinding fluids and debris.

A rapid thinning technique by lifting-off a 20-70 μm thick layer from the surface is presented, which can be applied to the front side of the wafer, and independently to the backside regardless of the starting surface condition, i.e. as sliced from boule. A crack propagates across a 4″ wafer within a fraction of a second and leaves the surface shiny with an average roughness<1 nm. The surface can be CMP'ed further down to 0.1 nm to make it epi-ready. The savings in lapping and polishing add up to 60%, when this technique is incorporated in the crystal manufacturing process. There are additional savings in CMP time because this technique is expected to yield less subsurface damage as it does not use abrasives. This technology also has application for backside thinning where the savings are even larger because the cleaved surface does not need further polishing post lift-off. Furthermore, the present rapid thinning technique does not produce any bow or warpage and does not require taping of the front side during backside thinning.

The growth of LEDs on bulk GaN substrates is critical to the development of Solid State Lighting. GaN has outstanding properties for switching at high frequencies, while SiC is best known for its high temperature abilities. They are the most prominent candidates to replace Si for power applications. At the present time, SiC is considered to offer the best trade-off between properties and commercial maturity. Premium quality 150 mm 4H—SiC wafers are commercially available. Nevertheless, it is generally agreed upon that both materials have tremendous potential [25].

Currently, state-of-the-art GaN substrates have defect densities on the order of 10⁶ cm⁻². This can be reduced by at least three orders of magnitude if the GaN layers are grown on GaN substrates. Epitaxy on the native substrate material eliminates all problems related to hetero-epitaxy, such as defects and bow due to lattice and coefficient of thermal expansion (CTE) mismatch. In fact the CTE mismatch was exploited to separate a 100 μm-500 μm thick GaN layer from it growth sapphire substrate by propagating horizontal cracks parallel to the interface [27,32,33]. The threading dislocations also bent horizontally in the direction of the cracks.

Diamond scribing and cleavage of GaN substrates are routinely used for the fabrication of edge-emitting laser diode facets [28]. It is very important to produce vertical flat surfaces that act as mirrors for this application. The stress depends on the dimensions of the wafer and is inversely proportional to the thickness squared. For this reason GaN wafers must be thinned to about 100 μm or less before cleavage [10]. This method has not been widely adopted for GaN laser diodes grown on sapphire substrates, however, because sapphire has many planes that have approximately equal cleavage strength. These planes lie within a small angular distance. Therefore, any perturbation, such as slight misalignment of the applied pressure redirects the fracture from one plane to another resulting in a jagged facet [34]. It is very difficult to cleave a 200 μm thick GaN substrate, whereas a 400 μm thick SiC wafer cleaves readily, and has vertical cleavage planes. Wafer thinning to about 100 μm has become a standard procedure before dicing. All the techniques currently used require thinning of the wafer prior to cleaving.

Completed device wafers are routinely thinned before separating the individual chips. It is necessary to thin the wafer for vertical devices because the current travels through the thickness of the wafer. The substrate contributes about 70% of the overall diode resistance. The thermal behavior of the chip is also improved, which leads to a cooler junction. Thinning the wafer from the standard 350 μm to below 150 μm leads to significant improvements of the electrical as well as thermal resistances of SiC diodes operating at 650 V [30]. However, the damage to the backside due to grinding combined with the reduced thickness lead to significant increase in wafer bow. For example, the starting bow on a typical SiC 2″ wafer before grinding is <20 um, whereas after grinding it jumps to 1.5-1.8 mm, which is a major drawback for backside thinning [31].

Dislocation densities and subsurface damage appear as dark lines in Cathodo-Luminescence (CL). The quality of a cleaved laser diode facet correlates with low crystal defect density [35]. Lapping and polishing produce a sub-surface damaged layer which is deeper than the surface scratches, which are typically about 5-10 nm deep. It took 150 hours of CMP time to remove all the dark lines observed in the CL image of GaN substrate [29]. Overall, 2.5 μm of material was removed to obtain the scratch-free surface and get rid of all the sub-surface damage [29].

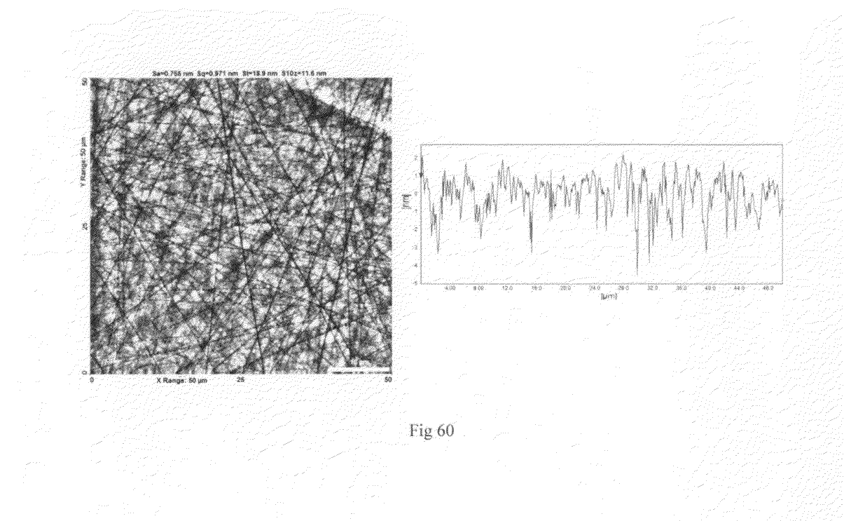

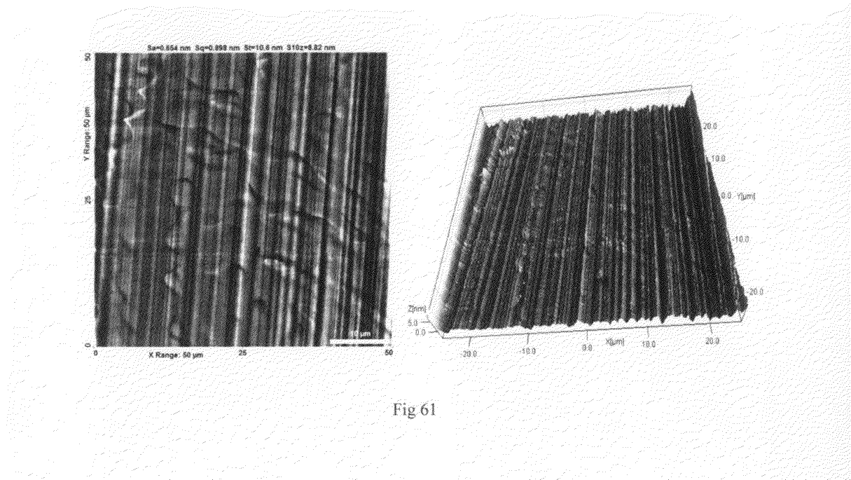

A state-of-the-art commercial epi-ready 2″ GaN or 4″ 4H—SiC substrate exhibits grinding marks which are a few nanometers deep, as measured by AFM, as shown in FIG. 60. It is very difficult to get rid of these surface marks even after extended CMP time because these materials are very hard and chemically stable. The average roughness of a polished surface is about 0.755 nm. By contrast, a cleaved surface is even smoother at 0.654 nm, as shown in FIG. 61, and the grinding marks are gone.

### Horizontal Cleavage

A new method of thinning a semiconductor wafer by driving a horizontal crack parallel to the surface at a certain depth into the substrate, which is also known as spalling, is presented. A polyimide tape is laminated to one face of a semiconductor wafer (either smooth or rough) and lowered slowly in liquid nitrogen. Within 30 seconds an audible crack sound is heard and a layer is separated from the wafer instantly, which remains stuck to the polyimide. It takes an hour to cure the adhesive, but the cleavage takes a fraction of a second. The cleavage transfers a layer about 50 μm thick to the polyimide substrate which is used as the stressor layer. Kapton® Polyimide sheet is used, which is manufactured by DuPont. The crack is driven purely by the thermal stresses due to the CTE difference between GaN or SiC (4-5.5×10⁻⁶/° C.) and polyimide (16×10⁻⁶/° C.) across a temperature drop of 300° C. without the necessity for any external mechanical force or tool to aid crack propagation. The crack can start either on the surface or the side of the wafer, but propagates at a depth which depends on the thickness ratio and the elastic modulus ratio of the polyimide/GaN. It is independent of the dimensions of the wafers. A 2″ wafer will cleave at the same depth as a 4″ wafer, as long as the thickness ratio of polyimide to GaN is the same. Unlike manual cleavage where the stress depends on the dimensions of the wafer and the skills of the operator, cleavage by polyimide is a lot more uniform. A stress of about 20 MPa is needed to initiate a crack in GaAs. Stresses on the order of up to 1 GPa may be needed to cleave GaN. The polyimide is capable of exerting the necessary stress by choosing the right thickness of polyimide. Kapton comes in sheets of 25 μm increments. So it is easy to choose the desired thickness.

About 700 μm of polyimide cleaves about 50 μm off a 400 μm SiC wafer. The thickness of the lifted-off layer can be controlled from 10 to 100 μm by controlling the thickness of polyimide. The cleaved thickness can be calculated by equating the elastic strain energies of the system before and after crack propagation, according to the Griffith criterion. The initial elastic strain energy at full thickness is equal to the residual strain energy in the thin SiC/Kapton plus the energies of the two newly created surfaces. The surface energy is a known material property.

Smooth cleavage was obtained for both polar (c) and non-polar (m) planes, and 4″ wafers have been cleaved. We have laminated Kapton to a cleaved surface and cleaved the second time. The hexagonal atomic structure of GaN/SiC cleaves even better than the cubic FCC zinc blende structure of GaAs.

Currently, about 80-90% of the GaN and SiC crystals are thrown away or ground to dust in order to satisfy the thinning requirement for cleavage, as discussed above. This is a huge waste because these materials are very expensive to produce. By contrast, the polyimide is able to cleave 50 μm off a 400 μm SiC wafer without prior thinning. Furthermore, the lifted-off material is not lost. It is still intact single crystal sitting on the Kapton and can be reclaimed.

Layers have been peeled off GaN and 4H—SiC substrates. The starting surface of the wafer can be as-cut from boule. This technique has been used to lift III-V epitaxial layers off GaAs substrates to fabricate flexible high efficiency solar cells, and reused the substrate multiple times [36]. The wafer is recovered in one piece and can be reused to grow epitaxial layers several times. Similarly, epitaxial layers of GaN can be lifted off any substrate. The layer peel-off process is done wafer scale, and requires minimal investment in equipment. The process can be scaled up II to process hundreds of wafers simultaneously with the use of automated roll-to-roll processes.

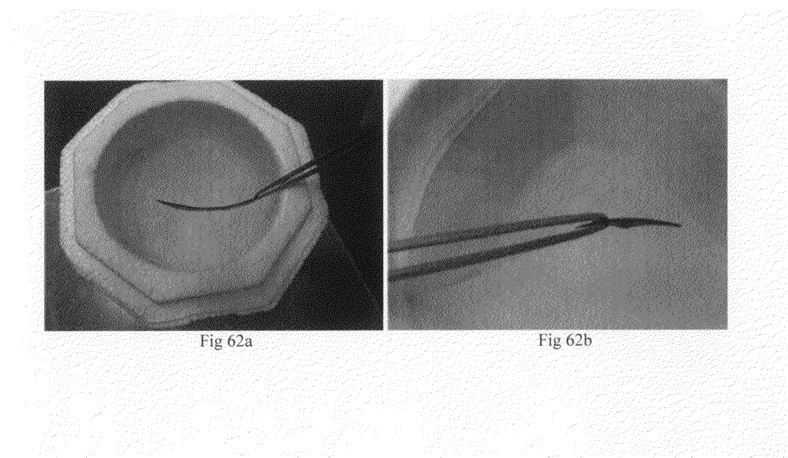

The thermal stresses cause bending of the composite structure. The organic adhesive has enough shear strength to transmit the force to bend the wafer and holds its grip in LN₂. FIGS. 62a and 62b show pictures of SiC and GaN laminates, respectively, in LN₂ which are concavely bent with the polyimide on the inside because it tends to shrink more than GaN. The bending applies tensile stresses in the upper layers of the GaN and SiC wafers opposite the polyimide and initiates the crack.

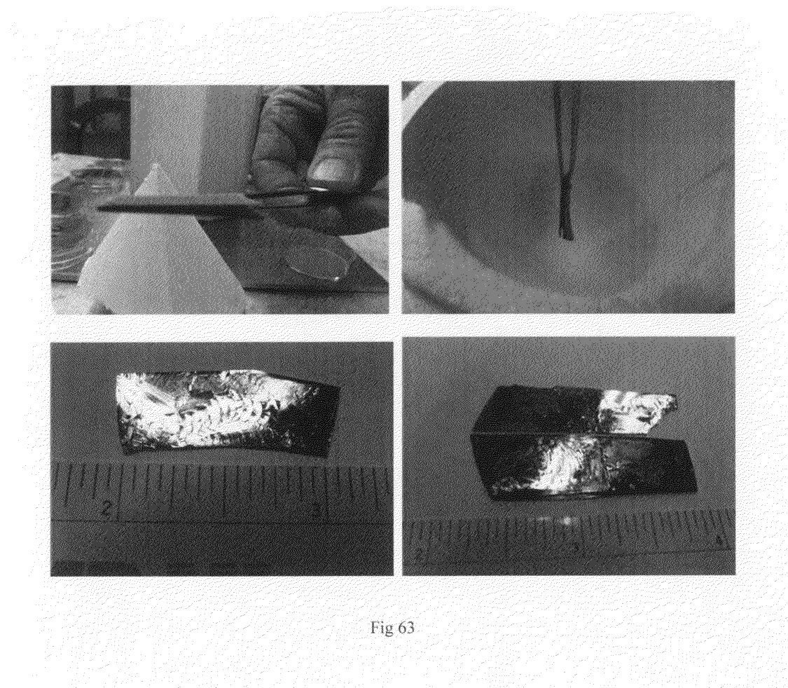

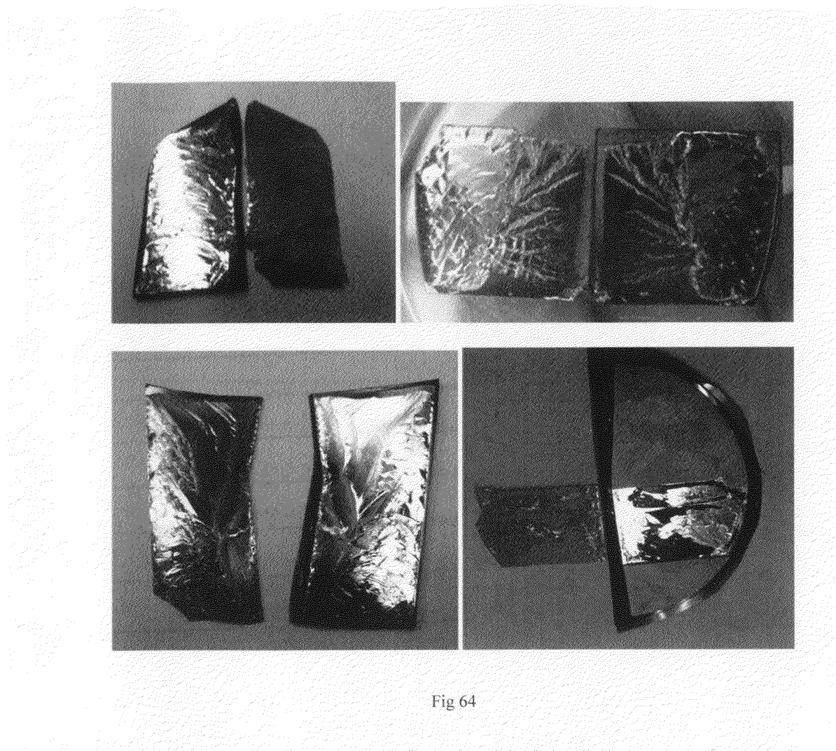

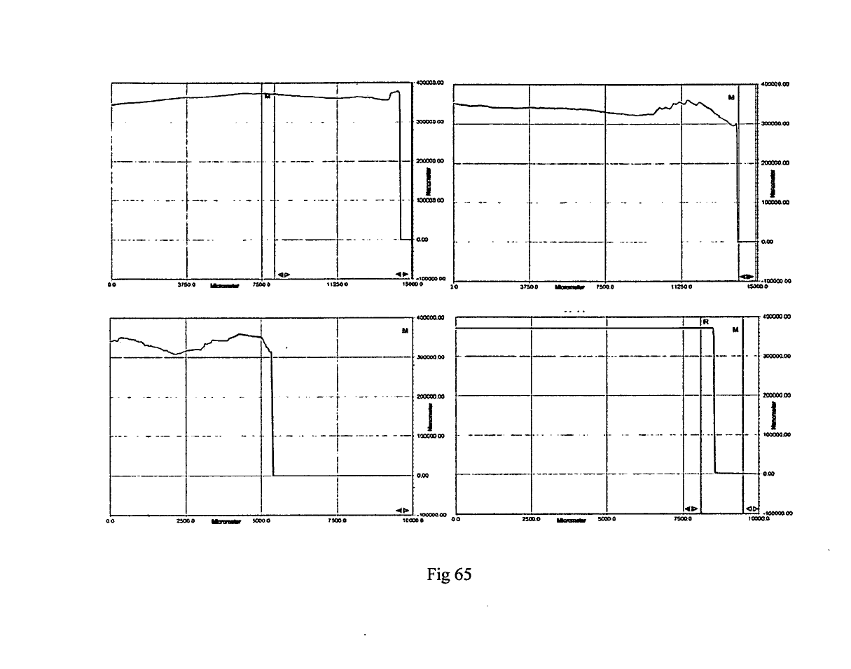

FIG. 63 and FIG. 64 show samples that have cleaved partially and are still hanging on one edge of the Kapton, while others cleaved completely and separated from the Kapton. Propagation of the crack leaves the surface shiny and reflective but produces height variations on the order of tens of microns over mm scales. CMP is still needed to make the surface epi-ready. FIG. 65 shows DekTak height profile measurements along different cross-sections of cleaved surface also of the backside of a cleaved wafer piece. The original SiC wafer thickness was about 370 μm. The flat backside profile indicates that cleavage does not produce any warpage.

The goal is to do CMP directly on the surface as-cleaved. It is desired to avoid lapping and polishing if possible because that would destroy the smoothness of the surface and re-introduce subsurface damage. The grinding marks will return after lapping. If the CMP is successful, then the lapping and polishing and some CMP time will have been saved, because the surface is expected to have less sub-surface damage than a lapped and polished surface. These savings amount to 60% of the polishing costs. The goal is to reduce the time and cost of lapping and polishing and possibly CMP of GaN and SiC substrates in the process of making the surface epi-ready.

It is desired to thin the wafer using only the polyimide without lapping or grinding, and to remove only the amount of material necessary for the application. Multiple layers can be lifted off the same surface with the Kapton. For the front side it is only needed to lift-off about 10-20 μm once. For the backside we can lift-off several times to reach the desired final thickness and there would be no need for lapping or polishing afterward because major roughness is not an issue for the back side. Therefore, this process saves the grinding time and does not produce any warpage. Rapid thinning reduces the cost of manufacturing GaN and SiC substrates. This technology also applies to large size wafers.

The main goal will be to reduce the surface variation to about 20 μm, which is equivalent to the TTV on premium 4H-4″ SiC wafers. We want to obtain the smoothest surface starting from the roughest surface while minimizing abrasive machining. The height variation is due to the convergence of multiple crack fronts. Cracks start simultaneously from several points on the sample as soon as it is lowered in the LN2 Dewar. The key to obtain a smooth cleavage is to launch a single crack. A crack propagates across a 4″ diameter wafer in less than 0.1 milli-second at a speed of Km/sec which is about 35% of the Rayleigh wave speed. In order to control the crack it is necessary to slow it down [16]. A fast camera that has a time resolution of 0.1 μ-sec can be used to grab at least 1000 frames to image crack nucleation and propagation, as this would give us insight on how to control the crack.

It is very important to discover whether crack propagation yields any subsurface damage. A crack has tendency to branch out and travel in different directions. However, it is not known whether a crack would produce lateral damage along its path. The extent of post lift-off CMP needed depends on such damage. Contiguous layers have been cleaved off 4″ wafers and recovered the base wafer in one piece.

Another issue which is equally important is the effect of defects and dislocations on the cleavage. It is believed that in order to obtain good cleavage, a low dislocation density is required [35] because the propagation of cracks is altered at dislocations. GaN has about two orders of magnitude higher dislocation density compared to other semiconductors, such as Si or GaAs.

The subsurface damage can be inspected using the optical microscope, AFM, SEM, TEM, FIB, Cathode Luminescence imaging (CL) and reflection high energy electron diffraction (RHEED). Dislocations act mainly as non-radiative recombination centers, hence, appear as dark spots and lines in CL images. Therefore, the objectives will be to reduce the height variations during lift-off and to measure subsurface damage using CL in order to reduce CMP time. Another objective will be to improve the uniformity of bonding between Kapton and GaN by applying uniform pressure using a hot press.

### APPENDIX

### Stress Analysis of Polyimide/Semiconductor Wafer Bi-Layer

A sheet of polyimide about 50 μm thick is bonded to a semiconductor wafer, either GaAs with orientation (110) 370 μm thick or Si with orientation (111) 200 μm thick, using a layer of organic adhesive about 25 μm thick in between. The thickness of polyimide can be increased by laminating several layers. The structure is modeled as a two-layer because the organic adhesive has physical and thermal properties similar to polyimide. Layer 1 refers to the semiconductor material, either Si, GaAs, SiC or GaN and layer 2 is the lumped polyimide/adhesive. FIG. 44a shows the two layers flat and equal in length, hence zero stress, at a temperature Tₒ˜150° C., which is the curing temperature of the adhesive. As the temperature is lowered to room temperature or below to liquid nitrogen (−196° C.), the polyimide material having a larger CTE wants to shrink at a higher rate than the semiconductor material (α₂>α₁). The GaAs opposes the polyimide motion and puts it in tension. Reciprocally, the polyimide puts the GaAs in compression. However, as will be seen later from the analysis, only the lower half of the GaAs adjacent to the polyimide is in compression, while the outer half away from the polyimide is in tension due to bending. If the two materials were separated, as shown in FIG. 44b, then the GaAs would shrink by Lα₁ΔT while the polyimide shrinks by Lα₂ΔT and there would be no stress. However, as the two materials are bonded at the interface, this leads to stress and bowing. The two materials are not clamped and there is no external force acting on them. They are free to stretch and bend due to their own internal thermal stresses. They accommodate each other by bending with a radius of curvature R, as shown in FIG. 44c. The GaAs is compressed more than it wishes and the polyimide is stretched quite a bit. They come to an equilibrium point in between. It is assumed that a plane cross-section remains planar after deformation. FIG. 45 shows a close up view of the common edge before and after deformation. Points A₁ and A₂ represent the centroids of the two cross-sections at temperature Tₒ. If left alone point A₁ wants to move to B₁ and A₂ to B₂. They compromise and end up at C₁ and C₂, respectively. Line C₁C₂ represents the cross-section after deformation. The GaAs is compressed from B₁ to C₁, and the polyimide is stretched from B₂ to C₂. The arrows represent the bending stresses, which are proportional to the curvature and the elastic moduli E₁ and E₂. The line C₁C₂ intersects with the vertical from B₁ at the neutral axis which is the point of zero strain and stress.

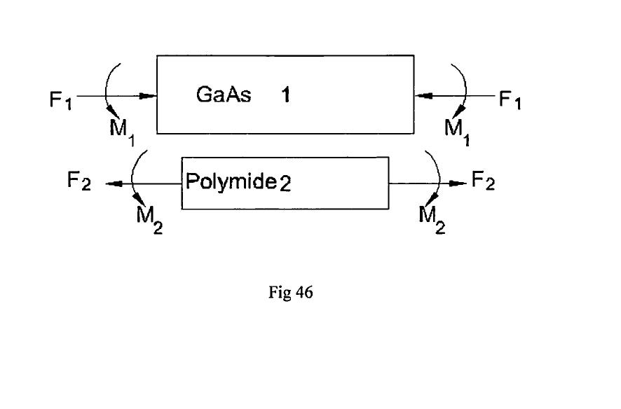

There are two components of stresses in each material: axial stresses which are uniform across the cross-section, and bending stresses which vary linearly across the cross-section. These are denoted by σₐ₁, σₐ₂, σ_{b1} and σ_{b2}, respectively, where σ_{b1} and σ_{b2} are the maximum bending stresses at the boundaries. These stresses give rise to the forces F₁ and F₂, and the moments M₁ and M₂, acting on each element, as shown in FIG. 46.

So the problem consists of 4 unknowns and can be stated either in terms of the stresses σₐ₁, σₐ₂, σ_{b1} and σ_{b2}, or equivalently in terms of the forces and moments F₁, F₂, M₁ and M₂.

Therefore, 4 linear equations are needed to solve for the 4 unknowns. These are the balance of axial forces ΣFₓ=0, which yields F₁=F₂=F; the total moment must also vanish because there are no external forces acting on the bi-layer, ΣM=0; the geometric compatibility which relates the bending strains in both materials ε_{b1} and ε_{b2}, to their relative thicknesses h₁ and h₂ due to planar deformation, which can be inferred from FIG. 45; and the fact that the summation of all the strains add up to the total thermal strain which is the driving force behind the deformation. These 4 equations can be summarized as follows:

σₐ₁h₁=σₐ₂h₂ (1)

M₁+M₂=F(h₁+h₂)/2 (2)

εₐ₁/h₁=εₐ₂/h₂=1/R (3)

εₐ₁+ε_{b1}+εₐ₂+ε_{b2}=(α₂−α₁)ΔT (4)

The solution of these 4 equations yields all the pertinent parameters including the stresses, strains, radius of curvature, forces and moments acting on the structure. We define two parameters E and h, which are the ratios of E₁/E₂ and h₁/h₂, respectively. The curvature 1/R is given by equation (5).

$$\frac{1}{2 R} = \frac{1}{{h}_{2}} \frac{3 Eh ( 1 + h ) Δ ∝ Δ T}{[ 3 {Eh ( 1 + h )}^{2} + ( 1 + Eh ) ( 1 + {Eh}^{3} ) ]} \qquad ( 5 )$$

This is the same as equation (3) in [19]. The axial and bending stresses are given by

$$\begin{matrix}σ {a}_{1} = {E}_{1} \frac{( 1 + {Eh}^{3} ) Δ ∝ Δ T}{[ 3 {Eh ( 1 + h )}^{2} + ( 1 + Eh ) ( 1 + {Eh}^{3} ) ]} & ( 6 ) \\ σ {a}_{2} = {E}_{1} \frac{h ( 1 + {Eh}^{3} ) Δ ∝ Δ T}{[ 3 {Eh ( 1 + h )}^{2} + ( 1 + Eh ) ( 1 + {Eh}^{3} ) ]} & ( 7 ) \\ σ {b}_{1} = 3 {E}_{1} \frac{{Eh}^{2} ( 1 + h ) Δ ∝ Δ T}{[ 3 {Eh ( 1 + h )}^{2} + ( 1 + Eh ) ( 1 + {Eh}^{3} ) ]} & ( 8 ) \\ σ {b}_{2} = 3 {E}_{2} \frac{Eh ( 1 + h ) Δ ∝ Δ T}{[ 3 {Eh ( 1 + h )}^{2} + ( 1 + Eh ) ( 1 + {Eh}^{3} ) ]} & ( 9 )\end{matrix}$$

Usually, the bending stresses in the GaAs or Si, σₐ₁, are dominant followed by the axial stresses in the polyimide σ_{b2}. The bending stresses are related to the radius of curvature R as

σ_{b1}=E₁h₁/2R and σ_{b2}=E₂h₂/2R (10)

Thus, the bending stresses are directly proportional to the curvature 1/R. FIGS. 47a and 47b plot the curvature and bending stresses at full thickness before lift-off vs h=h₁/h₂ which is the ratio of the thickness of GaAs or Si to the thickness of polyimide, for GaAs and Si, respectively. In these plots, it is assumed that h₁ remains constant while h₂ varies. The plot shows that the curvature peaks at the point where the GaAs and polyimide have comparable strengths where the bending stresses dominate, beyond which the curvature and bending stresses decrease again. If one substrate becomes much thicker and outmuscles the other, then the composite structure remains flat as the temperature drops, and the stresses are mainly axial. The highest stresses which are responsible for opening of the crack are due to bending. Thus, bending is necessary for cleavage and peaks at the point where the two substrates have equal stiffness. Thus, it is not completely true that as the thickness of polyimide is increased, it will lift-off a thicker chunk of semiconductor. This is true up to a certain point, however, after a certain thickness, the lifted-off thickness will decrease again. For example, in this particular case h=2.467 for GaAs and h=1.333 for Si which places the operating point beyond the hump in both instances.

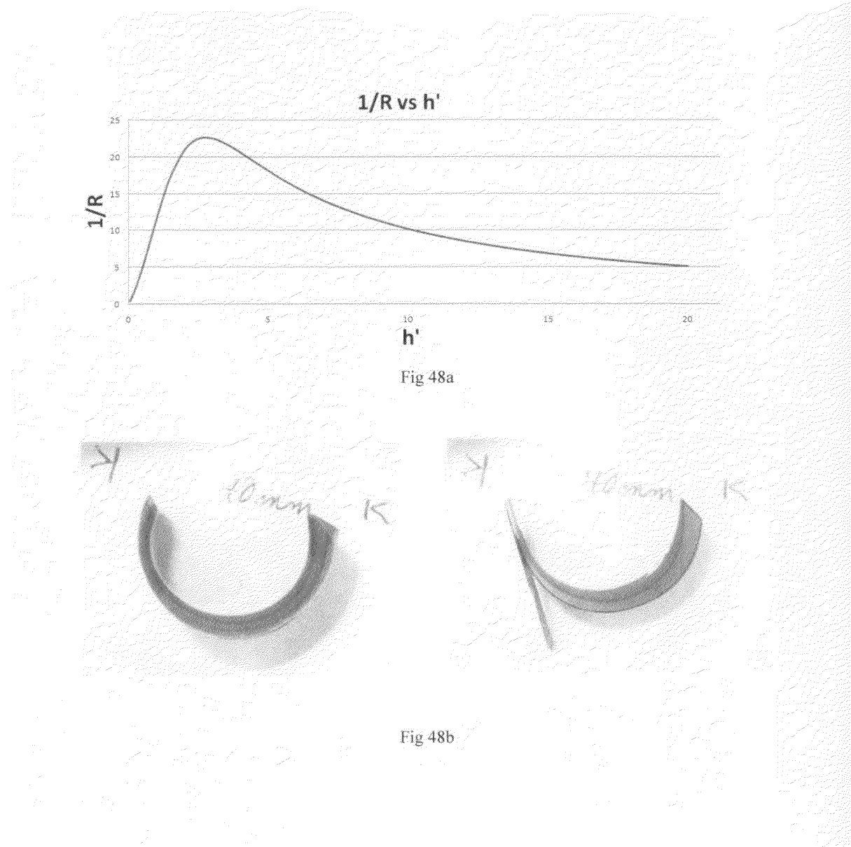

FIG. 48a plots the curvature after lift-off for GaAs thickness h₁=20 μm and ΔT=300° C. vs h′=h₂/h₁ which is the ratio of the thickness of polyimide to the thickness of GaAs. It is seen that the curvature peaks (1/R=22.5 m⁻¹, R=4.4 cm) at a ratio h′=3.75, i.e. h₂=75 μm. This is verified experimentally as shown in FIG. 48b.

### Bi-Axial State of Stress and Dependence on Orientation

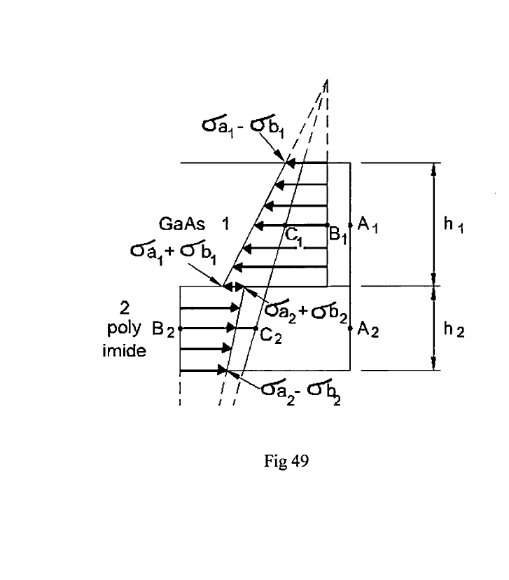

The layers shrink in both in-plane directions relative to each other. This gives rise to a bi-axial state of stress σₓ=σ_{y}=(σₐ₁−σ_{b1}), as shown in FIG. 49. In this figure it is assumed that the bending stress σ_{b1} is smaller than the axial stress σₐ₁, so that the GaAs is completely in compression (arrows pointing to the left). As will be seen later from the analysis below, this is not actually the case. σ_{b1} is indeed larger than σₐ₁ with the result that the stress at the free upper surface of the GaAs (away from the polyimide) is positive, i.e. tensile (arrow pointing to the right). The polyimide, however, is completely under tension. The tensile stress (σ_{b}−σₐ₁) is the one responsible for opening the crack when scratched on the upper surface of the GaAs wafer.

GaAs and Si are crystalline materials and therefore, have different properties along different crystallographic orientations. In particular, the elastic modulus varies up to 65% depending on the orientation. For example Young's modulus for

GaAs <100> E=86 GPa

GaAs <110> E=122 GPa

GaAs <111> E=142 GPa

whereas for Si

Si <100> E=130 GPa

Si <110> E=169 GPa

Si <111> E=188 GPa

These values act along the direction of the respective vectors, rather than in the plane. Furthermore, the (110) plane is known to be the preferred cleavage plane in GaAs, whereas (111) is the preferred cleavage plane in silicon.

### Effective Modulus for Plane Strain

Since the GaAs wafer is thicker than (K_{Ic}/σ_{Y})²=1.3×10⁻⁸ m, where K_{Ic} is the fracture toughness=0.31-0.43 MPa(m)^{1/2} and σ_{Y} is the yield stress=2.7 GPa, it is in plane strain. This means that there is no strain perpendicular to the surface of the wafer ε_{z}=0, but there must be vertical stress σ_{z} in order to cancel the effects of the in-plane stresses. Under these circumstances for bi-axial stress σₓ=σ_{y}=(σ_{b1}−σₐ₁), the effective modulus E_{eff}=E/(1−ν−2ν²) where ν is Poisson's ratio. For uni-axial stress, E_{eff}=E/(1−ν²). For GaAs ν=0.31, while for Si ν=0.278. Thus, the effective modulus for GaAs (110) E_{eff}=250 GPa, while for Si (111) E_{eff}=300 GPa. For Kapton E_{eff}=5.8 GPa. Thus, the material becomes significantly stiffer for plane strain under bi-axial stress.

### Importance of the Scratching Direction

Since the effective moduli mentioned above act along the respective vector directions and the stresses act in the plane, it is important to know what crystallographic vectors exist in a particular wafer surface. It helps to examine the face centered cubic lattice structure of GaAs shown in FIG. 26a. From examination of the lattice structure we make the following observations:

A (100) face contains both <100> and <110> vectors. The vectors make an angle of 45° with each other. The <110> vector is perpendicular to the flat.

A (110) face contains all three <100>, <110> and <111> types of vectors. The <100> and <110> vectors are orthogonal to each other, while the <111> vector makes an angle of 54.3° with the <100> vector. The <100> vector is perpendicular to the flat.

A (111) surface contains only a <110> vector.

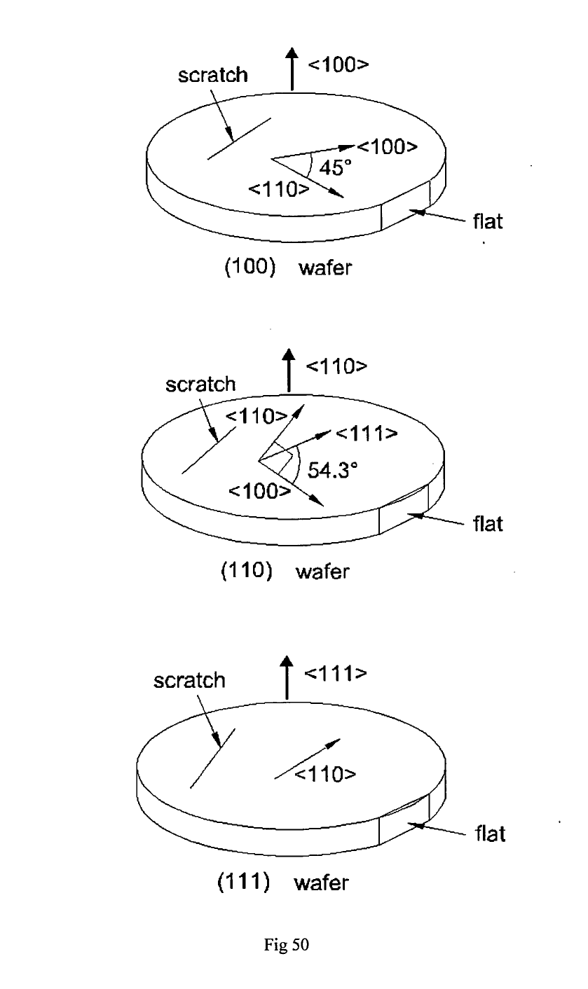

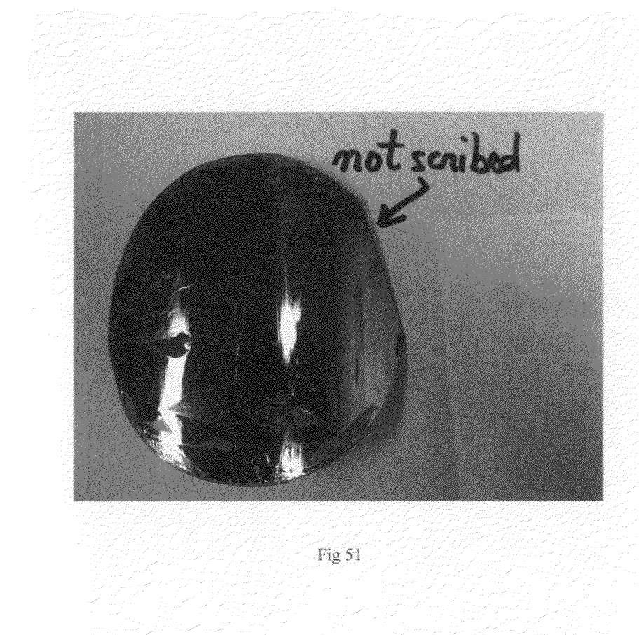

Thus, all three principal semiconductor surfaces contain a <110> vector. This is illustrated in the diagrams of FIG. 50. Thus, the effective modulus depends on the direction of the scratch and could be a combination of all three moduli, unless the scratch coincides with one of the principal directions. This explains why the lifted-off layer on Kapton curls in a cylindrical fashion whose axis is not parallel to the flat of the wafer, as shown in FIG. 51.

### Computation of Stresses

The temperature drop AT is taken to be 300° C. and the difference in CTE between the polyimide and semiconductor is assumed to be 10×10⁻⁶/° C. for both GaAs and Si. To be more accurate the CTE of Si is 3×10⁻⁶/° C. while that of GaAs is 6×10⁻⁶1° C. Thus, the driving thermal strain ΔαΔT=3×10⁻³.

### EXAMPLE 1

GaAs (110) E_{1eff}=250 GPa, h₁=370 μm, polyimide E_{2eff}=5.8 GPa, h₂=150 μm E=E_{1eff}/E_{2eff}=42.88, h=h₁/h₂=2.467

Equations (5-9) yield:

1/(2R)=0.3 m⁻¹→R=1.66 m (10)
σₐ₁=6.75 MPa
σₐ₂=16.65 MPa
σ_{b1}=27.75 MPa
σ_{b2}=0.26 MPa
εₐ₁=0.27×10⁻⁴
εₐ₂=28.7×10⁻⁴
ε_{b1}=1.20×10⁻⁴
ε_{b2}=0.48×10⁻⁴

### EXAMPLE 2

Si (111) E_{1eff}=300 GPa, h₁=200 μm, polyimide E_{2eff}=5.8 GPa, h₂=150 μm E=E_{1eff}/E_{2eff}=51.3, h=h₁/h₂=1.333

Equations (5-9) yield:

1/(2R)=1 m⁻¹→R=50 cm (11)
σₐ₁=11.4 MPa
σₐ₂=15.2 MPa
σ_{b1}=59.6 MPa
σ_{b2}=0.87 MPa
εₐ₁=0.38×10⁻⁴
εₐ₂=26.2×10⁻⁴
ε_{b1}=2.0×10⁻⁴
ε_{b2}=1.5×10⁻⁴

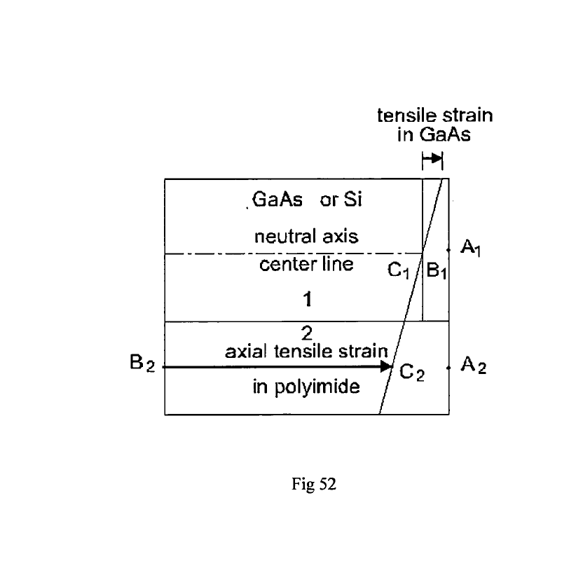

As can be seen from the two examples above, the bending stress σ_{b1} is larger than the axial stress σₐ₁ for both GaAs and Si, i.e. the outer half of the wafer is under tension. Thus, the stresses are not exactly as depicted in FIGS. 45 and 49, rather as shown in FIG. 52. Points B₁ and C₁ are almost coincident and the neutral axis is actually very close to the centroid of the GaAs cross-section. The stress in the GaAs at the polyimide/GaAs interface is compressive, which helps prevent the crack from propagating at the interface. FIG. 52 depicts the stresses due to cooling below the temperature of zero stress. In the case of heating, the stresses are reversed, i.e. the polyimide will be in compression because it wants to expand at a faster rate than the GaAs which restrains it. The curvature of the composite structure will be upward with the GaAs or Si concave on the inside and the polyimide on the outside. The GaAs or Si will be under tensile stress at the interface and the outer side of the GaAs away from the polyimide in compression. Thus, the crack would have higher tendency to initiate at the interface if heated. In fact, it was reported that interfacial debonding between Si and Ni occurs at high temperature during cell fabrication [7,19]. This limits the processing temperature of thin solar cells to about 200° C. [19]. The bulk of the strain is actually taken up by the polyimide, which gets stretched by about 26-28×10⁻⁴. The force F on the GaAs is practically applied at the centroid of the polyimide. Thus, the tensile stress which is responsible for opening of the crack in GaAs is (σ_{b1}−σₐ₁)=27.75−6.75 MPa=21 MPa, and in Si (σ_{b1}−σₐ₁)=59.6−11.4 MPa=48.2 MPa.

### Depth of Scratch

According to the theory of fracture mechanics, the stress at the crack tip is described by the stress intensity factor, K_{I}=σ\sqrt{πa} where σ is the tensile stress responsible for opening of the crack (σ_{b1}−σₐ₁) and a is the crack depth. The theory of fracture mechanics assumes that a crack already exists in the material. This corresponds to a static crack due to either a hand scratch or the median crack depth obtained after nano-indentation. When K_{I} reaches a certain value known as the fracture toughness of the material K_{Ic}, which is a material property, under plane strain conditions, the crack starts to propagate. For GaAs (110) K_{Ic}=0.31 MPa(m)^{1/2} [15] and for Si (111) K_{Ic}=0.62 MPa(m)^{1/2} [6]. From these values of K_{Ic} and (σ_{b1}−σₐ₁) above, the depth of the scratch that is necessary to propagate the crack can be calculated.

The crack opens vertically in pure mode I at the upper surface where the stress and K_{I} are maximal, as shown in FIG. 18. As it approaches the neutral axis, K_{I} drops to zero as the stress switches from tensile to compressive. Actually, the location of the neutral axis may shift as the crack propagates downward. The crack will stop as it enters a zone of compressive stress and turns horizontally. At that point K_{II} becomes larger than K_{I}.

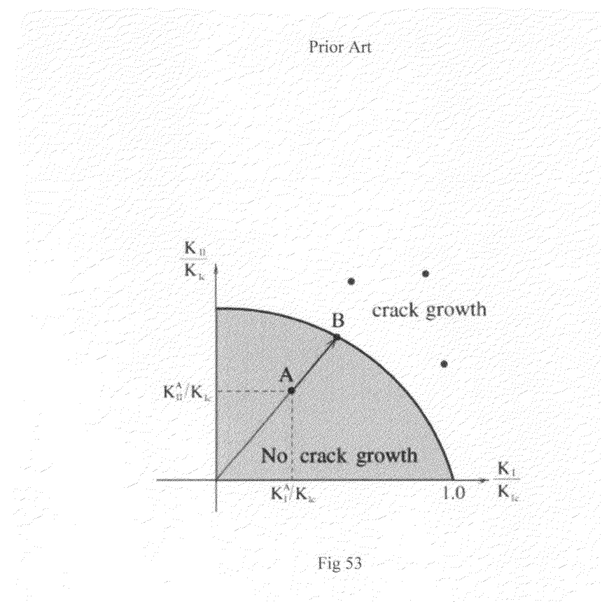

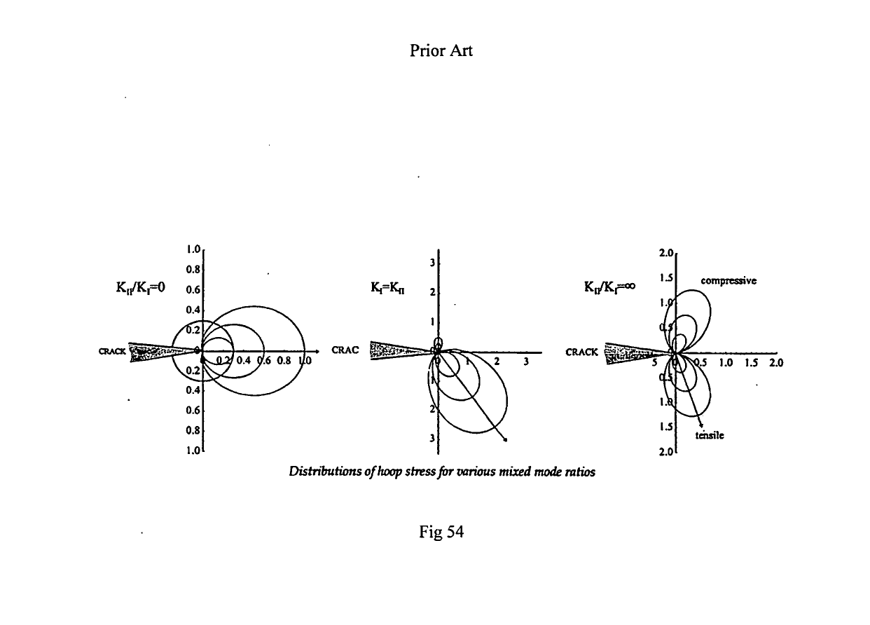

A crack will propagate as long as K_{I} and K_{II} are outside the envelope given by (K_{I}²+K_{II}²)=K_{Ic}², as shown in FIG. 53. However, the direction of propagation of the crack changes depending on the ratio of K_{II}/K_{I} [9]. The crack turns by 90° and steers away from a compressive zone as K_{I} drops to zero (K_{II}/K_{I}→∞), as shown in FIG. 54.

Horizontal crack propagation is due to mixed mode stress at the crack tip. However, K_{Iv} and K_{IIv} for the vertical crack are different from those for the horizontal crack K_{Ih} and K_{IIh}. Nevertheless, they are related by the same driving force, which is the energy release rate G

G=(K_{Iv}²+K_{IIv}²)/E_{eff}=(K_{Ih}²+K_{IIh}²)/E_{eff} G=(K_{I}²+K_{II}²)/Ē (12)

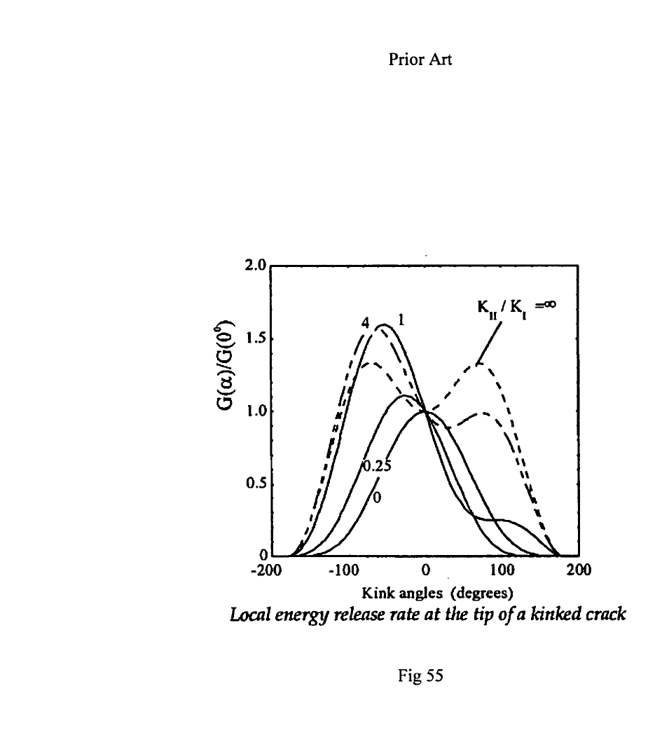

Thus, as K_{Iv} approaches zero, the crack swerves by 90° and keeps going. FIG. 55 shows the dependence of the energy release rate on the angle of propagation which peaks at 90° [9]. It is well known that the horizontal crack propagates at a depth where K_{IIh}=0 [2,3,4]. But there is experimental evidence that the vertical crack stops at a depth where K_{Iv}=0. Thus, it would be most advantageous to coincide the two locations where K_{Iv}=0 with K_{IIh}=0 at the desired cleavage depth.

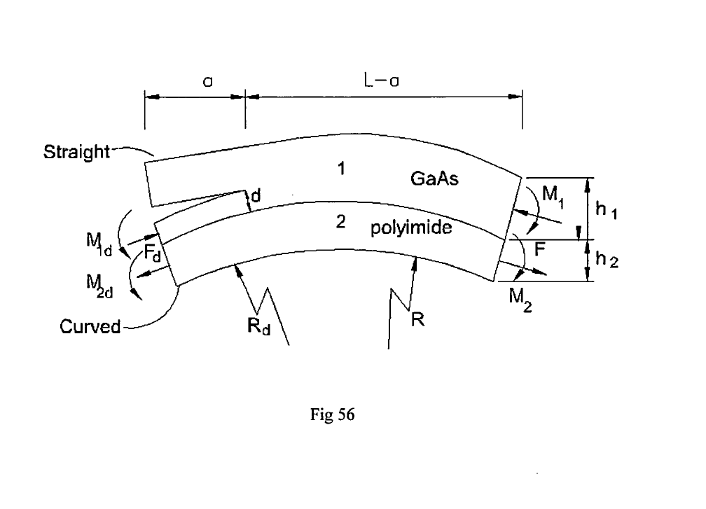

FIG. 56 shows a horizontal crack of length a propagating across the wafer at depth d from the interface. The cantilever beam of length a above the crack made of GaAs material is under no stress, therefore it remains straight. However, the cantilever of length a below the crack made of GaAs and polyimide of total thickness (h₂+d) is curved under the action of force F_{d} and moments M_{1d} and M_{2d}, and has a new radius of curvature R_{d}. These are given by the same equations (5-9) above, but are different from the original forces F, and moments M₁ and M₂, and radius of curvature R, that still act on the right side of the structure of length (L−a), because the stresses depend on the thickness ratio h_{d}=d/h₂, which is different from h=h₁/h₂.

### Elastic Strain Energy of Composite Structure and Energy Release Rate

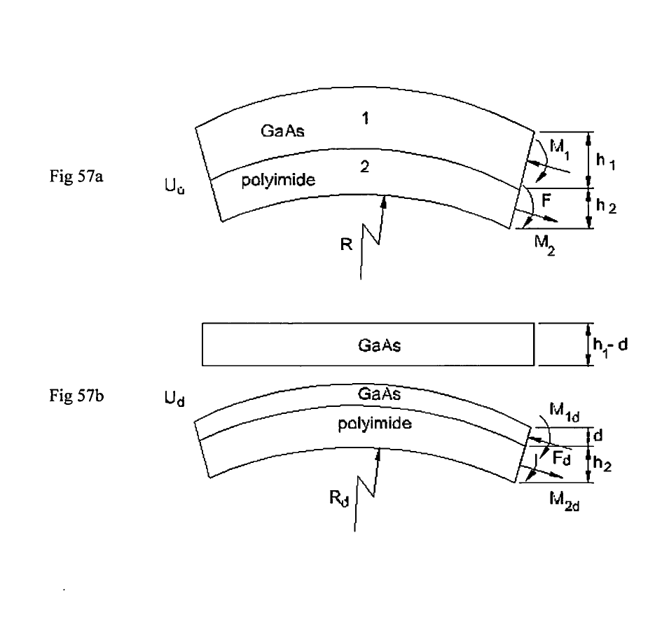

The total elastic strain energy Uₒ at the onset of crack propagation (a=0), which is proportional to the width b (into the page) times the length L, can be evaluated from the forces, moments and strains calculated above, as shown in FIG. 57a. The energy can also be evaluated as a function of the horizontal crack length a. When the crack reaches the end of the wafer (a=L), the surface area of the strip that has been split open after crack propagation is bL.

The lifted-off thickness d depends on the stress intensity factors K_{I} and K_{II} at the tip of the crack, which are function of the point of application of the force on the edge of the lifted-off layer (M_{1d}/F_{d}) [2,3,4]. However, the Griffith criterion for crack advance circumvents the necessity to consider the actual physical mechanism of material separation at the crack tip in detail and eliminates the need to determine K_{I} and K_{II} exactly. The two approaches are equivalent, as can be seen from equation (12) above, and can be used interchangeably. After separation, the backside of the wafer of thickness (h₁−d) is stress free and therefore has zero strain energy, whereas the lifted-off GaAs layer having thickness d, width b and length L, has residual strain energy U_{d}, as shown in FIG. 57b. The difference (Uₒ−U_{d}) is the work of fracture, which is equal to the surface energy per unit area, γₛ, times the area. The surface energy is a material property which depends on the number of atoms per unit area times the covalent energy per bond. The separation creates two surfaces of area bL each, therefore, the total work of fracture across the entire surface=2Lbγₛ.

The initial energy Uₒ is the total energy build up needed to initiate the crack. Once the crack starts to propagate then the rate of decrease in energy, i.e. the energy expended per unit crack advance, G which is defined as dU/b·da, is pinned at G=2γₛ. Therefore,

Uₒ−U_{d}=2Lbγₛ (13)

The energy Uₒ can be expressed in terms of the curvature 1/R and the stresses and strains, forces and moments given by equations (1-9) above and shown in FIG. 56, FIG. 57a and FIG. 57b.

Uₒ=1/2{Fε₁+Fε₂+M_{1/}R+M₂/R}L (14)

U_{d}=1/2{F_{d}ε_{1d}+F_{d}ε_{2d}+M_{1d}/R_{d}+M_{2d}/R_{d}}L (15)

### Solution for the Lifted-Off Thickness

Equation (13), in conjunction with equations (14) and (15), can in principle be solved for the lifted-off thickness, d. However, this involves solving an equation to the 8^{th} power (d⁸). Alternatively, the equation can be solved iteratively by trial and error by plugging in values of d until equation (13) is satisfied.

From the literature [15], the reported value of γₛ for GaAs (110) varies between 0.69 and 0.86 J/m², while that of Si (111) varies between 1.022 and 1.14 J/m² [6]. Thus, it is desired to find the thickness of GaAs which yields

(Uₒ−U_{d})/Lb=2γₛ=1.38−1.72 J/m² for GaAs, and (16)

(Uₒ−U_{d})/Lb=2γₛ=2.044−2.28 J/m² for Si (17)

### EXAMPLE 3

Referring back to Example 1 above, GaAs (110) full thickness h₁=370 μm, polyimide h₂=150 μm.

Uₒ=(0.0328+3.467+0.193+0.0003)bL=3.693 bL (18)

Uₒ=1/2{Fε₁+Fε₂+M₁/R+M₂/R}L (14)

Equation (14) is placed directly under equation (18) in order to compare the magnitudes of the corresponding terms. The largest contributor to the elastic strain energy at full thickness by far is the axial stress in the polyimide (1/2Fε₂). The Kapton is being stretched by 28.7×10⁻⁴, followed by bending in the GaAs, then compression in the GaAs, followed by a distant fourth, bending in the Kapton. The amount of energy that goes in bending the GaAs is 18× smaller than that goes in stretching the Kapton. The majority of the energy (93%) at full thickness is stored in the Kapton.

### EXAMPLE 4

GaAs (110) thickness d=15 μm, polyimide h₂=150 μm. Since a layer about 15 μm thick was cleaved in GaAs (110), this value is plugged in equation (15) to see whether it satisfies equation (16). Again, equation (15) is placed directly under equation (19) in order to compare the magnitudes of the corresponding terms. The radius of curvature R_{d}=4 cm.

U₁₅=(0.0412+0.1781+0.025+0.585)bL=0.8293bL (19)

U_{d}=1/2{F_{d}ε_{1d}+F_{d}ε_{2d}+M_{1d}/R_{d}+M_{2d}/R_{d}}L (15)

By contrast, the largest contributor to the elastic strain energy after lift-off is the bending in the polyimide (1/2M_{2d}/R_{d}), which exceeds the stretching energy (1/2F_{d}ε_{2d}). The majority of the energy (92%) after lift-off is still stored in the Kapton. By subtracting equation (19) from (18) and comparing to (16) we obtain:

(Uₒ−U₁₅)/Lb=2.864 J/m² which is outside the range 1.38-1.72 J/m² given by equation (16)

Therefore, a GaAs lifted-off thickness of 15 μm does not satisfy the energy release rate equation. Neither does a thickness of 25 μm. However, a thickness of 80 μm comes close.

### EXAMPLE 5

GaAs (110) thickness d=80 μm, polyimide h₂=150 μm. The radius of curvature R₈₀=8.1 cm in liquid nitrogen.

U₈₀=(0.0435+1+0.815+0.125)bL=1.9835bL (20)

U_{d}=1/2{F_{d}ε_{1d}+F_{d}ε_{2d}+M_{1d}/R_{d}+M_{2d}/R_{d}}L (15)

The majority of the energy (56.7%) after lift-off is still stored in the Kapton, but the GaAs carries a significant portion of the strain. By subtracting equation (20) from (18) and comparing to (16):

(Uₒ−U₈₀)/Lb=1.71 J/m² which is within the range 1.38-1.72 J/m². Thus, GaAs cleaves at a depth of 80 μm. This depth is within the compressive zone near the polyimide.

### EXAMPLE 6

GaAs (110) E_{1eff}=250 GPa, h₁=370 μm, polyimide E_{2eff}=5.8 GPa, h₂=75 μm E=E_{1eff}/E_{2eff}=42.88, h=h₁/h₂=4.933.
Equations (5-9) yield:

1/(2R)=0.135 m⁻¹→R=3.7 m in liquid nitrogen
σₐ₁=3.5 MPa
σₐ₂=17 MPa
σ_{b1}=12.5 MPa
σ_{b2}=0.059 MPa=58.7 KPa
εₐ₁=0.14×10⁻⁴
εₐ₂=29.3×10⁻⁴
ε_{b1}=0.5×10⁻⁴
ε_{b2}=0.1×10⁻⁴

Uₒ=(0.009+1.868+0.038+0.000007)bL=1.915bL (21)

Uₒ=1/2{Fε₁+F_{ε}₂+M₁/R+M₂/R}L (14)

This is barely above 2γₛ=1.38-1.72 J/m² for GaAs from equation (16) above. For this reason one layer of Kapton 75 μm thick is barely able to drive the crack across the GaAs wafer and needed to be scratched every step of the way to reach the edge. When another layer was laminated for a total thickness of 150 μm, the crack propagated readily. The majority of the elastic energy (97.5%) is stored in the Kapton.

### EXAMPLE 7

Referring back to Example 2 above, Si (110) full thickness h₁=200 μm, polyimide h₂=150 μm. R=50 cm

Uₒ=(0.0433+2.987+0.397+0.0033)bL=3.43bL (22)

Uₒ=1/2{Fε₁+Fε₂+M₁/R+M₂/R}L (14)

The total energy in the 200 μm Si wafer is almost equal to that in the 370 μm thick GaAs wafer. This is due to the fact that Si is stiffer than GaAs. The largest contributor to the elastic strain energy at full thickness by far is still the axial stress in the polyimide (1/2Fε₂). The Kapton is being stretched by 26.2×10⁻⁴, followed by bending in the GaAs, then compression in the GaAs, followed by a distant fourth, bending in the Kapton. The majority of the energy (87.2%) at full thickness is stored in the Kapton.

### EXAMPLE 8

Si (110) h₁=50 μm, polyimide h₂=150 μm. R=5.25 cm

Uₒ=(0.027+0.45+0.56+0.294)bL=1.331bL (23)

U_{d}=1/2{F_{d}ε_{1d}+F_{d}ε_{2d}+M_{1d}/R_{d}+M_{2d}/R_{d}}L (15)

By subtracting equation (22) from (21) and comparing to (17):

(Uₒ−U₅₀)/Lb=2.1 J/m² which is within the range 2.044-2.28 J/m². Thus, Si cleaves at a depth of 40-50 μm. This depth is within the compressive zone near the polyimide.

To summarize, the residual energy U_{d}/Lb must fall in the following ranges:

U_{d}/Lb=Uₒ/Lb−2γₛ=1.973-2.313 J/m² for GaAs, and (24)

U_{d}/Lb=Uₒ/Lb−2γₛ=1.15-1.386 J/m² for Si (25)

Thus, cleavage depths of 80-90 μm for GaAs and 40-50 μm for Si satisfy the energy release rate criterion, whereas lifted-off thicknesses of 15-25 μm for GaAs (110) and 25-40 μm for Si (111) were obtained experimentally. The discrepancy is due to inaccuracy in determining the effective modulus of elasticity.

### EXAMPLE 9

Si (111) E_{1eff}=300 GPa, h₁=200 μm, polyimide E_{2eff}=5.8 GPa, h₂=75 μm E=E_{Ieff}/E_{2eff}−51.3, h=h₁/h₂=2.667
Equations (5-9) yield: 1/(2R)=0.43 m⁻¹→R=1.16 m
σₐ₁=6.3 MPa
σₐ₂=16.8 MPa
σ_{b1}=25.8 MPa
σ_{b2}=0.187 MPa
εₐ₁=0.2×10⁻⁴
εₐ₂=29×10⁻⁴
ε_{b1}=0.86×10⁻⁴
ε_{b2}=0.3×10⁻⁴

Uₒ=(0.0126+1.827+0.074+0.000075)bL=1.914bL (26)

Uₒ=1/2{Fε₁+Fε₂+M₁/R+M₂/R}L (14)

This is below 2γₛ=2.044-2.28 J/m² for Si from equation (17) above. For this reason one layer of Kapton 75 μm thick was not able to drive a crack across a Si wafer 200 μm thick even after scratching. A second layer of Kapton was laminated and the crack propagated readily. The total elastic energy stored in the Si wafer 200 μm thick is very close to that of GaAs wafer 370 μm thick, equation (21) in example 6 above, for a polyimide thickness of 75 μm. The majority of the elastic energy (95.4%) is stored in the Kapton, and it is stretched by a similar amount.

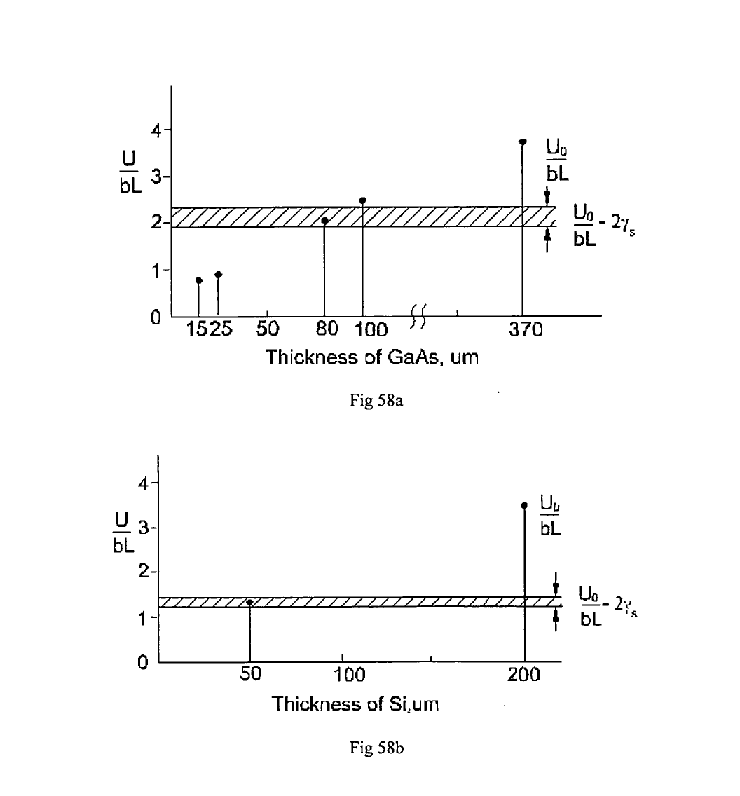

The results for GaAs and Si are summarized in FIGS. 58a and 58b, respectively.

### Calculation of Specific Power for Space

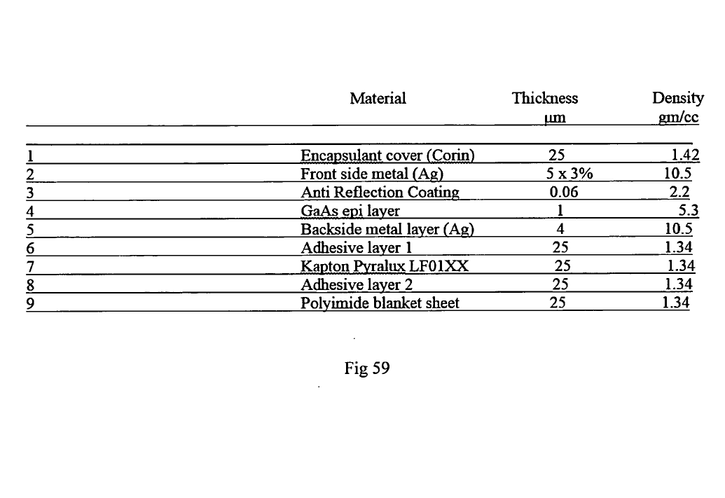

FIG. 59 shows the 9 layers of a solar cell along with their range of thickness and density. The thickness of the Imiclear XLS (Previously Corin made by Hybrid Plastics) spin-on polyimide encapsulating layer varies between 25 and 50 μm. This provides effective protection against UV radiation and oxygen ions in space, and adequate protection from moisture and abrasion on earth. The front side metal layer (2) is patterned in lines which cover 1.5% of the surface of the cell and the bus bar covers another 1.5%. The anti-reflective dielectric coating (ARC) (layer 3) is very thin (600 Angstroms), and therefore can be neglected.

The specific power is calculated for an ImiClear thickness of 50 μm, a GaAs epi-layer thickness of 10 μm, Kapton thickness of 50 μm, and blanket polyimide sheet thickness of 50 μm as follows:
Solar cell area=30 cm²
Solar irradiance in space=135 mW/cm² peak=1350 W/m²
Average efficiency of a triple-junction solar cell in space=28%
Power output of a solar cell in space=135×30×0.28=1.1 W
Specific gravity of GaAs=5.3
Density of kapton/polyimide/Corin=1.34-1.42 μm/cc
Density of silver=10.5 μm/cc
1. Weight of Imiclear encapsulating layer=30×50×10⁻⁴×1.42×10⁻³=0.0212×10⁻² Kg
2. Weight of front side metal layer Ag (5 μm)=3%×30×5×10⁻⁴×10.5×10⁻³=0.00047×10⁻² Kg
3. Weight of anti-reflection coating ARC=30×0.06×10⁻⁴×2.2×10⁻³=0.00004×10⁻² Kg
4. Weight of epi-layers GaAs (10 μm)=30×10×10⁻⁴×5.3×10⁻³=0.016×10⁻² Kg
5. Weight of backside metal layer Ag (4 μm)=30×4×10⁻⁴×10.5×10⁻³=0.012×10⁻² Kg
6. Weight of adhesive layer 1=30×25×10⁻⁴×1.34×10⁻³=0.01×10⁻² Kg
7. Weight of Kapton Pyralux LF0120 sheet=30×50×10⁻⁴×1.34×10⁻³=0.02×10⁻² Kg
8. Weight of adhesive layer 2=30×25×10⁻⁴×1.34×10⁻³=0.01×10⁻² Kg
9. Weight of polyimide blanket AP8555 sheet=30×50×10⁻⁴×1.34×10⁻³=0.02×10⁻² Kg
Weight of 9-layer cell=0.11×10⁻² Kg
Specific power of 9-layer cell=1.1 W/0.11×10⁻² Kg=1000 W/kg

Thus, the specific power ratio=1000 W/kg under AM0.

Having thus described several aspects of at least one embodiment of this invention, it is to be appreciated various alterations, modifications, and improvements will readily occur to those skilled in the art. Such alterations, modifications, and improvements are intended to be part of this disclosure, and are intended to be within the spirit and scope of the invention. Accordingly, the foregoing description and drawings are by way of example only.

### REFERENCES

1. Kelly M. Trautz, et al, Mobile Solar Power, IEEE JPV, Vol. 3, No. 1, p 535-541 January 2013
2. Thouless et al, Acta. Metall., Vol 35, No. 6, pages 1333-41, 1987
3. Suo Z and Hutchinson J W, Int. J. Solids Structures, Vol 25 No. 11, pages 1337-53, 1989
4. Hutchinson J W and Suo Z, Advances in Applied Mechanics, Vol 29, pages 63-191, 1992
5. Bedell et al, J. Phys. D: Appl. Phys. 46 (2013) 152002
6. Masolin et al, Journal of Materials Science, 18 Jul. 2012
7. Jawarani et al, 38^{th} IEEE PhotoVoltaics Specialists Conference, 2012
8. Masolin et al, Energy Procedia 27 (2012) 567-572
9. C. H. Wang, DSTO, Australia AR No. AR-009-786, July 1996
10. R. W. Margevicius et al, Philosophical Magazine A, 1998, Vol. 78, No. 3, 567-581
11. T. Okui et al, Surface Science, 2000, 448, 219
12. Rao Tatavarti, et al, 978-1-4244-1641-7/08 IEEE 2008
13. John Farah, IEEE 38^{th} PVSC 2012
14. K. Lee, et al, IEEE 38^{th} PVSC 2012
15. Wasmer, et al, Advanced Engineering Materials, 7, pages 309-317, 2005
16. K. Wasmer et al, Dicing of gallium-arsenide high performance laser diodes for industrial applications: Part I: Scratching, Part II: Cleavage, Journal of Materials Processing Technology, Volume 198, Issues 1-3, Pages 105-121, 3 Mar. 2008
18. A. Mette, et al, Prog. Photovolt: Res. Appl. 2007; 15: 621-627
19. Dewei Xu, et al, IRPS 2012
20. http://prism.mit.edu/xray/Introduction%20to%20HRXRD.pdf
21. S. Bedell et al, Kerf-less Removal of Si, Ge and III-V Layers by Controlled Spalling to Enable Low-Cost PV Technologies, 5th International Workshop on Crystalline Silicon Solar Cells—CSSC-5, 1-3 Nov. 2011, Boston, USA
22. J. Vaes et al, SLIM-CUT Thin Silicon Wafering with enhanced crack and stress control, SPIE Vol. 7772-12, 2010
23. F. Dross et al, METHOD FOR THE PRODUCTION OF THIN SUBSTRATE, Patent Application Pub No.: US 2010/0323472 A1, www.uspto.gov, Dec. 23, 2010
24. D. Jawarani et al, A LOW COST KERFLESS EXFOLIATION TECHNOLOGY FOR 25 μm THIN MONOCRYSTALLINE SI SOLAR CELLS, 5th International Workshop on Crystalline Silicon Solar Cells—CSSC-5, 1-3 Nov. 2011, Boston, Mass.
25. José Millán, A REVIEW OF WBG POWER SEMICONDUCTOR DEVICES, pages 57-66, IEEE 2012
26. http://english.gg-led.com/asdisp3-65b095fb-2893-.html
27. Claudio Ronald Miskys, New Substrates for Epitaxy of Group III Nitride Semiconductors: Challenges and Potential, PhD Discertation, Technischen Universität München, October 2004
28. Luca Redaelli, Design and fabrication of GaN laser diodes for single-mode and narrow-linewidth applications, PhD Thesis, Ferdinand Braun Institut, Berlin, Germany, November 2013
29. Hideo Aida, et al, Chemical Mechanical Polishing of Gallium Nitride with Colloidal Silica, J. Electrochem. Soc., Volume 158, Issue 12, Pages H1206-H1212, 2011
30. R Rupp, et al., Performance of a 650 V SiC diode with reduced chip thickness, Materials Science Forum Volumes 717-720, pages 921-924, 2012
31. Gao S, et al., Warping of silicon wafers subjected to back-grinding process, Precision Engineering 2014, http://dx.doi.org/10.1016/j.precisioneng.2014.10.009
32. K. Tomita, et al., Self-Separation of Freestanding GaN from Sapphire Substrates by Hydride Vapor Phase Epitaxy, phys. stat. sol. (a) 194, No. 2, pages 563-567, 2002
33. I. Ratschinski, et al., Indentation-induced dislocations and cracks in (0001) freestanding and epitaxial GaN, Journal of Physics: Conference Series 281, 2011
34. Kehl Sink, Cleaved-Facet Group-III Nitride Lasers, Ph.D. Dissertation, University of California, Santa Barbara, December, 2000
35. Kensaku Motoki, Development of Gallium Nitride Substrates, SEI Technical Review, Number 70, pages 28-35, APRIL 2010
36. John Farah, et al, Dry-Epitaxial Lift-off for High Efficiency Solar Cells, 40th IEEE Photovoltaics Specialist Conference, www.ieee-pvsc.org, pages 1796-1801, June 2014 http://ieeexplore.ieee.org/stamp/stamp.jsp?tp=&arnumber=6925271&tag=1

What is claimed:

1. A method for separating an epitaxially grown layer from a growth substrate comprising:
Laminating a layer of a material having a higher coefficient of thermal expansion than said substrate and said epitaxial layer, to said epitaxial layer,
Cooling the laminate, thus separating said epitaxially grown layer from said growth substrate.

2. The method of claim 1 wherein said growth substrate is made of GaAs and said epitaxially grown layer is made of III-V compounds.

3. The method of claim 2 wherein said epitaxially grown layer is an inverted triple junction solar cell.

4. The method of claim 1 wherein said material having a higher coefficient of thermal expansion is polyimide.

5. The method of claim 4 wherein said polyimide is Kapton® film.

6. The method of claim 5 wherein said Kapton® film having a layer of acrylic adhesive is Pyralux® manufactured by DuPont.

7. The method of claim 6 wherein said Pyralux® is LF0120 having a layer of acrylic adhesive 25 μm thick and a layer of Kapton 50 μm thick

8. The method of claim 7 wherein said Pyralux® consists of multiple layers of Kapton and acrylic adhesive

9. The method of claim 1 wherein said cooling is in liquid nitrogen.

10. A method of thinning a substrate by separating a first layer from said substrate comprising:
Laminating a second layer of a material having a higher coefficient of thermal expansion than said substrate, to said first layer,
Cooling the laminate, thus separating said first layer from said substrate.

11. The method of claim 10 wherein said substrate is made of the group of Gallium Nitride and Silicon Carbide.

12. The method of claim 11 wherein said material having a higher coefficient of thermal expansion is polyimide.

13. The method of claim 12 wherein said polyimide is Kapton® film.

14. The method of claim 13 wherein said Kapton® film having a layer of acrylic adhesive is Pyralux® manufactured by DuPont.

15. The method of claim 14 wherein said Pyralux® is a laminate of multiple layers of LF0100, LF0110, LF0120, LF0130 and LF0150 having a total thickness of about 750 μm.

16. The method of claim 12 wherein said polyimide has a coefficient of thermal expansion in the range of 50 to 60×10⁻⁶/° C.

17. The method of claim 10 wherein said cooling is in liquid nitrogen.

18. The method of claim 10 wherein said thinning reduces the amount of lapping, polishing and chemical-mechanical polishing necessary to make the surface epi-ready.

19. The method of claim 11 wherein said substrate is as-cut from boule.

20. The method of claim 11 wherein said thinning is applied to the backside of a substrate with completed devices on the front side.
